(19) United States
(12) Patent Application Publication
(10) Pub. No.: US 2008/0011350 A1
(43) Pub. Date: Jan. 17, 2008

(54) Collector grid, electrode structures and interconnect structures for photovoltaic arrays and other optoelectric devices

(76) Inventor: Daniel Luch, Morgan Hill, CA (US)

Correspondence Address: Daniel Luch, 17161 Copper Hill Drive, Morgan Hill, CA, 95037, US

(21) Appl. No.: 11/824,047

(22) Filed: Jun. 30, 2007

Related U.S. Application Data
(63) Continuation-in-part of application No. 11/404,168, filed on Apr. 13, 2006.
Application No. 11/404,168 is a continuation-in-part of application No. 10/776,480, filed on Feb. 11, 2004, now abandoned.
Application No. 10/776,480 is a continuation-in-part of application No. 10/682,093, filed on Oct. 8, 2003.
Application No. 10/682,093 is a continuation-in-part of application No. 10/186,546, filed on Jul. 1, 2002, now abandoned.
Application No. 10/186,546 is a continuation-in-part of application No. 09/528,086, filed on Mar. 17, 2000, now Pat. No. 6,414,235.
Application No. 09/528,086 is a continuation-in-part of application No. 09/281,656, filed on Mar. 30, 1999, now Pat. No. 6,239,352.

(51) Int. Cl. H01L 31/042

(52) U.S. Cl. 136/249

(57) ABSTRACT

The invention teaches novel structure and methods for producing electrical current collectors and electrical interconnections. Such articles find particular use in facile production of arrays of photovoltaic cells. The current collector and interconnecting structures are initially produced separately from the photovoltaic cells thereby allowing the use of unique materials and manufacture. Subsequent application of the structures to the cells allows facile and efficient completion of arrays. Methods for combining the collector and interconnect structures with cells and final interconnecting into arrays are taught.

### CROSS-REFERENCE TO RELATED APPLICATIONS

This application is a Continuation-in-Part of U.S. patent application Ser. No. 11/404,168 filed Apr. 13, 2006, entitled Substrate and Collector Grid Structures for Integrated Photovoltaic Arrays and Process of Manufacture of Such Arrays, which is a Continuation-in-Part of U.S. application Ser. No. 10/776,480 filed Feb. 11, 2004, entitled Methods and Structures for the Continuous Production of Metallized or Electrically Treated Articles, now abandoned, which is a Continuation-in-Part of U.S. patent application Ser. No. 10/682,093 filed Oct. 8, 2003 entitled Substrate and Collector Grid Structures for Integrated Series Connected Photovoltaic Arrays and Process of Manufacture of Such Arrays, which is a Continuation-in-Part of U.S. patent application Ser. No. 10/186,546 filed Jul. 1, 2002, entitled Substrate and Collector Grid Structures for Integrated Series Connected Photovoltaic Arrays and Process of Manufacture of Such Arrays, now abandoned, which is a Continuation-in-Part of U.S. patent application Ser. No. 09/528,086, filed Mar. 17, 2000, entitled Substrate and Collector Grid Structures for Integrated Series Connected Photovoltaic Arrays and Process of Manufacture of Such Arrays, and now U.S. Pat. No. 6,414,235, which is a Continuation-in-Part of U.S. patent application Ser. No. 09/281,656, filed Mar. 30, 1999, entitled Substrate and Collector Grid Structures for Electrically Interconnecting Photovoltaic Arrays and Process of Manufacture of Such Arrays, and now U.S. Pat. No. 6,239,352. The entire contents of the above identified applications are incorporated herein by this reference.

### BACKGROUND OF THE INVENTION

Photovoltaic cells have developed according to two distinct methods. The initial operational cells employed a matrix of single crystal silicon appropriately doped to produce a planar p-n junction. An intrinsic electric field established at the p-n junction produces a voltage by directing solar photon produced holes and free electrons in opposite directions. Despite good conversion efficiencies and long-term reliability, widespread energy collection using single-crystal silicon cells is thwarted by the high cost of single crystal silicon material and interconnection processing.

A second approach to produce photovoltaic cells is by depositing thin photovoltaic semiconductor films on a supporting substrate. Material requirements are minimized and technologies can be proposed for mass production. The thin film structures can be designed according to doped homojunction technology such as that involving silicon films, or can employ heterojunction approaches such as those using CdTe or chalcopyrite materials. Despite significant improvements in individual cell conversion efficiencies for both single crystal and thin film approaches, photovoltaic energy collection has been generally restricted to applications having low power requirements. One factor impeding development of bulk power systems is the problem of economically collecting the energy from an extensive collection surface. Photovoltaic cells can be described as high current, low voltage devices. Typically individual cell voltage is less than about two volts, and often less than 0.6 volt. The current component is a substantial characteristic of the power generated. Efficient energy collection from an expansive surface must minimize resistive losses associated with the high current characteristic. A way to minimize resistive losses is to reduce the size of individual cells and connect them in series. Thus, voltage is stepped through each cell while current and associated resistive losses are minimized.

It is readily recognized that making effective, durable series connections among multiple small cells can be laborious, difficult and expensive. In order to approach economical mass production of series connected arrays of individual cells, a number of factors must be considered in addition to the type of photovoltaic materials chosen. These include the substrate employed and the process envisioned. Since thin films can be deposited over expansive areas, thin film technologies offer additional opportunities for mass production of interconnected arrays compared to inherently small, discrete single crystal silicon cells. Thus a number of U.S. Patents have issued proposing designs and processes to achieve series interconnections among the thin film photovoltaic cells. Many of these technologies comprise deposition of photovoltaic thin films on glass substrates followed by scribing to form smaller area individual cells. Multiple steps then follow to electrically connect the individual cells in series array. Examples of these proposed processes are presented in U.S. Pat. Nos. 4,443,651, 4,724,011, and 4,769,086 to Swartz, Turner et al. and Tanner et al. respectively. While expanding the opportunities for mass production of interconnected cell arrays compared with single crystal silicon approaches, glass substrates must inherently be processed on an individual batch basis.

More recently, developers have explored depositing wide area films using continuous roll-to-roll processing. This technology generally involves depositing thin films of photovoltaic material onto a continuously moving web. However, a challenge still remains regarding subdividing the expansive films into individual cells followed by interconnecting into a series connected array. For example, U.S. Pat. No. 4,965,655 to Grimmer et. al. and U.S. Pat. No. 4,697,041 to Okamiwa teach processes requiring expensive laser scribing and interconnections achieved with laser heat staking. In addition, these two references teach a substrate of thin vacuum deposited metal on films of relatively expensive polymers. The electrical resistance of thin vacuum metallized layers significantly limits the active area of the individual interconnected cells.

It has become well known in the art that the efficiencies of certain promising thin film photovoltaic junctions can be substantially increased by high temperature treatments. These treatments involve temperatures at which even the most heat resistant plastics suffer rapid deterioration, thereby requiring either ceramic, glass, or metal substrates to support the thin film junctions. Use of a glass or ceramic substrates generally restricts one to batch processing and handling difficulty. Use of a metal foil as a substrate allows continuous roll-to-roll processing. However, despite the fact that use of a metal foil allows high temperature processing in roll-to-roll fashion, the subsequent interconnection of individual cells effectively in an interconnected array has proven difficult, in part because the metal foil substrate is electrically conducting.

U.S. Pat. No. 4,746,618 to Nath et al. teaches a design and process to achieve interconnected arrays using roll-to-roll processing of a metal web substrate such as stainless steel. The process includes multiple operations of cutting, selective deposition, and riveting. These operations add considerably to the final interconnected array cost.

U.S. Pat. No. 5,385,848 to Grimmer teaches roll-to-roll methods to achieve integrated series connections of adjacent thin film photovoltaic cells supported on an electrically conductive metal substrate. The process includes mechanical or chemical etch removal of a portion of the photovoltaic semiconductor and transparent top electrode to expose a portion of the electrically conductive metal substrate. The exposed metal serves as a contact area for interconnecting adjacent cells. These material removal techniques are troublesome for a number of reasons. First, many of the chemical elements involved in the best photovoltaic semiconductors are expensive and environmentally unfriendly. This removal subsequent to controlled deposition involves containment, dust and dirt collection and disposal, and possible cell contamination. This is not only wasteful but considerably adds to expense. Secondly, the removal processes are difficult to control dimensionally. Thus a significant amount of the valuable photovoltaic semiconductor is lost to the removal process. Ultimate module efficiencies are further compromised in that the spacing between adjacent cells grows, thereby reducing the effective active collector area for a given module area.

Thus there remains a need for manufacturing processes and articles which allow separate production of photovoltaic structures while also offering unique means to achieve effective integrated connections.

A further unsolved problem which has thwarted production of expansive surface photovoltaic modules is that of collecting the photogenerated current from the top, light incident surface. Transparent conductive oxide (TCO) layers are normally employed as a top surface electrode. However, these TCO layers are relatively resistive compared to pure metals. Thus, efforts must be made to minimize resistive losses in transport of current through the TCO layer. One approach is simply to reduce the surface area of individual cells to a manageable amount. However, as cell widths decrease, the width of the area between individual cells (interconnect area) should also decrease so that the relative portion of inactive surface of the interconnect area does not become excessive. Typical cell widths of one centimeter are often taught in the art. These small cell widths demand very fine interconnect area widths, which dictate delicate and sensitive techniques to be used to electrically connect the top TCO surface of one cell to the bottom electrode of an adjacent series connected cell. Furthermore, achieving good stable ohmic contact to the TCO cell surface has proven difficult, especially when one employs those sensitive techniques available when using the TCO only as the top collector electrode. Another method is to form a current collector grid over the surface. This approach positions highly conductive material in contact with the surface of the TCO in a spaced arrangement such that the travel distance of current through the TCO is reduced. In the case of the classic single crystal silicon or polycrystal silicon cells, a common approach is to form a collector grid pattern of traces using a silver containing paste and then fuse the paste to sinter the silver particles into continuous conductive silver paths. These highly conductive traces normally lead to a collection buss such as a copper foil strip. One notes that this approach involves use of expensive silver and requires the photovoltaic semiconductors tolerate the high fusion temperatures. Another approach is to attach an array of fine copper wires to the surface of the TCO. The wires may also lead to a collection buss, or alternatively extend to an electrode of an adjacent cell. This wire approach requires positioning and fixing of multiple fine fragile wires which makes mass production difficult and expensive. Another approach is to print a collector grid array on the surface of the TCO using a conductive ink, usually one containing a heavy loading of fine particulate silver. The ink is simply dried or cured at mild temperatures which do not adversely affect the cell. These approaches require the use of relatively expensive inks because of the high loading of finely divided silver. In addition, batch printing on the individual cells is laborious and expensive.

In a somewhat removed segment of technology, a number of electrically conductive fillers have been used to produce electrically conductive polymeric materials. This technology generally involves mixing of a conductive filler such as silver particles with the polymer resin prior to fabrication of the material into its final shape. Conductive fillers may have high aspect ratio structure such as metal fibers, metal flakes or powder, or highly structured carbon blacks, with the choice based on a number of cost/performance considerations. More recently, fine particles of intrinsically conductive polymers have been employed as conductive fillers within a resin binder. Electrically conductive polymers have been used as bulk thermoplastic compositions, or formulated into paints and inks. Their development has been spurred in large part by electromagnetic radiation shielding and static discharge requirements for plastic components used in the electronics industry. Other known applications include resistive heating fibers and battery components and production of conductive patterns and traces. The characterization “electrically conductive polymer” covers a very wide range of intrinsic resistivities depending on the filler, the filler loading and the methods of manufacture of the filler/polymer blend. Resistivities for filled electrically conductive polymers may be as low as 0.00001 ohm-cm. for very heavily filled silver inks, yet may be as high as 10,000 ohm-cm or even more for lightly filled carbon black materials or other “anti-static” materials. “Electrically conductive polymer” has become a broad industry term to characterize all such materials. In addition, it has been reported that recently developed intrinsically conducting polymers (absent conductive filler) may exhibit resistivities comparable to conductive metals such as copper.

In yet another separate technological segment, coating plastic substrates with metal electrodeposits has been employed to achieve decorative effects on items such as knobs, cosmetic closures, faucets, and automotive trim. The normal conventional process actually combines two primary deposition technologies. The first is to deposit an adherent metal coating using chemical (electroless) deposition to first coat the nonconductive plastic and thereby render its surface highly conductive. This electroless step is then followed by conventional electroplating. ABS (acrylonitrile-butadiene-styrene) plastic dominates as the substrate of choice for most applications because of a blend of mechanical and process properties and ability to be uniformly etched. The overall plating process comprises many steps. First, the plastic substrate is chemically etched to microscopically roughen the surface. This is followed by depositing an initial metal layer by chemical reduction (typically referred to as “electroless plating”). This initial metal layer is normally copper or nickel of thickness typically one-half micrometer. The object is then electroplated with metals such as bright nickel and chromium to achieve the desired thickness and decorative effects. The process is very sensitive to processing variables used to fabricate the plastic substrate, limiting applications to carefully prepared parts and designs. In addition, the many steps employing harsh chemicals make the process intrinsically costly and environmentally difficult. Finally, the sensitivity of ABS plastic to liquid hydrocarbons has prevented certain applications. ABS and other such polymers have been referred to as “electroplateable” polymers or resins. This is a misnomer in the strict sense, since ABS (and other nonconductive polymers) are incapable of accepting an electrodeposit directly and must be first metallized by other means before being finally coated with an electrodeposit. The conventional technology for electroplating on plastic (etching, chemical reduction, electroplating) has been extensively documented and discussed in the public and commercial literature. See, for example, Saubestre, Transactions of the Institute of Metal Finishing, 1969, Vol. 47., or Arcilesi et al., Products Finishing, March 1984.

Many attempts have been made to simplify the process of electroplating on plastic substrates. Some involve special chemical techniques to produce an electrically conductive film on the surface. Typical examples of this approach are taught by U.S. Pat. No. 3,523,875 to Minklei, U.S. Pat. No. 3,682,786 to Brown et. al., and U.S. Pat. No. 3,619,382 to Lupinski. The electrically conductive film produced was then electroplated. None of these attempts at simplification have achieved any recognizable commercial application.

A number of proposals have been made to make the plastic itself conductive enough to allow it to be electroplated directly thereby avoiding the “electroless plating” process. It is known that one way to produce electrically conductive polymers is to incorporate conductive or semiconductive fillers into a polymeric binder. Investigators have attempted to produce electrically conductive polymers capable of accepting an electrodeposited metal coating by loading polymers with relatively small conductive particulate fillers such as graphite, carbon black, and silver or nickel powder or flake. Heavy such loadings are sufficient to reduce volume resistivity to a level where electroplating may be considered. However, attempts to make an acceptable electroplateable polymer using the relatively small metal containing fillers alone encounter a number of barriers. First, the most conductive fine metal containing fillers such as silver are relatively expensive. The loadings required to achieve the particle-to-particle proximity to achieve acceptable conductivity increases the cost of the polymer/filler blend dramatically. The metal containing fillers are accompanied by further problems. They tend to cause deterioration of the mechanical properties and processing characteristics of many resins. This significantly limits options in resin selection. All polymer processing is best achieved by formulating resins with processing characteristics specifically tailored to the specific process (injection molding, extrusion, blow molding, printing etc.). A required heavy loading of metal filler severely restricts ability to manipulate processing properties in this way. A further problem is that metal fillers can be abrasive to processing machinery and may require specialized screws, barrels, and the like.

Another major obstacle involved in the electroplating of electrically conductive polymers is a consideration of adhesion between the electrodeposited metal and polymeric substrate (metal/polymer adhesion). In most cases sufficient adhesion is required to prevent metal/polymer separation during extended environmental and use cycles. Despite being electrically conductive, a simple metal-filled polymer offers no assured bonding mechanism to produce adhesion of an electrodeposit since the metal particles may be encapsulated by the resin binder, often resulting in a resin-rich “skin”.

A number of methods to enhance electrodeposit adhesion to electrically conductive polymers have been proposed. For example, etching of the surface prior to plating can be considered. Etching can be achieved by immersion in vigorous solutions such as chromic/sulfuric acid. Alternatively, or in addition, an etchable species can be incorporated into the conductive polymeric compound. The etchable species at exposed surfaces is removed by immersion in an etchant prior to electroplating. Oxidizing surface treatments can also be considered to improve metal/plastic adhesion. These include processes such as flame or plasma treatments or immersion in oxidizing acids. In the case of conductive polymers containing finely divided metal, one can propose achieving direct metal-to-metal adhesion between electrodeposit and filler. However, here the metal particles are generally encapsulated by the resin binder, often resulting in a resin rich “skin”. To overcome this effect, one could propose methods to remove the “skin”, exposing active metal filler to bond to subsequently electrodeposited metal.

Another approach to impart adhesion between conductive resin substrates and electrodeposits is incorporation of an “adhesion promoter” at the surface of the electrically conductive resin substrate. This approach was taught by Chien et al. in U.S. Pat. No. 4,278,510 where maleic anhydride modified propylene polymers were taught as an adhesion promoter. Luch, in U.S. Pat. No. 3,865,699 taught that certain sulfur bearing chemicals could function to improve adhesion of initially electrodeposited Group VIII metals.

For the above reasons, electrically conductive polymers employing metal fillers have not been widely used as bulk substrates for electroplateable articles. Such metal containing polymers have found use as inks or pastes in production of printed circuitry. Revived efforts and advances have been made in the past few years to accomplish electroplating onto printed conductive patterns formed by silver filled inks and pastes.

An additional physical obstacle confronting practical electroplating onto electrically conductive polymers is the initial “bridge” of electrodeposit onto the surface of the electrically conductive polymer. In electrodeposition, the substrate to be plated is often made cathodic through a pressure contact to a metal rack tip, itself under cathodic potential. However, if the contact resistance is excessive or the substrate is insufficiently conductive, the electrodeposit current favors the rack tip to the point where the electrodeposit will not bridge to the substrate.

Moreover, a further problem is encountered even if specialized racking or cathodic contact successfully achieves electrodeposit bridging to the substrate. Many of the electrically conductive polymers have resistivities far higher than those of typical metal substrates. Also, many applications involve electroplating onto a thin (less than 25 micrometer) printed substrate. The conductive polymeric substrate may be relatively limited in the amount of electrodeposition current which it alone can convey. Thus, the conductive polymeric substrate does not cover almost instantly with electrodeposit as is typical with metallic substrates. Except for the most heavily loaded and highly conductive polymer substrates, a large portion of the electrodeposition current must pass back through the previously electrodeposited metal growing laterally over the surface of the conductive plastic substrate. In a fashion similar to the bridging problem discussed above, the electrodeposition current favors the electrodeposited metal and the lateral growth can be extremely slow and erratic. This restricts the size and “growth length” of the substrate conductive pattern, increases plating costs, and can also result in large non-uniformities in electrodeposit integrity and thickness over the pattern.

This lateral growth is dependent on the ability of the substrate to convey current. Thus, the thickness and resistivity of the conductive polymeric substrate can be defining factors in the ability to achieve satisfactory electrodeposit coverage rates. When dealing with selectively electroplated patterns long thin metal traces are often desired, deposited on a relatively thin electrically conductive polymer substrate. These factors of course often work against achieving the desired result.

This coverage rate problem likely can be characterized by a continuum, being dependent on many factors such as the nature of the initially electrodeposited metal, electroplating bath chemistry, the nature of the polymeric binder and the resistivity of the electrically conductive polymeric substrate. As a “rule of thumb”, the instant inventor estimates that coverage rate issue would demand attention if the resistivity of the conductive polymeric substrate rose above about 0.001 ohm-cm. Alternatively, a “rule of thumb” appropriate for thin film substrates would be that attention is appropriate if the substrate film to be plated had a surface “sheet” resistance of greater than about 0.1 ohm per square.

The least expensive (and least conductive) of the readily available conductive fillers for plastics are carbon blacks. Attempts have been made to electroplate electrically conductive polymers using carbon black loadings. Examples of this approach are the teachings of U.S. Pat. Nos. 4,038,042, 3,865,699, and 4,278,510 to Adelman, Luch, and Chien et al. respectively.

Adelman taught incorporation of conductive carbon black into a polymeric matrix to achieve electrical conductivity required for electroplating. The substrate was pre-etched in chromic/sulfuric acid to achieve adhesion of the subsequently electroplated metal. A fundamental problem remaining unresolved by the Adelman teaching is the relatively high resistivity of carbon loaded polymers. The lowest “microscopic resistivity” generally achievable with carbon black loaded polymers is about 1 ohm-cm. This is about five to six orders of magnitude higher than typical electrodeposited metals such as copper or nickel. Thus, the electrodeposit bridging and coverage rate problems described above remained unresolved by the Adelman teachings.

Luch in U.S. Pat. No. 3,865,699 and Chien et al. in U.S. Pat. No. 4,278,510 also chose carbon black as a filler to provide an electrically conductive surface for the polymeric compounds to be electroplated. The Luch Patent U.S. Pat. No. 3,865,699 and the Chien Patent U.S. Pat. No. 4,278,510 are hereby incorporated in their entirety by this reference. However, these inventors further taught inclusion of materials to increase the rate of metal coverage or the rate of metal deposition on the polymer. These materials can be described herein as “electrodeposit growth rate accelerators” or “electrodeposit coverage rate accelerators”. An electrodeposit coverage rate accelerator is a material functioning to increase the electrodeposition coverage rate over the surface of an electrically conductive polymer independent of any incidental affect it may have on the conductivity of an electrically conductive polymer. In the embodiments, examples and teachings of U.S. Pat. Nos. 3,865,699 and 4,278,510, it was shown that certain sulfur bearing materials, including elemental sulfur, can function as electrodeposit coverage or growth rate accelerators to overcome problems in achieving electrodeposit coverage of electrically conductive polymeric surfaces having relatively high resistivity or thin electrically conductive polymeric substrates having limited current carrying capacity.

In addition to elemental sulfur, sulfur in the form of sulfur donors such as sulfur chloride, 2-mercapto-benzothiazole, N-cyclohexyle-2-benzothiaozole sulfonomide, dibutyl xanthogen disulfide, and tetramethyl thiuram disulfide or combinations of these and sulfur were identified. Those skilled in the art will recognize that these sulfur donors are the materials which have been used or have been proposed for use as vulcanizing agents or accelerators. Since the polymer-based compositions taught by Luch and Chien et al. could be electroplated directly they could be accurately defined as directly electroplateable resins (DER). These directly electroplateable resins (DER) can be generally described as electrically conductive polymers with the inclusion of a growth rate accelerator.

Specifically for the present invention, specification, and claims, directly electroplateable resins, (DER), are characterized by the following features:
(a) presence of an electrically conductive polymer;
(b) presence of an electrodeposit coverage rate accelerator;
(c) presence of the electrically conductive polymer and the electrodeposit coverage rate accelerator in the directly electroplateable composition in cooperative amounts required to achieve direct coverage of the composition with an electrodeposited metal or metal-based alloy.

In his Patents, Luch specifically identified unsaturated elastomers such as natural rubber, polychloroprene, butyl rubber, chlorinated butyl rubber, polybutadiene rubber, acrylonitrile-butadiene rubber, styrene-butadiene rubber etc. as suitable for the matrix polymer of a directly electroplateable resin. Other polymers identified by Luch as useful included polyvinyls, polyolefins, polystyrenes, polyamides, polyesters and polyurethanes.

When used alone, the minimum workable level of carbon black required to achieve “microscopic” electrical resistivities of less than 1000 ohm-cm. for a polymer/carbon black mix appears to be about 8 weight percent based on the combined weight of polymer plus carbon black. The “microscopic” material resistivity generally is not reduced below about 1 ohm-cm. by using conductive carbon black alone. This is several orders of magnitude larger than typical metal resistivities.

It is understood that in addition to carbon blacks, other well known, highly conductive fillers can be considered in DER compositions. Examples include but are not limited to metallic fillers or flake such as silver. In these cases the more highly conductive fillers can be used to augment or even replace the conductive carbon black. Furthermore, one may consider using intrinsically conductive polymers to supply the required conductivity. In this case, it may not be necessary to add conductive fillers to the polymer.

The “bulk, macroscopic” resistivity of conductive carbon black filled polymers can be further reduced by augmenting the carbon black filler with additional highly conductive, high aspect ratio fillers such as metal containing fibers. This can be an important consideration in the success of certain applications. Furthermore, one should realize that incorporation of non-conductive fillers may increase the “bulk, macroscopic” resistivity of conductive polymers loaded with finely divided conductive fillers without significantly altering the “microscopic resistivity” of the conductive polymer “matrix” encapsulating the non-conductive filler particles.

Regarding electrodeposit coverage rate accelerators, both Luch and Chien et al. in the above discussed U.S. Patents demonstrated that sulfur and other sulfur bearing materials such as sulfur donors and vulcanization accelerators function as electrodeposit coverage rate accelerators when using an initial Group VIII metal electrodeposit “strike” layer. Thus, an electrodeposit coverage rate accelerator need not be electrically conductive, but may be a material that is normally characterized as a non-conductor. The coverage rate accelerator need not appreciably affect the conductivity of the polymeric substrate. As an aid in understanding the function of an electrodeposit coverage rate accelerator the following is offered:
a. A specific conductive polymeric structure is identified as having insufficient current carrying capacity to be directly electroplated in a practical manner.
b. A material is added to the conductive polymeric material forming said structure. Said material addition may have insignificant affect on the current carrying capacity of the structure (i.e. it does not appreciably reduce resistivity or increase thickness).
c. Nevertheless, inclusion of said material greatly increases the speed at which an electrodeposited metal laterally covers the electrically conductive surface.
   It is contemplated that a coverage rate accelerator may be present as an additive, as a species absorbed on a filler surface, or even as a functional group attached to the polymer chain. One or more growth rate accelerators may be present in a directly electroplateable resin (DER) to achieve combined, often synergistic results.

A hypothetical example might be an extended trace of conductive ink having a dry thickness of 1 micrometer. Such inks typically include a conductive filler such as silver, nickel, copper, conductive carbon etc. The limited thickness of the ink reduces the current carrying capacity of this trace thus preventing direct electroplating in a practical manner. However, inclusion of an appropriate quantity of a coverage rate accelerator may allow the conductive trace to be directly electroplated in a practical manner.

One might expect that other Group 6A elements, such as oxygen, selenium and tellurium, could function in a way similar to sulfur. In addition, other combinations of electrodeposited metals, such as copper and appropriate coverage rate accelerators may be identified. It is important to recognize that such an electrodeposit coverage rate accelerator is important in order to achieve direct electrodeposition in a practical way onto polymeric substrates having low conductivity or very thin electrically conductive polymeric substrates having restricted current carrying ability.

It has also been found that the inclusion of an electrodeposit coverage rate accelerator promotes electrodeposit bridging from a discrete cathodic metal contact to a DER surface. This greatly reduces the bridging problems described above.

Due to multiple performance problems associated with their intended end use, none of the attempts identified above to directly electroplate electrically conductive polymers or plastics has ever achieved any recognizable commercial success. Nevertheless, the current inventor has persisted in personal efforts to overcome certain performance deficiencies associated with the initial DER technology. Along with these efforts has come a recognition of unique and eminently suitable applications employing the DER technology. Some examples of these unique applications for electroplated articles include solar cell electrical current collection grids, electrodes, electrical circuits, electrical traces, circuit boards, antennas, capacitors, induction heaters, connectors, switches, resistors, inductors, batteries, fuel cells, coils, signal lines, power lines, radiation reflectors, coolers, diodes, transistors, piezoelectric elements, photovoltaic cells, emi shields, biosensors and sensors. One readily recognizes that the demand for such functional applications for electroplated articles is relatively recent and has been particularly explosive during the past decade.

It is important to recognize a number of important characteristics of directly electroplateable resins (DERS) which facilitate the current invention. One such characteristic of the DER technology is its ability to employ polymer resins and formulations generally chosen in recognition of the fabrication process envisioned and the intended end use requirements. In order to provide clarity, examples of some such fabrication processes are presented immediately below in subparagraphs 1 through 7.
(1) Should it be desired to electroplate an ink, paint, coating, or paste which may be printed or formed on a substrate, a good film forming polymer, for example a soluble resin such as an elastomer, can be chosen to fabricate a DER ink (paint, coating, paste etc.). For example, in some embodiments thermoplastic elastomers having an olefin base, a urethane base, a block copolymer base or a random copolymer base may be appropriate. In some embodiments the coating may comprise a water based latex. Other embodiments may employ more rigid film forming polymers. The DER ink composition can be tailored for a specific process such flexographic printing, rotary silk screening, gravure printing, flow coating, spraying etc. Furthermore, additives can be employed to improve the adhesion of the DER ink to various substrates. One example would be tackifiers.
(2) Very thin DER traces often associated with collector grid structures can be printed and then electroplated due to the inclusion of the electrodeposit growth rate accelerator.
(3) Should it be desired to cure the DER substrate to a 3 dimensional matrix, an unsaturated elastomer or other “curable” resin may be chosen.
(4) DER inks can be formulated to form electrical traces on a variety of flexible substrates. For example, should it be desired to form electrical structure on a laminating film, a DER ink adherent to the sealing surface of the laminating film can be effectively electroplated with metal and subsequently laminated to a separate surface.
(5) Should it be desired to electroplate a fabric, a DER ink can be used to coat all or a portion of the fabric intended to be electroplated. Furthermore, since DER's can be fabricated out of the thermoplastic materials commonly used to create fabrics, the fabric itself could completely or partially comprise a DER. This would eliminate the need to coat the fabric.
(6) Should one desire to electroplate a thermoformed article or structure, DER's would represent an eminently suitable material choice. DER's can be easily formulated using olefinic materials which are often a preferred material for the thermoforming process. Furthermore, DER's can be easily and inexpensively extruded into the sheet like structure necessary for the thermoforming process.
(7) Should one desire to electroplate an extruded article or structure, for example a sheet or film, DER's can be formulated to possess the necessary melt strength advantageous for the extrusion process.
(8) Should one desire to injection mold an article or structure having thin walls, broad surface areas etc. a DER composition comprising a high flow polymer can be chosen.
(9) Should one desire to vary adhesion between an electrodeposited DER structure supported by a substrate the DER material can be formulated to supply the required adhesive characteristics to the substrate. For example, the polymer chosen to fabricate a DER ink can be chosen to cooperate with an “ink adhesion promoting” surface treatment such as a material primer or corona treatment. In this regard, it has been observed that it may be advantageous to limit such adhesion promoting treatments to a single side of the substrate. Treatment of both sides of the substrate in a roll to roll process may adversely affect the surface of the DER material and may lead to deterioration in plateability. For example, it has been observed that primers on both sides of a roll of PET film have adversely affected plateability of DER inks printed on the PET. It is believed that this is due to primer being transferred to the surface of the DER ink when the PET is rolled up.

All polymer fabrication processes require specific resin processing characteristics for success. The ability to “custom formulate” DER's to comply with these changing processing and end use requirements while still allowing facile, quality electroplating is a significant factor in the teachings of the current invention.

Another important recognition regarding the suitability of DER's for the teachings of the current invention is the simplicity of the electroplating process. Unlike many conventional electroplated plastics, DER's do not require a significant number of process steps prior to actual electroplating. This allows for simplified manufacturing and improved process control. It also reduces the risk of cross contamination such as solution dragout from one process bath being transported to another process bath. The simplified manufacturing process will also result in reduced manufacturing costs.

Another important recognition regarding the suitability of DER's for the teachings of the current invention is the wide variety of metals and alloys capable of being electrodeposited. Deposits may be chosen for specific attributes. Examples may include copper for conductivity and nickel for corrosion resistance.

Yet another recognition of the benefit of DER's for the teachings of the current invention is the ability they offer to selectively electroplate an article or structure. The articles of the current invention often consist of metal patterns selectively positioned in conjunction with insulating materials. Such selective positioning of metals is often expensive and difficult. However, the attributes of the DER technology make the technology eminently suitable for the production of such selectively positioned metal structures. As will be shown in later embodiments, it is often desired to electroplate a polymer or polymer-based structure in a selective manner. DER's are eminently suitable for such selective electroplating.

Yet another recognition of the benefit of DER's for the teachings of the current invention is the ability they offer to continuously electroplate an article or structure. As will be shown in later embodiments, it is often desired to continuously electroplate articles. DER's are eminently suitable for such continuous electroplating. Furthermore, DER's allow for selective electroplating in a continuous manner.

Yet another recognition of the benefit of DER's for the teachings of the current invention is their ability to withstand the pre-treatments often required to prepare other materials for plating. For example, were a DER to be combined with a metal, the DER material would be resistant to many of the pre-treatments such as cleaning which may be necessary to electroplate the metal.

Yet another recognition of the benefit of DER's for the teachings of the current invention is that the desired plated structure often requires the plating of long and/or broad surface areas. As discussed previously, the coverage rate accelerators included in DER formulations allow for such extended surfaces to be covered in a relatively rapid manner thus allowing one to consider the use of electroplating of conductive polymers.

These and other attributes of DER's may contribute to successful articles and processing of the instant invention. However, it is emphasized that the DER technology is but one of a number of alternative metal deposition or positioning processes suitable to produce many of the embodiments of the instant invention. Other approaches, such as electroless metal deposition or electroplating onto silver ink patterns may be suitable alternatives. These choices will become clear in light of the teachings to follow in the remaining specification, accompanying figures and claims.

In order to eliminate ambiguity in terminology, for the present invention the following definitions are supplied:

While not precisely definable, for the purposes of this specification, electrically insulating materials may generally be characterized as having electrical resistivities greater than 10,000 ohm-cm. Also, electrically conductive materials may generally be characterized as having electrical resistivities less than 0.001 ohm-cm. Also electrically resistive or semi-conductive materials may generally be characterized as having electrical resistivities in the range of 0.001 ohm-cm to 10,000 ohm-cm. The term “electrically conductive polymer” as used in the art and in this specification and claims extends to materials of a very wide range of resistivities from about 0.00001 ohm-cm. to about 10,000 ohm-cm and higher.

An “electroplateable material” is a material having suitable attributes that allow it to be coated with a layer of electrodeposited material.

A “metallizable material” is a material suitable to be coated with a metal deposited by any one or more of the available metallizing process, including chemical deposition, vacuum metallizing, sputtering, metal spraying, sintering and electrodeposition.

“Metal-based” refers to a material or structure having at least one metallic property and comprising one or more components at least one of which is a metal or metal-containing alloy.

“Alloy” refers to a substance composed of two or more intimately mixed materials.

“Group VIII metal-based” refers to a substance containing by weight 50% to 100% metal from Group VIII of the Periodic Table of Elements.

A “bulk metal foil” refers to a thin structure of metal or metal-based material that may maintain its integrity absent a supporting structure. Generally, metal films of thickness greater than about 2 micrometers may have this characteristic.

### OBJECTS OF THE INVENTION

An object of the invention is to eliminate the deficiencies in the prior art methods of producing-expansive area, series or parallel interconnected photovoltaic arrays.

A further object of the present invention is to provide improved substrates to achieve series or parallel interconnections among photovoltaic cells.

A further object of the invention is to provide structures useful for collecting current from an electrically conductive surface.

A further object of the invention is to provide current collector electrode structures useful in facilitating mass production of optoelectric devices such as photovoltaic cell arrays.

A further object of the present invention is to provide improved processes whereby interconnected photovoltaic arrays can be economically mass produced.

A further object of the invention is to provide a process and means to accomplish interconnection of photovoltaic cells into an integrated array through continuous processing.

Other objects and advantages will become apparent in light of the following description taken in conjunction with the drawings and embodiments.

### SUMMARY OF THE INVENTION

The current invention provides a solution to the stated need by producing the active photovoltaic cells and interconnecting structures separately and subsequently combining them to produce the desired interconnected array. One embodiment of the invention contemplates deposition of thin film photovoltaic junctions on metal foil substrates which may be heat treated following deposition if required in a continuous fashion without deterioration of the metal support structure. In a separate operation, interconnection structures are produced. In an embodiment, interconnection structures are produced in a continuous roll-to-roll fashion. In an embodiment, the interconnecting structure is laminated to the metal foil supported photovoltaic cell and conductive connections are applied to complete the array. In this way the interconnection structures can be uniquely formulated using polymer-based materials. Furthermore, the photovoltaic junction and its metal foil support can be produced in bulk without the need to use the expensive and intricate material removal operations currently taught in the art to achieve interconnections.

In another embodiment, a separately prepared current collector grid structure is taught. In an embodiment the current collector structure is produced in a continuous roll-to-roll fashion. The current collector structure comprises conductive material positioned on a first surface of a laminating sheet or positioning sheet. This combination is prepared such that the first surface of the laminating or positioning sheet and the conductive material can be positioned in abutting contact with a conductive surface. In one embodiment the conductive surface is the light incident surface of a photovoltaic cell. In another embodiment the conductive surface is the rear conductive surface of a photovoltaic cell.

### BRIEF DESCRIPTION OF THE DRAWINGS

The various factors and details of the structures and manufacturing methods of the present invention are hereinafter more fully set forth with reference to the accompanying drawings wherein:

FIG. 1 is a top plan view of a thin film photovoltaic structure including its support structure.

FIG. 1A is a top plan view of the article of FIG. 1 following an optional processing step of subdividing the article of FIG. 1 into cells of smaller dimension.

FIG. 2 is a sectional view taken substantially along the line 2-2 of FIG. 1.

FIG. 2A is a sectional view taken substantially along the line 2A-2A of FIG. 1A.

FIG. 2B is a simplified sectional depiction of the structure embodied in FIG. 2A.

FIG. 3 is an expanded sectional view showing a form of the structure of semiconductor 11 of FIGS. 2 and 2A.

FIG. 4 illustrates a possible process for producing the structure shown in FIGS. 1-3.

FIG. 5 is a sectional view illustrating the problems associated with making series connections among thin film photovoltaic cells shown in FIGS. 1-3.

FIG. 6 is a top plan view of a substrate structure for achieving series interconnections of photovoltaic cells.

FIG. 7 is a sectional view taken substantially along the line 7-7 of FIG. 6.

FIG. 8 is a sectional view similar to FIG. 7 showing an alternate embodiment of a substrate structure for achieving series interconnections of photovoltaic cells.

FIG. 9 is a top plan view of an alternate embodiment of a substrate structure for achieving series interconnections of photovoltaic cells.

FIG. 10 is a sectional view similar to FIGS. 7 and 8 taken substantially along the line 10-10 of FIG. 9.

FIG. 11 is a top plan view of another embodiment of a substrate structure for achieving series interconnections of photovoltaic cells.

FIG. 12 is a sectional view taken substantially along the line 12-12 of FIG. 11.

FIGS. 13A and 13B schematically depict a process for laminating a foil supported thin film photovoltaic structure of FIGS. 1 through 3 to an interconnecting substrate structure. FIG. 13A is a side view of the process. FIG. 13B is a sectional view taken substantially along line 13B-13B of FIG. 13A.

FIGS. 14A, 14B, and 14C are views of the structures resulting from the laminating process of FIG. 13A and using the substrate structure of FIGS. 7, 8, and 10 respectively.

FIGS. 15A, 15B, and 15C are sectional views taken substantially along the lines 15a-15a, 15b-15b, and 15c-15c of FIGS. 14A, 14B, and 14C respectively.

FIG. 16 is a top plan view of the structure resulting from the laminating process of FIG. 13A and using the substrate structure of FIGS. 11 and 12.

FIG. 17 is a sectional view taken substantially along the line 17-17 of FIG. 16.

FIG. 18 is a top plan view of the structures of FIGS. 14A and 15A but following an additional step in the manufacture of the interconnected cells.

FIG. 19 is a sectional view taken substantially along the line 19-19 of FIG. 18.

FIG. 20 is a top plan view of an embodiment of an interconnected array.

FIG. 21 is a sectional view taken substantially along line 21-21 of FIG. 20.

FIG. 22 is a sectional view similar to FIG. 15A but showing an alternate method of accomplishing the mechanical and electrical joining of the lamination process of FIG. 13A.

FIG. 23 is a sectional view similar to FIG. 15A but showing an alternate embodiment of the laminated structure.

FIG. 24 is a sectional view of an alternate embodiment.

FIG. 25 is a sectional view of the embodiment of FIG. 24 after a further processing step.

FIG. 26 is a sectional view of another embodiment of a laminated intermediate article in the manufacture of series interconnected arrays.

FIG. 27 is a top plan view of a starting component of an additional embodiment of the invention.

FIG. 28 is a sectional view taken along the line 28-28 of FIG. 27.

FIG. 29 is a simplified representation of the sectional structure of FIG. 28.

FIG. 30 is a top plan view of the embodiment of FIGS. 27 through 29 following an additional processing step.

FIG. 31 is a sectional view taken along the line 31-31 of FIG. 30.

FIG. 32 is a sectional view taken along the line 32-32 of FIG. 30.

FIG. 33 is a top plan view of an alternate structural embodiment.

FIG. 34 is a top plan view of another structural embodiment.

FIG. 35 is a top plan view similar to FIG. 34 of another structural embodiment.

FIG. 36 is a top plan view of the embodiments of FIGS. 30 through 32 after an additional optional processing step.

FIG. 37 is a sectional view taken along the line 37-37 of FIG. 36.

FIG. 38 is a sectional view taken along the line 38-38 of FIG. 36.

FIG. 39 is a sectional view taken along the line 39-39 of FIG. 36.

FIG. 40 is a simplified representation of a process used in the manufacture of an embodiment of the invention.

FIG. 41 is a sectional view taken along the line 41-41 of FIG. 40 using the structures of FIGS. 19 and 36 through 39.

FIG. 42 is a sectional view showing a lamination resulting from processing the structures of FIG. 41 according to the process of FIG. 40.

FIG. 43 is an enlarged sectional view of the portion of FIG. 42 within Circle “A” of FIG. 42.

FIG. 44 is a sectional view embodying a possible condition when using a circular form in a lamination process.

FIG. 45 is a sectional view embodying a possible condition resulting from choosing a low profile form in a lamination process.

FIG. 46 is a top plan view of a starting structure for other embodiments of the instant invention.

FIG. 47A is a sectional view taken substantially from the perspective of lines 47A-47A of FIG. 46.

FIG. 47B is a sectional view taken substantially from the perspective of lines 47B-47B of FIG. 46.

FIG. 47C is a simplified sectional representation of the FIG. 47B embodiment.

FIG. 48 is a sectional view embodying the article of FIGS. 46 and 47A through 47C after an additional processing step.

FIG. 49 is a sectional view embodying yet another article of the instant invention which combines the article of FIG. 48 with a cell as in FIGS. 1A and 2A.

FIG. 50 is a sectional view of multiple articles as embodied in FIG. 49 spatially arranged relative to an interconnect substrate as embodied in FIG. 10.

FIG. 51 is a sectional view showing the result of electrically joining the articles embodied in FIG. 50 with positioning intended to achieve series interconnection.

FIG. 52 is a sectional view embodying a spatial arrangement of two articles as in FIG. 48 along with an individual solar cell just prior to forming a laminated structure.

FIG. 53 is a sectional view of the novel article produced by laminating the three spatially arranged components embodied in FIG. 52.

FIG. 54 is a sectional view of a structural arrangement to produce a series joining of multiple articles as depicted in FIG. 53.

FIG. 55 is an enlarged view of the region contained within the rectangle “K” of FIG. 54.

FIG. 56 is a top plan view of a structure forming a starting article for an embodiment of the invention.

FIG. 57 is a sectional view taken substantially from the perspective of lines 57-57 of FIG. 56.

FIG. 58 is a sectional view embodying a possible structure of the article of FIGS. 56 and 57 in more detail.

FIG. 59 is a sectional view showing another embodiment of the basic structure depicted in FIG. 57.

FIG. 60 is a top plan view showing the initial article depicted in FIG. 56 following an additional processing step.

FIG. 61 is a sectional view taken substantially from the perspective of lines 61-61 of FIG. 60.

FIG. 62 is a sectional view of the article of FIGS. 60 and 61, taken from a similar perspective of FIG. 61, showing the FIGS. 60/61 embodiment following an additional optional processing step.

FIG. 63 is a sectional view of one article produced by laminating the structure embodied in FIG. 62 with a photovoltaic cell as embodied in FIGS. 1A and 2A.

FIG. 64 is a sectional view showing one embodiment of an arrangement appropriate to combine a multiple of FIG. 63 articles to achieve a series interconnected photovoltaic assembly.

FIG. 65 is a top plan view of a starting structure for another embodiment of the instant invention.

FIG. 66 is a sectional view, taken substantially along the lines 66-66 of FIG. 65, illustrating a possible laminate structure of the embodiment.

FIG. 66A is another embodiment of a laminate structure useful in the instant invention.

FIG. 67 is a simplified sectional view of the structure of FIG. 66 used for ease of presentation of additional embodiments.

FIG. 68 is a top plan view of the structure embodied in FIGS. 65 through 67 but following an additional processing step.

FIG. 69 is a sectional view taken substantially from the perspective of lines 69-69 of FIG. 68 using the simplified sectional representation illustrated in FIG. 67.

FIG. 70 is a top plan view of the structure presented in FIG. 68 following an additional processing step.

FIG. 71 is a sectional view taken substantially from the perspective of lines 71-71 of FIG. 70.

FIG. 72 is a sectional view similar to FIG. 71 after an additional optional processing step.

FIG. 73 is a top plan view of an alternate structure similar to that embodied in FIG. 70.

FIG. 74 is a simplified sectional view taken substantially from the perspective of lines 74-74 of FIG. 73.

FIG. 75 is a sectional view showing an article combining the structure of FIG. 72 with a photovoltaic cell structure embodied in FIGS. 1A and 2A.

FIG. 76 is a sectional view showing a joining of multiple FIG. 75 articles into a series interconnected array.

FIG. 77 is a top plan view of a starting component for an additional embodiment of the invention.

FIG. 78 is a sectional view taken along line 78-78 of FIG. 77.

FIG. 79 is a top plan view after an additional processing step employing the structure of FIGS. 77 and 78.

FIG. 80 is a simplified sectional view taken along line 80-80 of FIG. 79.

FIG. 81 is a top plan view, similar to FIG. 79, of an alternate embodiment.

FIG. 82 is a sectional view of the structure of FIG. 80 after an additional processing step.

FIG. 83 is a sectional view of a portion of the FIG. 82 structure after an additional processing step.

FIG. 84 is a sectional view similar to FIG. 13B just prior to the process illustrated in FIG. 13A, employing the structures shown in the sectional views of FIGS. 7 and 83.

FIG. 85 is a sectional view showing the structure resulting from application of the process such as that of FIG. 13A to the structural arrangement shown in FIG. 84.

FIG. 86 is a sectional view of the spacial positioning of the structure shown in FIG. 85 and an additional component of the embodiment just prior to a process employed to combine them.

FIG. 87 is a top plan view from the perspective of line 87-87 of FIG. 86.

FIG. 88 is another alternate embodiment of the FIG. 87 functional structure.

FIG. 89 is another embodiment of the functional structure of FIG. 87.

FIG. 90 is a sectional view of the possible structure of component 318 of FIG. 86.

FIG. 91 is a sectional view embodying the structure resulting from laminating the articles as depicted in FIG. 86.

### DESCRIPTION OF PREFERRED EMBODIMENTS

Reference will now be made in detail to the preferred embodiments of the invention, examples of which are illustrated in the accompanying drawings. In the drawings, like reference numerals designate identical, equivalent or corresponding parts throughout several views and an additional letter designation is characteristic of a particular embodiment.

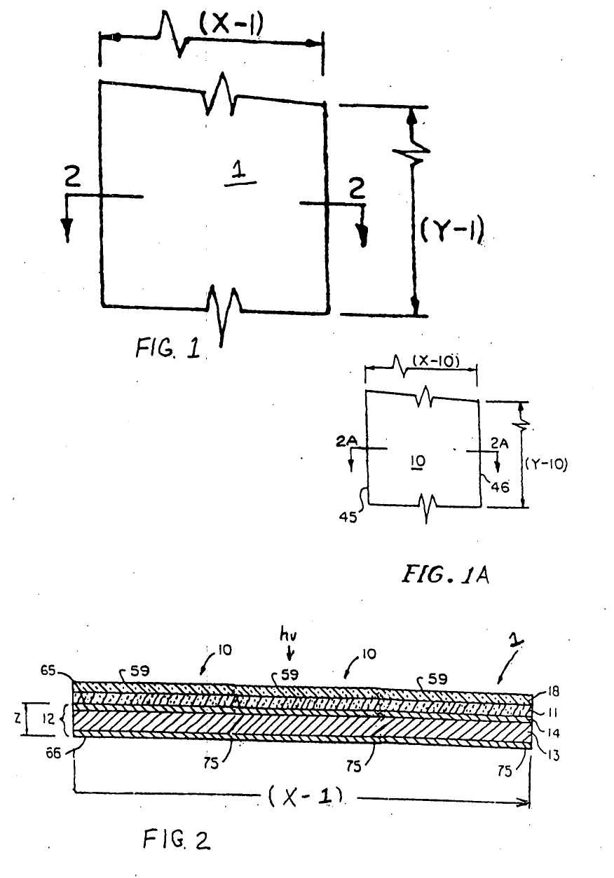

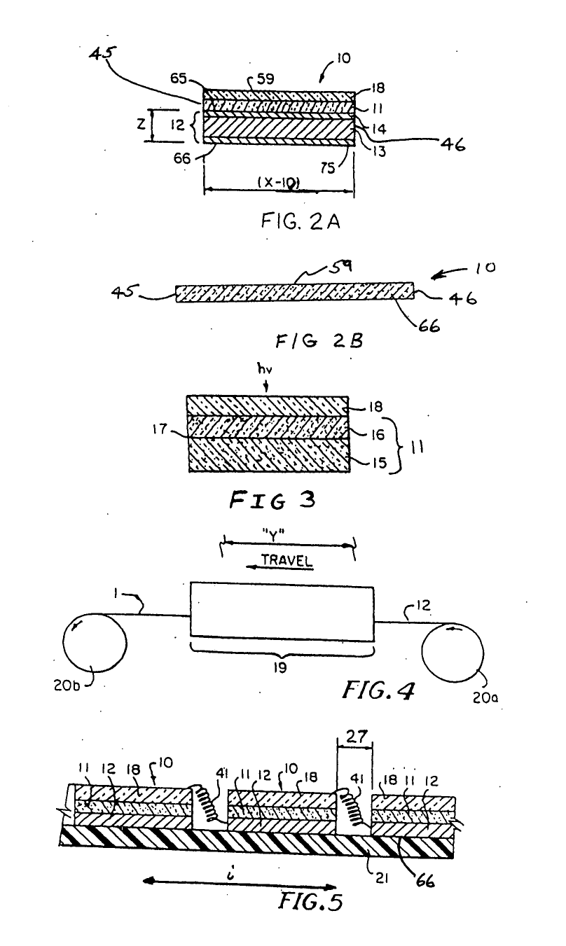

Referring to FIGS. 1 and 2, an embodiment of a thin film photovoltaic structure is generally indicated by numeral 1. It is noted here that “thin film” has become commonplace in the industry to designate certain types of semiconductor materials in photovoltaic applications. While the characterization “thin film” may be used to describe many of the embodiments of the instant invention, principles of the invention may extend to photovoltaic devices not normally considered “thin film” such as single crystal or polysilicon devices, as those skilled in the art will readily appreciate. Structure 1 has a light-incident top surface 59 and a bottom surface 66. Structure 1 has a width X-1 and length Y-1. It is contemplated that length Y-1 may be considerably greater than width X-1 such that length Y-1 can generally be described as “continuous” or being able to be processed in a roll-to-roll fashion. FIG. 2 shows that structure 1 comprises a thin film semiconductor structure 11 supported by metal-based foil 12. Foil 12 has a top surface 65, bottom surface 66, and thickness “Z”. Metal-based foil 12 may be of uniform composition or may comprise a laminate of multiple layers. For example, foil 12 may comprise a base layer of inexpensive and processable metal 13 with an additional metal-based layer 14 disposed between base layer 13 and semiconductor structure 11. The additional metal-based layer 14 may be chosen to ensure good ohmic contact between the top surface 65 of foil 12 and photovoltaic semiconductor structure 11. Bottom surface 66 of foil 12 may comprise a material 75 chosen to achieve good electrical and mechanical joining characteristics as will be shown. The thickness “Z” of foil 12 is often between 0.001 cm. and 0.025 cm. although thicknesses outside this range may be functional in certain applications. Nevertheless, a thickness between 0.001 cm. and 0.025 cm. would be expected to provide adequate handling strength while still allowing flexibility if roll-to-roll processing were employed, as further taught hereinafter.

In its simplest form, a photovoltaic structure combines an n-type semiconductor with a p-type semiconductor to from a p-n junction. Often an optically transparent “window electrode” such as a thin film of zinc or tin oxide is employed to minimize resistive losses involved in current collection. FIG. 3 illustrates an example of a typical photovoltaic structure in section. In FIGS. 2 and 3 and other figures, an arrow labeled “hv” is used to indicate the light incident side of the structure. In FIG. 3, 15 represents a thin film of a p-type semiconductor, 16 a thin film of n-type semiconductor and 17 the resulting photovoltaic junction. Window electrode 18 completes the typical photovoltaic structure. The exact nature of the photovoltaic semiconductor structure 11 does not form the subject matter of the present invention. For example, cells can be multiple junction or single junction and comprise homo or hetero junctions. Semiconductor structure 11 may comprise any of the thin film structures known in the art, including but not limited to CIS, CIGS, CdTe, Cu2S, amorphous silicon, polymer based semiconductors and the like. Structure 11 may also comprise organic solar cells such as dye sensitized cells. Further, semiconductor structure 11 may also represent characteristically “non-thin film” cells such as those based on single crystal or polycrystal silicon since many embodiments of the invention may encompass such cells, as will be evident to those skilled in the art in light of the teachings to follow.

In the following, photovoltaic cells having a metal based support foil will be used to illustrate the embodiments and teachings of the invention. However, those skilled in the art will recognize that many of the embodiments of the instant invention do not require the presence of a “bulk” foil as represented in FIGS. 1 and 2. In many embodiments, other conductive substrate structures, such as a metallized polymer film or glass having a thin metallized or conductive resin layer, may be substituted for the “bulk” metal foil.

FIG. 4 refers to a method of manufacture of the bulk thin film photovoltaic structures generally illustrated in FIGS. 1 and 2. In the FIG. 4 embodiment, a metal-based support foil 12 is moved in the direction of its length Y through a deposition process, generally indicated as 19. Process 19 accomplishes deposition of the active photovoltaic structure onto metal foil 12. Metal foil 12 is unwound from supply roll 20a, passed through deposition process 19 and rewound onto takeup roll 20b. Process 19 can comprise any of the processes well-known in the art for depositing thin film photovoltaic structures. These processes include electroplating, vacuum evaporation and sputtering, chemical deposition, and printing of nanoparticle precursors. Process 19 may also include treatments, such as heat treatments, intended to enhance photovoltaic cell performance.

Those skilled in the art will readily realize that the deposition process 19 of FIG. 4 may most efficiently produce photovoltaic structure 1 having dimensions far greater than those suitable for individual cells in an interconnected array. Thus, the photovoltaic structure 1 may be subdivided into cells having dimensions X-10 and Y-10 as indicated in FIGS. 1A and 2A for further fabrication. In FIG. 1A, width X-10 defines a first photovoltaic cell terminal edge 45 and second photovoltaic cell terminal edge 46. In one embodiment, for example, X-10 of FIG. 1A may be from 0.25 inches to 12 inches and Y-10 of FIG. 1A may be characterized as “continuous”. In other embodiments the final form of cell 10 may be rectangular, such as 6 inch by 6 inch, 4 inch by 3 inch or 8 inch by 2 inch. In other embodiments, the photovoltaic structure 1 of FIG. 1 may be subdivided in the “X” dimension only thereby retaining the option of further processing in a “continuous” fashion in the “Y” direction. In the following, cell structure 10 in this subdivided form having dimensions suitable for interconnection into a multi-cell array may be referred to as “cell stock” or simply as cells. “Cell stock” can be characterized as being either continuous or discreet.

FIG. 2B is a simplified depiction of cell 10 shown in FIG. 2A. In order to facilitate presentation of the aspects of the instant invention, the simplified depiction of cell 10 shown in FIG. 2B will normally be used.

Referring now to FIG. 5, there are illustrated cells 10 as shown in FIG. 2A. The cells have been positioned to achieve spacial positioning on the support substrate 21. Support structure 21 is by necessity non-conductive at least in that distance indicated by numeral 27 separating the adjacent cells 10. This insulating space prevents short circuiting from metal foil electrode 12 of one cell to foil electrode 12 of an adjacent cell. In order to achieve series connection, electrical communication must be made from the top surface of window electrode 18 to the foil electrode 12 of an adjacent cell. This communication is shown in the FIG. 5 as a metal wire or tab 41. The direction of the net current flow for the arrangement shown in FIG. 5 is indicated by the double pointed arrow “I”. It should be noted that foil electrode 12 is normally relatively thin, on the order of 0.001 cm. to 0.025 cm. Therefore, connecting to its edge as indicated in FIG. 5 would be impractical. Thus, such connections are normally made to the bottom surface 66 of the cell. One readily recognizes that connecting metal wire or tab 41 is laborious, making inexpensive production difficult.

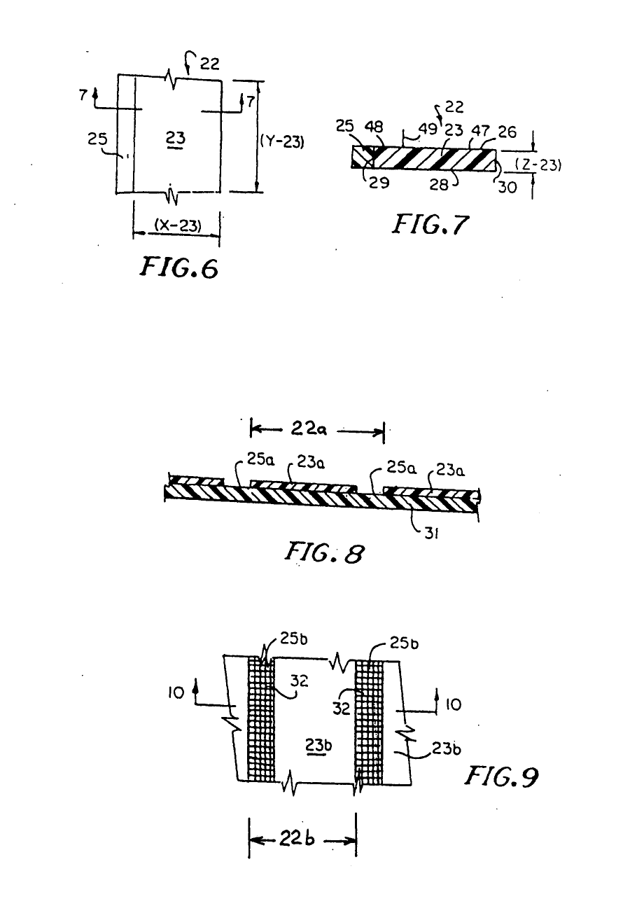

Referring now to FIGS. 6 and 7, one embodiment of the interconnection substrate structures of the current invention is generally indicated by 22. Unit of interconnection substrate 22 comprises electrically conductive region 23 and electrically insulating joining portion region 25. Electrically conductive region 23 has a top surface 26, bottom surface 28, width X-23, length Y-23 and thickness Z-23. In the embodiment of FIGS. 6 and 7, width X-23 defines a first terminal edge 29 and a second terminal edge 30 of conductive region 23. Top surface 26 of conductive region 23 can be thought of as having top collector region 47 and top contact region 48 separated by imaginary line 49. The purpose for these definitions will become clear in the following. While X-23 of the conductive region 23 is shown as substantially constant in the Y dimension, one will understand that X-23 can comprise a more complicated structure such as traces of conductive material separated by a non-conductive surface or a conductive mesh having “non-conductive” regions in the mesh pattern.

In the embodiment of FIGS. 6 and 7, electrically conductive region 23 comprises an electrically conductive polymer. Typically, as stated above, electrically conductive polymers generally exhibit bulk resistivity values of less than 10,000 ohm-cm. Resistivities between about 0.00001 and 10,000 ohm-cm can be achieved by compounding well-known conductive fillers into a polymer matrix binder.

The interconnection substrate structure 22 may be fabricated in a number of different ways. Electrically conductive region 23 can comprise an extruded film of electrically conductive polymer joined to a strip of compatible insulating polymer 25 at or near terminal edge 29 as illustrated in FIG. 7. Alternatively, the conductive region 23 may comprise a strip or coating of electrically conductive polymer 23a laminated or printed onto an insulating support structure 31 as illustrated in section in FIG. 8. In FIG. 8, electrically insulating joining portions 25a are simply those portions of insulating support structure 31 not overlaid by conductive regions 23a.

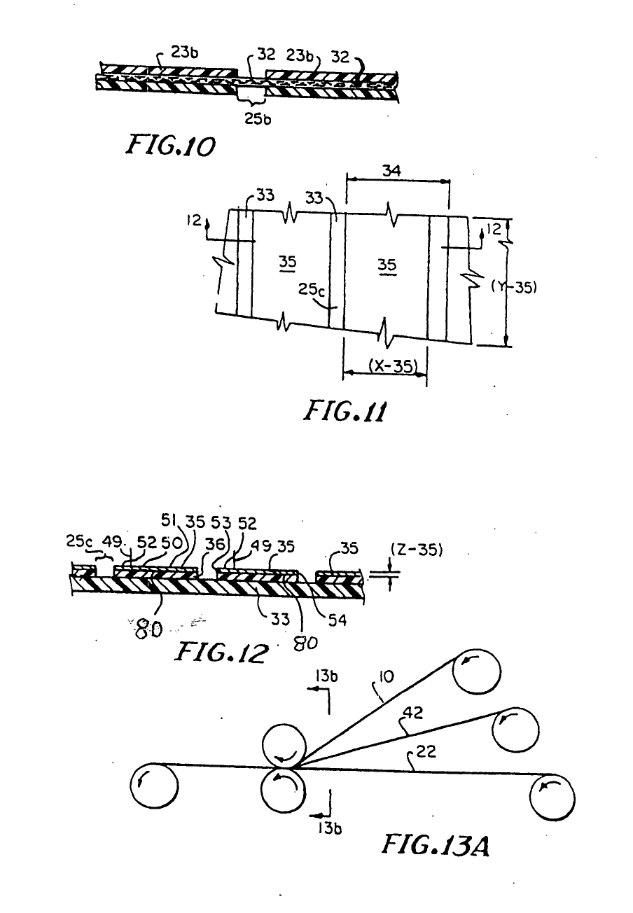

A further embodiment of fabrication of interconnection substrate structure 22 is illustrated in FIGS. 9 and 10. In FIG. 9, electrically conductive region 23b comprises electrically conductive polymer impregnated into a fabric or web 32. A number of known techniques can be used to achieve such impregnation. Insulating joining portion 25b in FIG. 9 is simply an un-impregnated extension of the web 32. Fabric or web 32 can be selected from a number of woven or non-woven fabrics, including non-polymeric materials such as fiberglass. Electrically conductive region 23b may also comprise fabric material comprising fibrils of conductive polymer or metal.

It is contemplated that electrically conductive regions 23 may comprise materials in addition to the electrically conductive polymer. For example, a metal may be electrodeposited to the electrically conductive polymer for increased conductivity. Electrodeposition is rapid, relatively inexpensive and allows choice of a wide variety of metal deposits. In addition, a wide range of metal thickness is possible using electrodeposition. Selection of thickness over a range from 0.1 to 200 micrometer (i.e. 0.1, 5, 10, 25, 100, 200. micrometer) is entirely reasonable. In this regard, the use of a directly electroplateable resin (DER) may be particularly advantageous as a component of regions 23. The electrically conductive regions 23 may also comprise materials functioning to assist in the ultimate assembly of the interconnected array. For example, portions of the top surface 26 of conductive region 23 may comprise a low melting point metal or alloy such as a solder. Alternatively, the top surface 26 may comprise a conductive adhesive. The purpose for such choices will become clear in light of the teachings to follow.

Referring now to FIG. 11, an alternate embodiment for the substrate structures of the present invention is illustrated. In the FIG. 11, a support web or film 33 extends among and supports multiple individual units, generally designated by repeat dimension 34. Electrically conductive regions 35 are analogous to conductive region 23 of FIGS. 6 through 10. Those skilled in the art will realize that conductive regions 35 may comprise bulk metal foil or a metal film deposited by techniques such as vacuum metal evaporation, sputtering or electroless chemical metal deposition. At the stage of overall manufacture illustrated in FIG. 11, electrically conductive regions 35 need not comprise an electrically conductive polymer as do conductive region 23 of FIGS. 6 through 10. However, as will be shown, electrically conducting means, often in the form of an electrically conductive polymer containing adhesive, may eventually be utilized to join photovoltaic cell 10 to the top surface 50 of electrically conductive regions 35. In addition, the electrically conducting regions 35 must be attached to the support web 33 with integrity required to maintain positioning and dimensional control. This may often be accomplished with an adhesive, indicated by layer 36 of FIG. 12.

Conductive regions 35 are shown in FIGS. 11 and 12 as having length Y-35, width X-35 and thickness Z-35. It is contemplated that length Y-35 may be considerably greater than width X-35. Often, length Y-35 may generally be described as “continuous” or being able to be processed in roll-to-roll fashion. Width X-35 defines a first terminal edge 53 and second terminal edge 54 of conductive region 35.

When using bulk metal foil for the conductive regions 35, Z-35 should be sufficient to allow for facile application to the support web 33. Optionally, such application may be accomplished using continuous processing. Typically when using metal based foils for conductive regions 35, thickness between 0.001 cm and 0.025 cm would be appropriate. When conductive regions 35 are applied using vacuum or chemical metal deposition techniques, smaller metal thickness for example 0.1 to 2.5 micrometer may be typical.

As with the substrate structures of FIGS. 6 through 10, it is helpful to characterize top surface 50 of conductive regions 35 as having a top collector region 51 and a top contact region 52 separated by an imaginary line 49. As with the embodiments of FIGS. 6 through 10, it may be useful to have portions of the top surface 50 be formed by a material such as a solder or conductive adhesive. Conductive region 35 also is characterized as having a bottom surface 78.

In the embodiments of FIGS. 6 through 12, conductive regions 23 and 35 and insulating regions 25 are shown to be substantially rectangular. This is indeed not necessary. It may be advantageous for example to have a more elaborate positioning of conductive and nonconductive regions. For example, it will be shown that having the conductive region comprise thin metal traces separated by an adhesive laminating film may produce specific and very novel advantages.

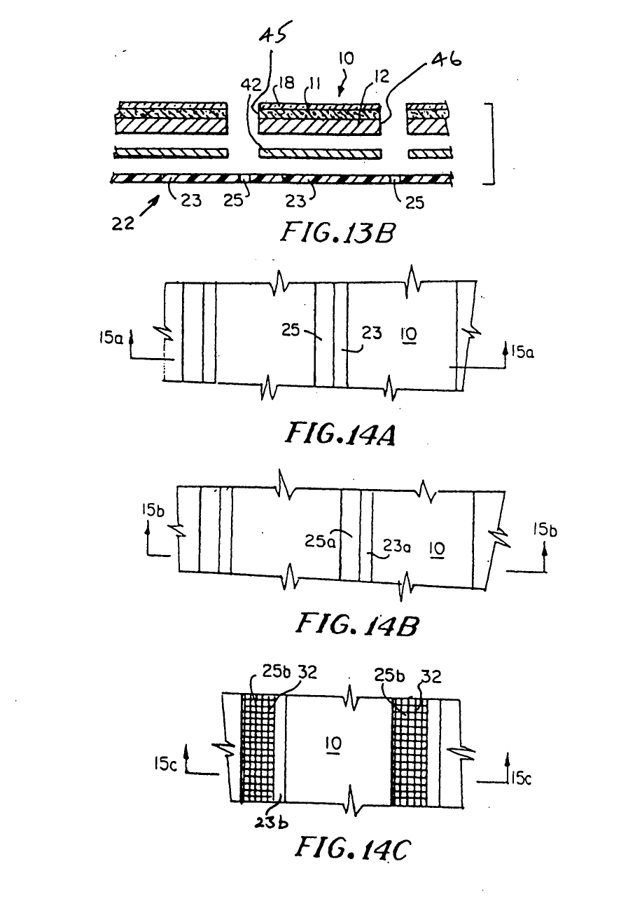

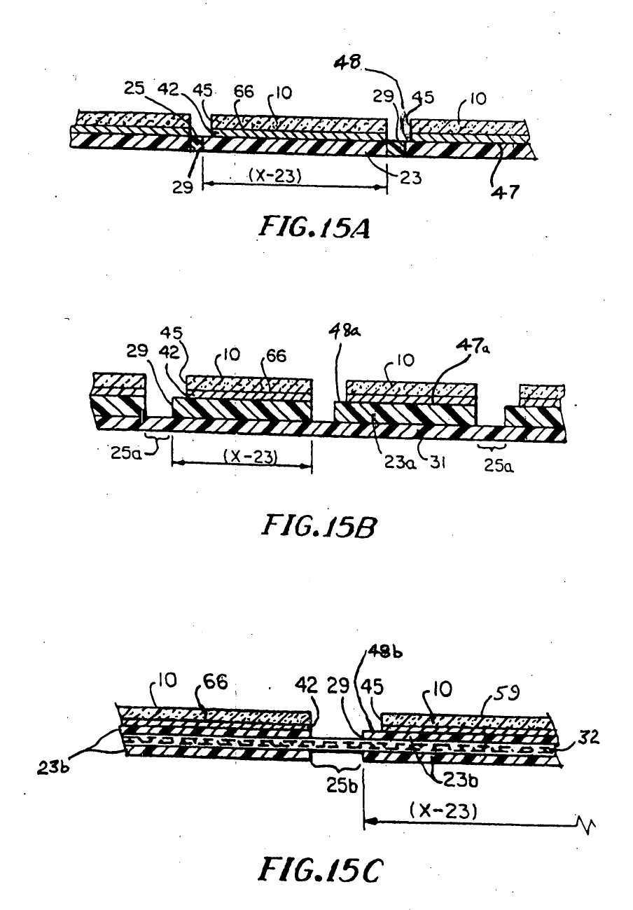

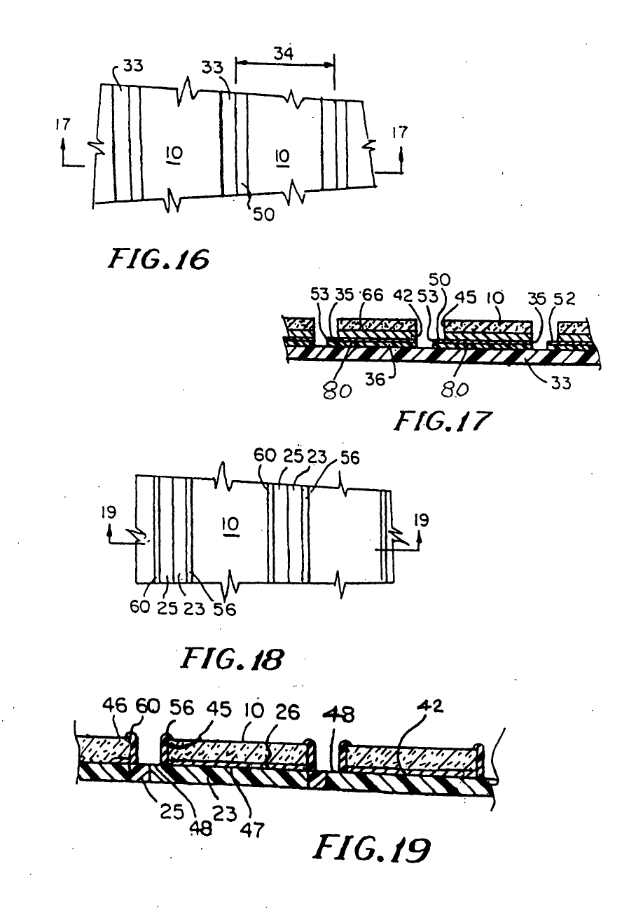

Referring now to FIGS. 13A and 13B, a process is shown for combining the metal-based foil supported thin film photovoltaic cell stock of FIGS. 1A, 2A and 2B to the substrate structures such as taught in FIGS. 6 through 12. FIGS. 14 and 15 embody the resulting articles. Specifically, in FIG. 13B the process of FIG. 13A is illustrated using the substrate structure of FIGS. 6 and 7. In FIGS. 13A and 13B, photovoltaic cell stock as illustrated in FIG. 2A is indicated by numeral 10. Interconnection substrate structures as taught in the FIGS. 6 through 12 are indicated by the numeral 22. Numeral 42 indicates a layer of electrically conductive adhesive intended to join electrically conductive metal-based foil 12 of FIG. 2A to electrically conductive region 23 of FIGS. 6 through 10 or electrically conductive regions 35 of FIGS. 11 and 12. It will be appreciated by those skilled in the art that the adhesive layer 42 shown in FIG. 13B is one of a number of appropriate conventional conductive joining techniques which would maintain required ohmic communication. For the purpose of the instant specification and claims, conductive joining comprises methods such as applying conductive resin adhesives, spot welding, soldering, joining with low melt temperature metals or alloys, crimping or pressure and mechanical surface contacts. These conductive joining methods would serve as alternate methods to accomplish the ohmic joining illustrated as achieved in FIGS. 13A and 13B with a layer of conductive adhesive. These methods can be generically referred to as conductive joining means.

One particularly suitable conductive joining means in this application is the use of inexpensive carbon filled conductive adhesives. These adhesives employ carbon material, such as graphite or conductive carbon black, as a filler. It is noted in the embodiments of FIGS. 13-15 that conductive adhesive layer 42 may extend over a broad surface region of mating surfaces 66 of foil 12 and 47 of conductive region 23. The thickness of adhesive layer 42 can also be small. Thus, despite the relatively high intrinsic resistivity of a carbon filled adhesive, actual resistive losses through the layer 42 are minimized. Carbon filled adhesives are relatively inexpensive and allow a wide choice of resin binders, possible curatives, adhesive characteristics and application techniques. For example, the carbon filled adhesive may be supplied as a tape, a hot melt bead or as a solution. They may be applied either prior or during processing to achieve final conductive joining of mating surfaces. Conductivity of such carbon filled adhesives may be augmented with additional more highly conductive fillers such as metal fibrils or metal powders and flake. Ohmic joining may also be enhanced using multiple conductive joining means such as a combination of carbon containing and silver containing adhesive regions.

Referring now to FIGS. 14 and 15, there is shown the result of the combination process of FIG. 13 using the interconnection substrate structures of FIGS. 6 through 10. In these and most subsequent figures, cells 10 are shown as a single layer for simplicity, but it is understood that in these figures cells 10 would have a structure similar to that shown in detail in FIG. 2A. FIGS. 14A and 15A correspond to the substrate structures of FIGS. 6 and 7. FIGS. 14B and 15B correspond to the substrate structure of FIG. 8. FIGS. 14C and 15C correspond to the substrate structures of FIGS. 9 and 10.

In the FIGS. 15A, 15B and 15C, electrically conductive adhesive layer 42 is shown as extending completely and contacting the entirety of the bottom surface 66 of metal-based foil supported photovoltaic cells 10. This complete surface coverage is not a requirement however, if metal foil 12 is highly conductive and able to distribute current over the expansive width X-10 with minimal resistance losses. In this case, should a highly conductive joining, such as soldering or use of a very highly conductive adhesive, be employed, the surface area of contact can be correspondingly reduced. For example, the structure of FIG. 22 shows an embodiment wherein electrical communication is achieved between conductive region 23 of FIGS. 6 and 7 and bottom surface 66 of foil 12 through a narrow bead of highly conductive joining means 61. An additional bead of adhesive shown in FIG. 22 by 44, may be used to ensure spacial positioning and dimensional support for this form of structure. Adhesive 44 need not be electrically conductive, and can be chosen from a variety of adhesive types of materials. For example, “hot melt” laminating adhesives, thermoset epoxies, elastomeric based solvent adhesives or so called “super glues” are examples of suitable non-conductive adhesives. Alternatively, the extensive area conductive joining embodied in FIGS. 15A, 15B and 15C may present distinct advantages. The extensive area of electrical contact permits the use of adhesive materials having relatively high intrinsic resistivity. For example, adhesives using reduced filler loading or using lower conductivity fillers such as carbon black can be considered. Consequently, broad selection of economical and versatile adhesive material binders and application techniques such as hot melt formulations can be considered.

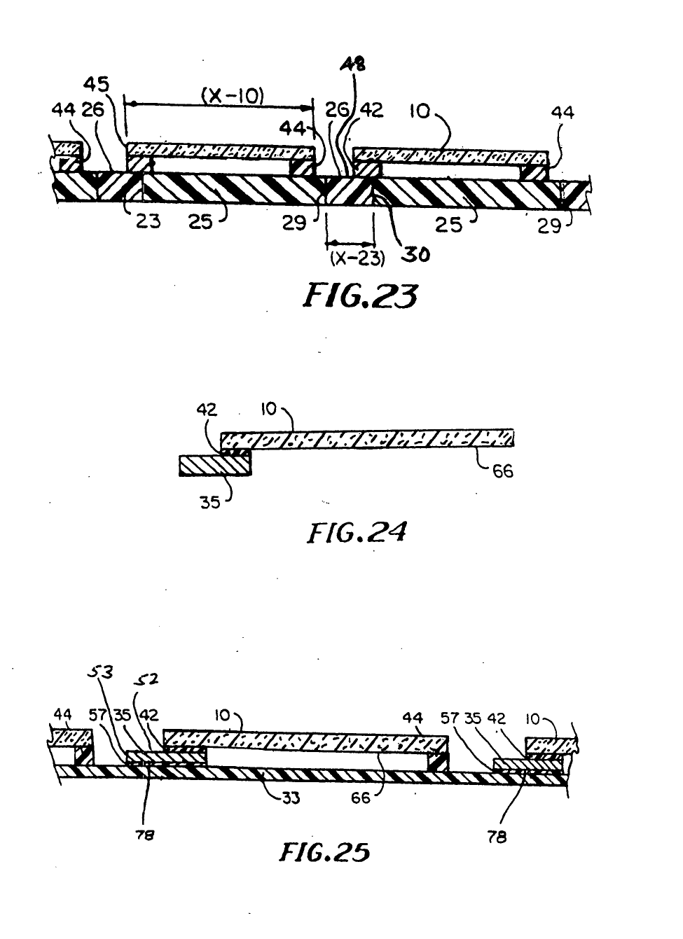

In the FIGS. 15A, 15B and 15C, the conductive regions 23, 23a and 23b are shown to be slightly greater in width X-23 than the width of cell X-10. As is shown in FIG. 23, this is not a requirement for satisfactory completion of the series connected arrays. FIG. 23 is a sectional view of a form of the substrate structures of FIGS. 6 and 7 laminated by the process of FIG. 13 to the photovoltaic cell stock of FIGS. 1A, 2A and 2B. In FIG. 23, width X-10 is greater than width X-23. Nevertheless, a structural feature of the FIG. 23 embodiment is that first conductive region terminal edge 29 is offset from a first photovoltaic cell terminal edge 45 to expose a portion of top surface 26 of conductive region 23. In the FIG. 23 embodiment, electrical communication is achieved through conductive adhesive 42 and additional adhesive 44 serves to achieve dimensional stability. As will be shown, the conductive adhesive shown in FIG. 23 may be replaced in other embodiments wherein the top surface of non-conductive region 25 comprises a material having adhesive affinity to the bottom surface of cell 10. In that case the adhesive surface of region 25 would be activated by the heat associated with a laminating process such as that of FIG. 13, securely holding the cell to the interconnecting substrate and producing a pressure contact between the abutting portions of conductive region 23 and bottom cell surface 66. The technique of producing electrical joining through lamination will be further taught in additional embodiments of the instant invention to follow.

Referring now to FIGS. 16 and 17, there is shown an alternate structure resulting from the laminating process of FIG. 13 as applied to the photovoltaic cell stock of FIGS. 1A, 2A and 2B and the substrate structure of FIGS. 11 and 12. In a fashion similar to that of FIGS. 15, 22, and 23, the first terminal edges 53 of conductive regions 35 supported by support web 33 are slightly offset from the first terminal edges 45 of photovoltaic cells 10. This offset exposes a portion of top surface 50 of conductive region 35. Electrical and mechanical joining of conductive region 35 with bottom surface 66 of metal-based foil 12 is shown in FIG. 17 as being achieved with conductive adhesive 42 as in previous embodiments. However, it is contemplated as in previous embodiments that this electrical and mechanical joining can be accomplished by alternate means such as soldering, joining with compatible low melting point alloys, spot welding, crimping or pressure induced contact such as may be produced by arranging laminating surfaces adjacent portions of conductive surface 50. This latter electrical joining through lamination will be taught in additional embodiments of the instant invention taught below.

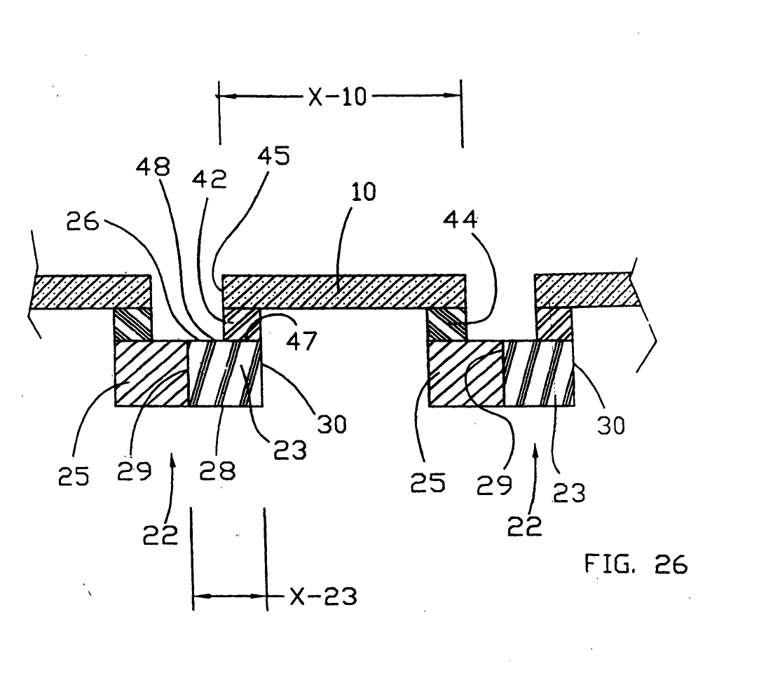

In FIG. 17, support web or film 33 is shown as extending continuously among many cells. However, it should be clear that support film 33 can be discontinuous. Support film 33 need only be attached to a portion of a first conductive region 35 and a portion of a second conductive region 35 of an adjacent cell. This arrangement would suffice to achieve the desired spacial positioning among cells and leave exposed a portion of bottom surface 78 of electrically conductive region 35. Similarly, interconnection substrate 22 may be discontinuous as embodied in FIG. 26.

Comparing the sectional views of FIGS. 15, 22, 23, and 26, one observes a common structural similarity being that the first terminal edges 29 of conductive regions 23 are offset slightly from first terminal edge 45 of photovoltaic cells 10. Similarly, first terminal edges 53 of conductive region 35 are slightly offset from first terminal edges 45 of photovoltaic cells 10 (FIG. 17). As will be shown, the remaining exposed top contact regions 48 and 52 are used as contact surfaces for the final interconnected array.

It should also be observed that the structures equivalent to those shown in FIGS. 16 and 17 can also be achieved by first joining photovoltaic cells 10 and conductive regions 35 with suitable electrically conductive joining means 42 to give the structure shown in FIG. 24 and laminating these strips to an insulating support web 33. An example of such an equivalent structure is shown in FIG. 25, wherein the laminates of FIG. 24 have been adhered to insulating support web 33 in defined repeat positions with adhesive means 57 and 44. As mentioned above and as shown in FIGS. 24 and 25, conductive regions 35 do not have to contact the whole of the bottom surface 66 of photovoltaic cell 10. In addition, support web 33 need not be continuous among all the cells. The support web 33 need only extend from the adhesive means 57 of one cell to the adhesive attachment 44 of an adjacent cell. This arrangement would leave a portion of the bottom surface 66 of foil 12, and perhaps a portion of the bottom surface 78 of conductive region 35 exposed.

Referring now to FIGS. 18 and 19, insulating beads 56 and 60 of insulating material having been applied to the first and second terminal edges 45 and 46 respectively of photovoltaic cells 10. While these beads 56 and 60 are shown as applied to the structure of FIG. 15a, it is understood that appropriate beads of insulating material are also envisioned as a subsequent manufacturing step for the structures of FIGS. 15b, 15c, 17, 22, 23, 25, and 26. Further, one readily recognizes that such insulating beads could be applied to individual cell terminal edges 45 and 46 prior to application of cells 10 to substrate 22. The purpose of the insulating beads is to protect the edge of the photovoltaic cells from environmental and electrical deterioration. In addition, as will be shown the insulating bead allows for certain electrical interconnections to be made among adjacent cells without electrical shorting.

It is noted that the insulating bead 56 at first terminal edge 45 of photovoltaic cells 10 defines two regions of the top surfaces 26 and 50 of conductive regions 23 and 35 respectively. The first region (region 48 of surface 26 or region 52 of surface 50) can be considered as a contact region for series interconnects among adjacent cells. The second region (region 47 of surface 26 or region 51 of surface 50) can be considered as the contact region for interconnecting the substrate to the bottom surface 66 of photovoltaic cells 10. Thus insulating beads 56 give substance to the imaginary lines 49 of FIGS. 7 and 12.

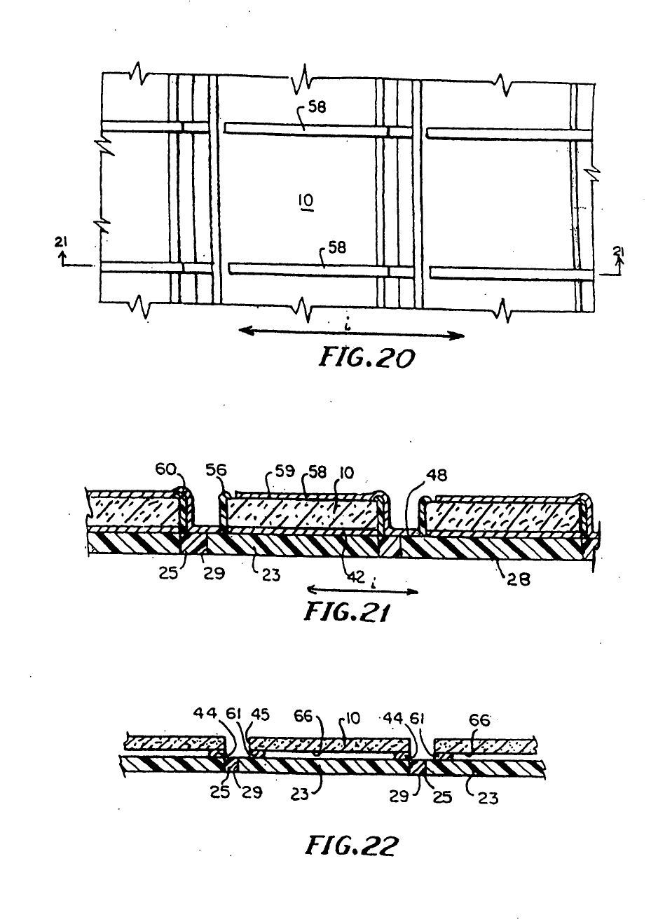

Referring now to FIGS. 20 and 21, there is shown one method of forming the final interconnected array. Grid fingers 58 of an electrically conductive material are deposited to achieve electrical communication between the top surface 59 of the photovoltaic cell 10 and the remaining exposed contact regions 48 or 52 of an adjacent cell. It is contemplated that these fingers can be deposited by any of a number of processes to deposit metal containing or metal-based foils or films, including masked vacuum deposition, printing of conductive inks, electrodeposition or combinations thereof. In the embodiments of FIGS. 20 and 21, the net current flow among cells will be understood by those skilled in the art to be in the direction of the double pointed arrow labeled “i” in the figures.

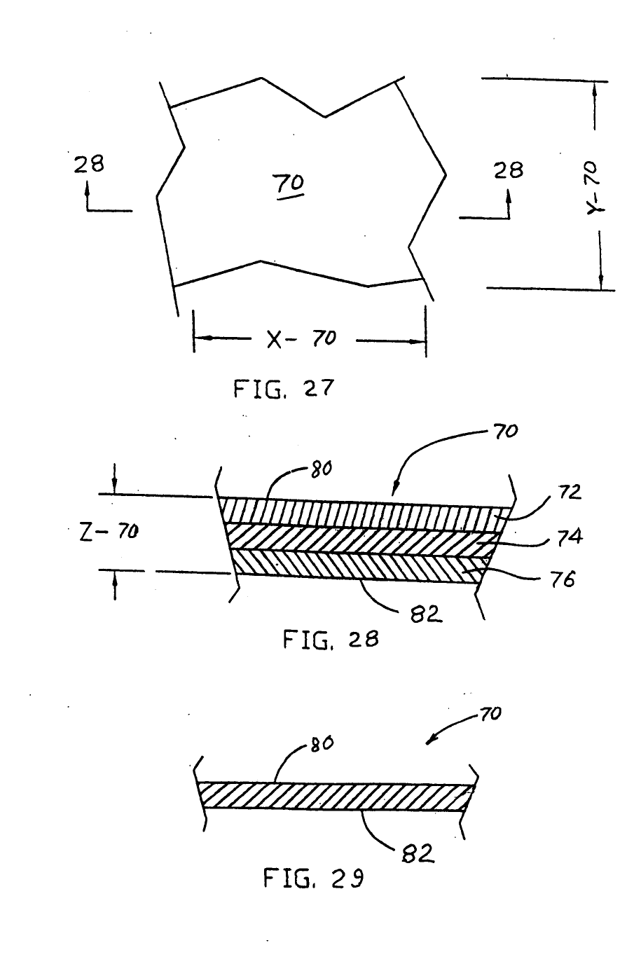

The current collector grid/interconnect structures produced by directly applying conductive inks or metal extending from the cell surface 59 to an adjacent contact surface 48 as described for the embodiment of FIGS. 20 and 21 are conceptually simple. Nevertheless, it has been discovered that separate production of a grid/interconnect structure followed by subsequent application to a geometrically registered arrangement of photovoltaic cells may be employed to advantage. This concept would avoid masking, possible exposure of the photovoltaic cells to wet electrochemistry, or laborious handling, printing or wiring of grid patterns onto individual unprotected cells. Thus, a further embodiment of a current collector grid structure, design and fabrication process is taught below in conjunction with FIGS. 27 through 43. It is emphasized that many of the principles taught in detail with reference to FIGS. 27 through 43 extend to additional embodiments of the invention taught in subsequent Figures.

FIG. 27 is a top plan view of a starting article in production of a laminating current collector grid or electrode according to the instant invention. FIG. 27 embodies a polymer based film or glass substrate 70. Substrate 70 has width X-70 and length Y-70. In embodiments, taught in detail below, Y-70 may be much greater than width X-70, whereby film 70 can generally be described as “continuous” in length and able to be processed in length direction Y-70 in a continuous roll-to-roll fashion. FIG. 28 is a sectional view taken substantially from the view 28-28 of FIG. 27. Thickness dimension Z-70 is small in comparison to dimensions Y-70, X-70 and thus substrate 70 may have a flexible sheetlike, or web structure contributing to possible roll-to-roll processing. As shown in FIG. 28, substrate 70 may be a laminate of multiple layers 72, 74, 76 etc. or may comprise a single layer of material. Any number of layers 72, 74, 76 etc. may be employed. The layers 72, 74, 76 etc. may comprise inorganic or organic components such as thermoplastics, thermosets or silicon containing glass-like layers. The various layers are intended to supply functional attributes such as environmental barrier protection or adhesive characteristics. Such functional layering is well-known and widely practiced in the plastic packaging art. Sheetlike substrate 70 has first surface 80 and second surface 82. In particular, in light of the teachings to follow, one will recognize that it may be advantageous to have layer 72 forming surface 80 comprise a sealing material such as an ethylene vinyl acetate (EVA), ethylene ethyl acetate (EEA), an ionomer, or a polyolefin based adhesive for adhesive characteristics during a possible subsequent lamination process. Lamination of such sheetlike films employing such sealing materials is a common practice in the packaging industry. In the packaging industry lamination is known and understood as applying a film, normally polymer based, to a surface and sealing them together with heat and/or pressure. Suitable sealing materials may be made tacky and flowable, often under heated conditions, and retain their adhesive bond to many surfaces upon cooling. A wide variety of laminating films with associated sealing materials is available, depending on the surface to which the adhesive seal or bond is to be made. Sealing materials such as olefin copolymers or atactic polyolefins may be advantageous, since these materials allow for the minimizing of materials which may be detrimental to the longevity of the solar cell with which it is in contact. Additional layers 74, 76 etc. may comprise materials which assist in support or processing such as polypropylene and polyethylene terepthalate. Additional layers 74, 76 may comprise barrier materials such as fluorinated polymers, biaxially oriented polypropylene (BOPP), poly(vinylidene chloride), such as Saran, a product of Dow Chemical, and Siox. Saran is a tradename for poly (vinylidene chloride) and is manufactured by Dow Chemical Corporation. Siox refers to a vapor deposited thin film of silicon oxide often deposited on a polymer support. Additional layers 74, 76 etc. may also comprise materials intended to afford protection against ultraviolet radiation and may also comprise materials to promote curing. The instant invention does not depend on the presence of any specific material for layers 72, 74, or 76. Substrate 70 may be generally referred to as a laminating material. For example, the invention has been successfully demonstrated using standard laminating films sold by GBC Corp., Northbrook, Ill., 60062.

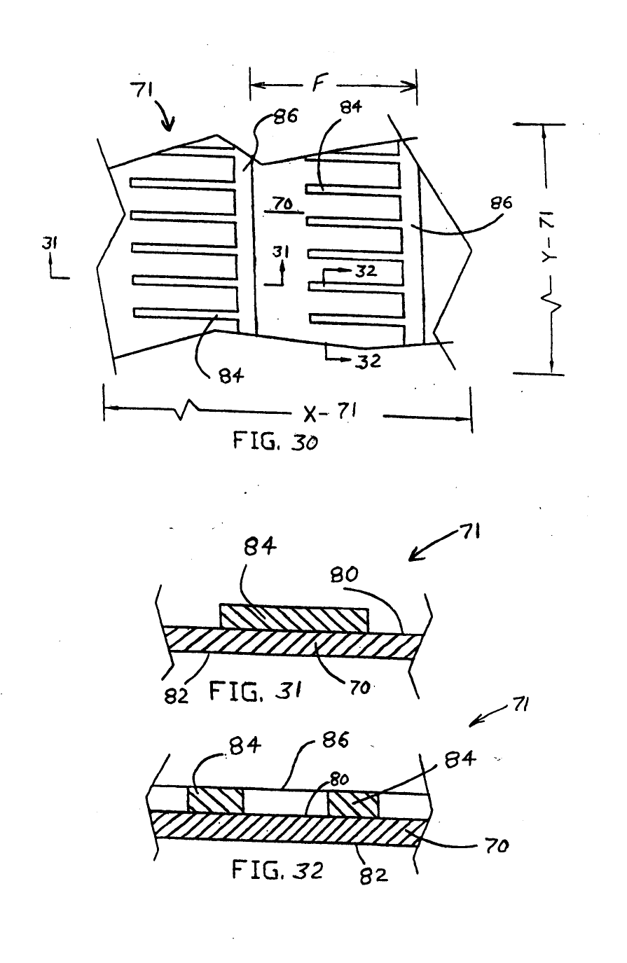

FIG. 29 depicts the structure of substrate 70 (possibly laminate) as a single layer for purposes of presentation simplicity. Substrate 70 will be represented as this single layer in the subsequent embodiments, but it will be understood that structure 70 may be a laminate of any number of layers. In addition, substrate 70 is shown in FIGS. 27 through 29 as a uniform, unvarying monolithic sheet. In this specification and claims, the term “monolithic” or “monolithic structure” is used as is common in industry to describe an object that is made or formed into or from a single item. However, it is understood that selected regions of substrate 70 may comprise differing sheetlike structures patched together using appropriate seaming techniques. A purpose for such a “patchwork” structure will become clear in light of the teachings to follow.

FIG. 30 is a plan view of the structure following an additional manufacturing step.

FIG. 31 is a sectional view taken along line 31-31 of FIG. 30.

FIG. 32 is a sectional view taken along line 32-32 of FIG. 30.

In FIGS. 30, 31, and 32, the structure is now designated 71 to reflect the additional processing. It is seen that a pattern of “fingers” or “traces”, designated 84, extends from “buss” or “tab” structures, designated 86. In the embodiments of FIGS. 30, 31 and 32, both “fingers” 84 and “busses” 86 are positioned on supporting substrate 70 in a grid pattern. “Fingers” 84 extend in the width X-71 direction of article 71 and “busses” (“tabs”) extend in the Y-71 direction substantially perpendicular to the “fingers”. As suggested above, structure 71 may be processed and extend continuously in the length “Y-71” direction. Repetitive multiple “finger/buss” arrangements are shown in the FIG. 30 embodiment with a repeat dimension “F” as indicted. Portions of substrate 70 not overlayed by “fingers” 84 and “busses” 86 remain transparent or translucent to visible light. In the embodiment of FIGS. 30 through 32, the “fingers” 84 and “busses” 86 are shown to be a single layer for simplicity of presentation. However, the “fingers” and “busses” can comprise multiple layers of differing materials chosen to support various functional attributes. For example the material in direct contact with substrate 70 defining the “buss” or “finger” patterns may be chosen for its adhesive affinity to surface 80 of substrate 70 and also to a subsequently applied constituent of the buss or finger structure. Further, it may be advantageous to have the first visible material component of the fingers and busses be of dark color or black. As will be shown, the light incident side (outside surface) of the substrate 70 will eventually be surface 82. By having the first visible component of the fingers and busses be dark, they will aesthetically blend with the generally dark color of the photovoltaic cell. This eliminates the often objectionable appearance of a metal colored grid pattern. Permissible dimensions and structure for the “fingers” and “busses” will vary somewhat depending on materials and fabrication process used for the fingers and busses, and the dimensions of the individual cell.

“Fingers” 84 and “busses” 86 may comprise electrically conductive material. Examples of such materials are metal wires and foils, conductive metal containing inks and pastes such as those having a conductive filler comprising silver, patterned deposited metals such as etched metal patterns or masked vacuum deposited metals, intrinsically conductive polymers and DER formulations. In a preferred embodiment, the “fingers and “busses” comprise electroplateable material such as DER or an electrically conductive ink which will enhance or allow subsequent metal electrodeposition. “Fingers” 84 and “busses” 86 may also comprise non-conductive material which would assist accomplishing a subsequent deposition of conductive material in the pattern defined by the “fingers” and “busses”. For example, “fingers” 84 or “busses” 86 could comprise a polymer which may be seeded to catalyze chemical deposition of a metal in a subsequent step. An example of such a material is seeded ABS. Patterns comprising electroplateable materials or materials facilitating subsequent electrodeposition are often referred to as “seed” patterns or layers. “Fingers” 84 and “busses” 86 may also comprise materials selected to promote adhesion of a subsequently applied conductive material. “Fingers” 84 and “busses” 86 may differ in actual composition and be applied separately. For example, “fingers” 84 may comprise a conductive ink while “buss/tab” 86 may comprise a conductive metal foil strip. Alternatively, fingers and busses may comprise a continuous unvarying monolithic material structure forming portions of both fingers and busses. Fingers and busses need not both be present in certain embodiments of the invention.

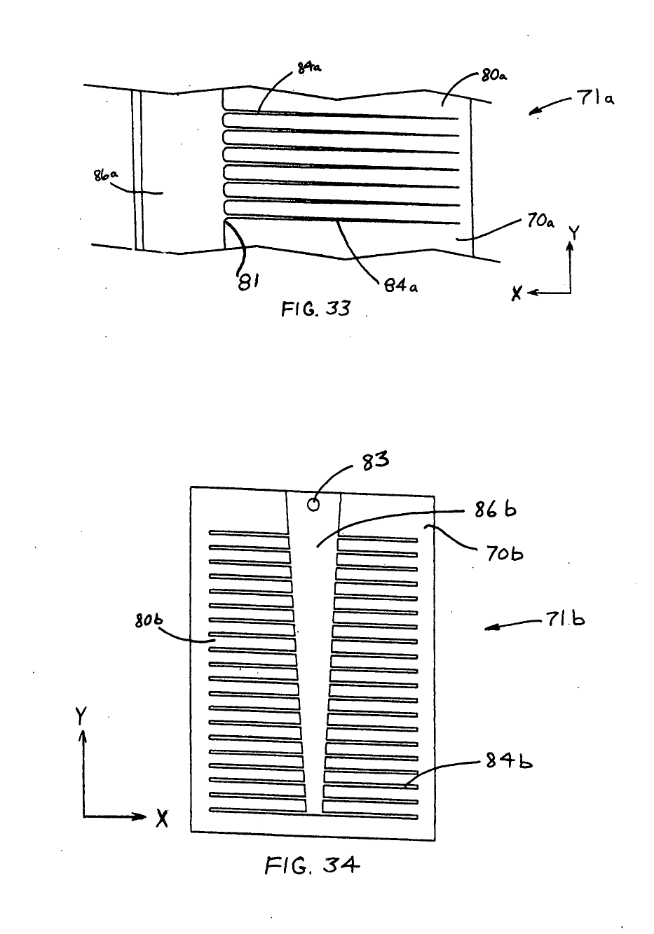

One will recognize that while shown in the embodiments as a continuous void free surface, “buss” 86 could be selectively structured. Such selective structuring may be appropriate to enhance functionality, such as flexibility, of article 71 or any article produced therefrom. Furthermore, regions of substrate 70 supporting the “buss” regions 68 may be different than those regions supporting “fingers” 84. For example, substrate 70 associated with “buss region” 86 may comprise a fabric while substrate 70 may comprise a film devoid of thru-holes in the region associated with “fingers” 84. A “holey” structure in the “buss region” would provide increased flexibility, increased surface area and increased structural characteristic for an adhesive to grip. Moreover, the embodiments of FIGS. 30 through 32 show the “fingers” and “busses” as essentially planar rectangular structures. Other geometrical forms are clearly possible, especially when design flexibility is associated with the process used to establish the material pattern of “fingers” and “busses”. “Design flexible” processing includes printing of conductive inks or “seed” layers, foil etching, masked deposition using paint or vacuum deposition, and the like. For example, these conductive paths can have triangular type surface structures increasing in width (and thus cross section) in the direction of current flow as embodied in article 71a of FIG. 33 for “fingers” 84a. Thus the resistance decreases as net current accumulates to reduce power losses. Alternatively, one may select more intricate patterns, such as a “watershed” pattern as described in U.S. Patent Application Publication 2006/0157103 A1 which is hereby incorporated in its entirety by reference. Various structural features, such as the radiused connections between fingers and busses shown at 81 in FIG. 33, may be employed to improve structural robustness.

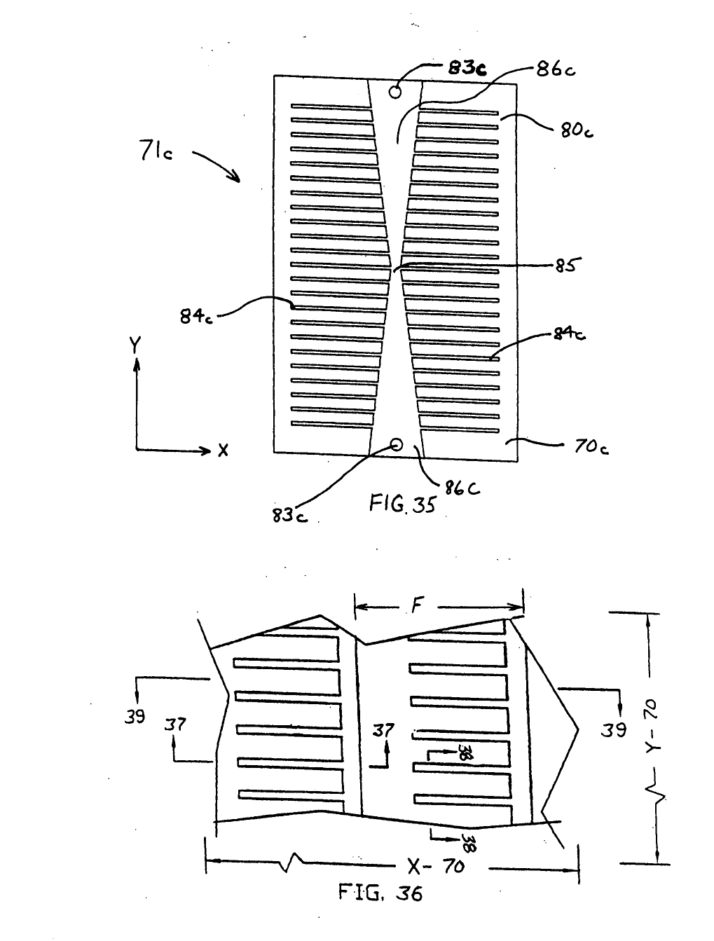

The embodiment of FIG. 30 shows multiple “busses” 86 extending in the direction Y-71 with “fingers” extending from one side of the “busses” in the X-71 direction. As will be later explained, this arrangement of conductive material on substrate 70 is very suitable to achieve interconnections among certain forms of cells. However, numerous other structural configurations may be appropriate for the current collecting structures arranged on sheetlike substrate 70. FIGS. 34 and 35 embody alternate structural forms for the “busses” and “fingers”. The top plan view of FIG. 34 shows article 71b having “fingers” 84b extending outward from both sides of a central “buss” artery 86b. In the FIG. 34 embodiment, current is collected by the extending “fingers” 84b and transported to a “buss” artery 86b. “Buss” artery 86b conveys current to a collection point 83 whose location may be vicinal the edge of a conductive surface to which support substrate 70 is laminated as explained below. The FIG. 34 article can be positioned such that collection point 83 is slightly outside a peripheral boundary of a mating conductive surface in order to give free access to buss artery 86b. Alternatively, collection point 83 may constitute a through hole whereby electrical communication may be established to the opposite surface of the article 71b. Embodiments of such through hole electrical communication are taught in detail in conjunction with the FIGS. 56 through 64 to follow. While not shown in the FIG. 34, the “buss” artery may be extended to reach an electrode of an adjacent cell. This extension may be accomplished by electrically joining a separate extension portion, or by extending the “buss” artery with a continuous and monolithic extension of material forming “buss” 86b. “Buss” artery 86b has variable width along its length for reasons explained above. Compared to the structure of FIG. 30, article 71b of FIG. 34 may be expected to allow increasing the “X” dimension (indicated in the figures) of an individual mating conductive surface such as surface 59 of a photovoltaic cell. One notes that multiple articles 71b may be produced in bulk using continuous web processing of substrate 70b in a fashion similar to that for described for production of article 71 of FIGS. 30 through 32. In this case one has the option of applying the bulk array of articles 71b to an expansive surface of cell structure as depicted in FIGS. 1 and 2 and subdividing to individual unit cells having current collector already attached. Electrical access to the current collector structure of the individual cells could be achieved using through holes as taught above or alternately by simply lifting the buss away from the cell surface at the cut edge.

FIG. 35 is a top plan view of another embodiment showing “fingers” 84c extending outward from both sides of a central “buss” artery 86c. In the FIG. 35 embodiment the “buss” 86c is shown to increase in width both upwardly and downwardly (in the drawing) from point 85, but one will understand that the buss width may be constant. The “fingers” 84c transport collected current to the “buss” 86c and the buss conveys that current upwardly or downwardly (in the drawing perspective), depending on location of the intersection of a particular finger with the buss. In the embodiment of FIG. 35, two collection points are shown at 83c. As with the article 71b of FIG. 34, collection points 83c may constitute through holes whereby electrical communication may be established to the opposite surface of article 71c. Multiple articles 71c may be produced in bulk using continuous processing of substrate 70c. Compared to the FIG. 34 embodiment, the FIG. 35 embodiment may allow increasing the “Y” dimension as shown of a mating conductive surface. Thus, many different such structural arrangements of the laminating current collector structures are possible within the scope and purview of the instant invention. It is important to note however that embodiments such as those of FIGS. 30 through 39 may be manufactured utilizing continuous, bulk roll to roll processing.

While the collector grid embodiments of the current invention may advantageously be produced using continuous processing, one will recognize that combining of grids or electrodes so produced with mating conductive surfaces may be accomplished using either continuous or batch processing. In one case it may be desired to produce photovoltaic cells having discrete defined dimensions. For example, single crystal silicon cells are often produced having X-Y dimensions of 6 inches by 6 inches. In this case the collector grids of the instant invention, which may be produced continuously, may then be subdivided to dimensions appropriate for combining with such cells. In other cases, such as production of many thin film photovoltaic structures, a continuous roll-to-roll production of an expansive surface article can be accomplished in the “Y” direction as identified in FIG. 1. Such a continuous expansive photovoltaic structure may be combined with a continuous arrangement of collector grids of the instant invention in a semicontinuous or continuous manner. Alternatively the expansive semiconductor structure may be subdivided into continuous strips of cell stock. In this case, combining a continuous strip of cell stock with a continuous strip of collector grid of the instant invention may be accomplished in a continuous or semi-continuous manner.

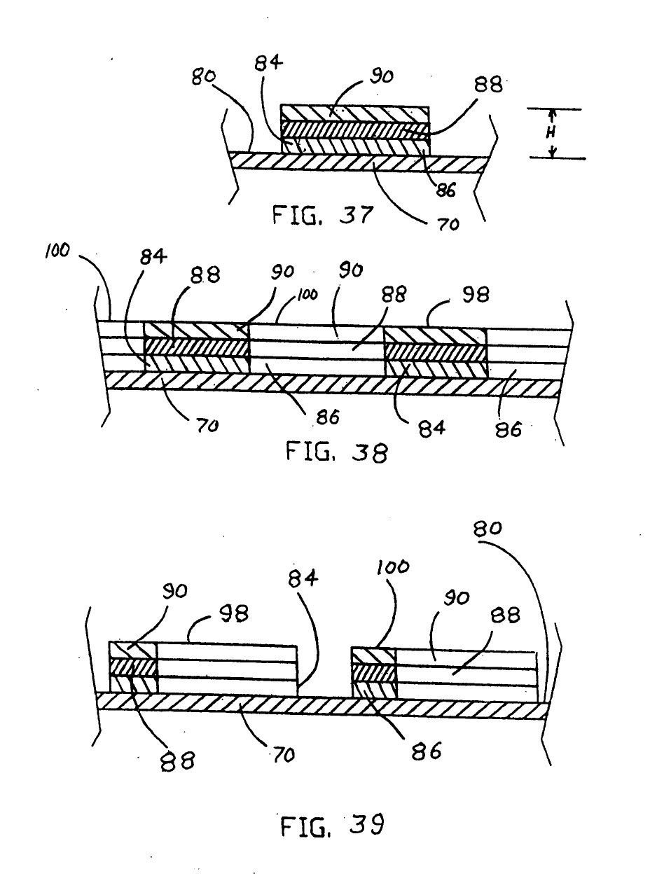

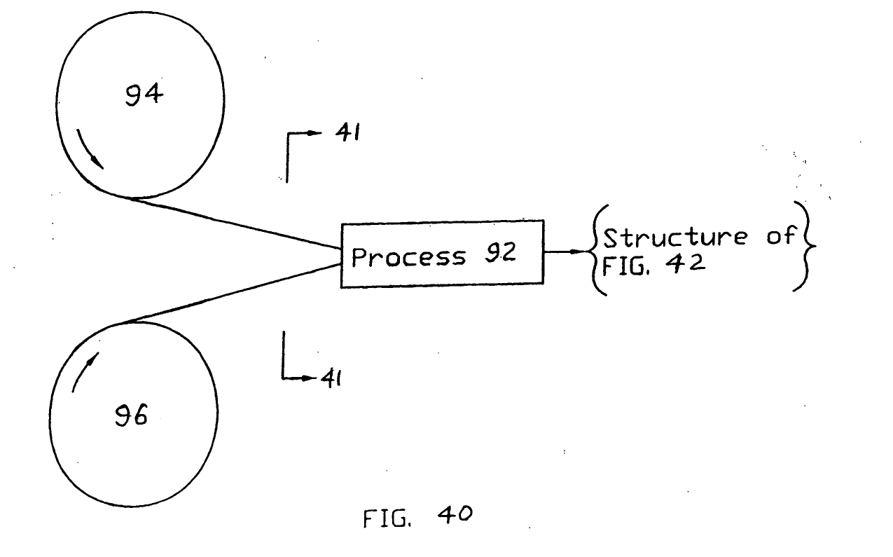

FIGS. 36, 37 and 38 correspond to the views of FIGS. 30, 31 and 32 respectively following an additional optional processing step. FIG. 39 is a sectional view taken substantially along line 39-39 of FIG. 36. One will understand that similar optional additional processing may be performed on the structural embodiments of FIGS. 33 through 35. FIGS. 36 through 39 show additional conductive material deposited onto the “fingers” 84 and “busses” 86 of FIGS. 30 through 32. In this embodiment additional conductive material is designated by one or more layers 88, 90 and the fingers and busses project above surface 80 as shown by dimension “H”. In some cases it may be desirable to reduce the height of projection “H” prior to eventual combination with a conductive surface such as 59 or 66 of photovoltaic cell 10. This reduction may be accomplished by passing the structures as depicted in FIGS. 37-39 through a pressurized and/or heated roller or the like to embed “fingers” 84 and/or “busses” 86 into layer 72 of substrate 70.

While shown as two layers 88, 90, it is understood that this conductive material could comprise more than two layers or be a single layer. In addition, while each additional conductive layer is shown in the embodiment as having the same continuous monolithic material extending over both the buss and finger patterns, one will realize that selective deposition techniques would allow the additional “finger” layers to differ from additional “buss” layers. For example, as best shown in FIG. 38, “fingers” 84 have top free surface 98 and “busses” 86 have top free surface 100. As noted, selective deposition techniques such as brush electroplating or masked deposition would allow different materials to be considered for the “buss” surface 100 and “finger” surface 98. In a preferred embodiment, at least one of the additional layers 88, 90 etc. are deposited by electrodeposition, taking advantage of the deposition speed, compositional choice, low cost and selectivity of the electrodeposition process. Many various metals, including highly conductive silver, copper and gold, nickel, tin and alloys can be readily electrodeposited. In these embodiments, it may be advantageous to utilize electrodeposition technology giving an electrodeposit of low tensile stress to prevent curling and promote flatness of the metal deposits. In particular, use of nickel deposited from a nickel sulfamate bath, nickel deposited from a bath containing stress reducing additives such as brighteners, or copper from a standard acid copper bath have been found particularly suitable. Electrodeposition also permits precise control of thickness and composition to permit optimization of other requirements of the overall manufacturing process for interconnected arrays. Alternatively, these additional conductive layers may be deposited by selective chemical deposition or registered masked vapor deposition. These additional layers 88, 90 may also comprise conductive inks applied by registered printing.

It has been found very advantageous to form surface 98 of “fingers” 84 or top surface 100 of “busses” 86 with a material compatible with the conductive surface with which eventual contact is made. In preferred embodiments, electroless deposition or electrodeposition is used to form a suitable metallic surface. Specifically electrodeposition offers a wide choice of potentially suitable materials to form the top surface. Corrosion resistant materials such as nickel, chromium, tin, indium, silver, gold and platinum are readily electrodeposited. When compatible, of course, surfaces comprising metals such as copper or zinc or alloys of copper or zinc may be considered. Alternatively, the surface 98 may comprise a conversion coating, such as a chromate coating, of a material such as copper or zinc. Further, as will be discussed below, it may be highly advantageous to choose a material to form surfaces 98 or 100 which exhibits adhesive or bonding ability to a subsequently positioned abutting conductive surface. For example, it may be advantageous to form surfaces 98 and 100 using an electrically conductive adhesive. Alternatively, it may be advantageous to form surface 100 of “busses” 86 with a conductive material such as a low melting point alloy solder in order to facilitate electrical joining to a complimentary conductive surface having electrical communication with an electrode of an adjacent photovoltaic cell. One will note that materials forming “fingers” surface 98 and “buss” surface 100 need not be the same.

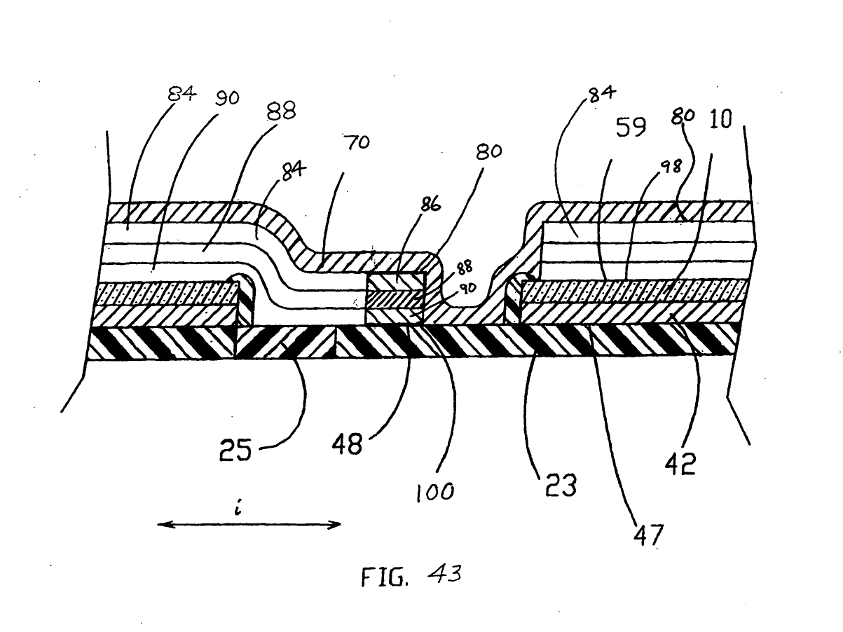

FIGS. 40 through 43 illustrate a process 92 by which the current collector grids of FIGS. 30 through 39 are combined with the structure illustrated in FIG. 19 to accomplish series interconnections among geometrically spaced cells. Process 92 is but one of many processes possible to achieve interconnections. Those skilled in the art will also readily recognize, in light of this and teachings to follow that parallel connections may also be achieved using the laminating electrodes of the invention. In FIG. 40 roll 94 represents a “continuous” feed roll of grid/buss structure on the flexible sheetlike substrate as depicted in FIGS. 30 through 32 or optionally 36 through 39. Roll 96 represents a “continuous” feed roll of the sheetlike geometrical arrangement of cells depicted in FIG. 19. As indicated in FIGS. 40 through 43, process 92 combines these two sheetlike structures together in a spacial arrangement wherein the grid “fingers” 84 project laterally across the top surface 59 of cells 10 and the “finger/buss” structure extends to the top contact surface 48 associated with an adjacent cell unit. The process 92 normally involves application of heat and pressure. Temperatures of up to 600 degree F. are envisioned. Lamination temperatures of less than 600 degree F. would be more than sufficient to melt and activate not only typical sealing materials but also many low melting point alloys and metallic solders. For example, tin melts at about 450 degree F. and its alloys even lower. Many conductive “hot melt” adhesives can be activated at even lower temperatures such as 300 degree F. Typical thermal curing temperatures for polymers are in the range 200 to 350 degree F. Thus, typical lamination practice is normally appropriate to simultaneously accomplish many conductive joining possibilities. As with prior embodiments, the double pointed arrow labeled “i” indicates the direction of net current flow in the embodiments of FIGS. 42 and 43.

In the embodiments of FIGS. 42 and 43, electrical joining between conductive material 90 of “buss” 86 and top contact region 48 of conductive region 23 is made through an appropriate electrical joining method (not shown in FIGS. 42 and 43). Some of these methods were referred to herein above. For example should contact surface region 48 of conductive region 23 be formed by a low-melting point solder such as tin or a tin based alloy, and material 90 forming buss portion 86 comprise a compatible solderable material, the electrical joining could be readily achieved through a robust solder connection. It is noted that while designated by the same numeral 90, additional conductive material “90” associated with the buss and fingers may be different. This could be achieved by selective deposition such as brush plating.

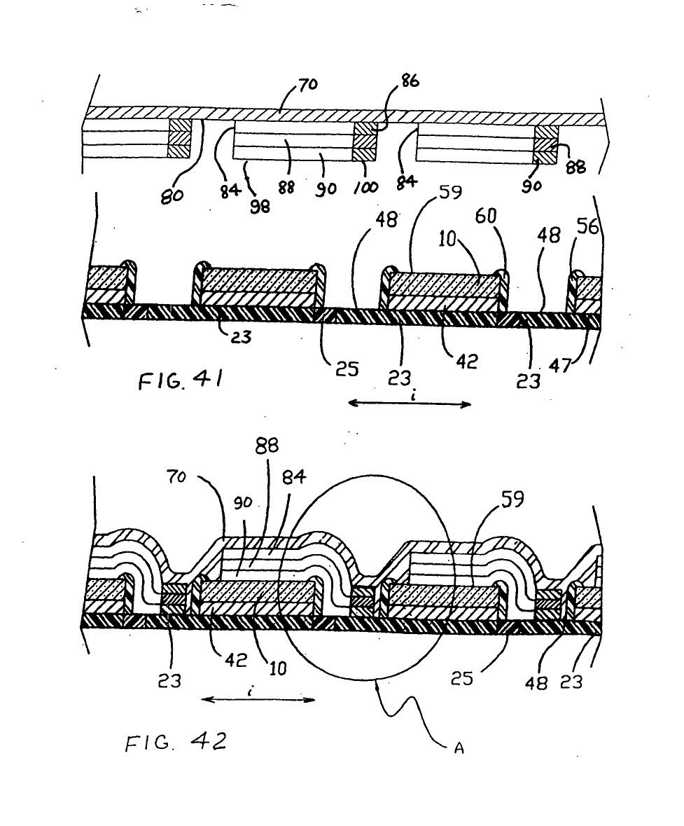

A series interconnection between adjacent cells is depicted in greatly magnified form in FIG. 43, magnifying the encircled region “A” of FIG. 42. In the embodiments of FIGS. 42 and 43, “buss” structure (86,88,90) is shown to extend in the “continuous” Y direction of the laminated structure (direction normal to the paper). It will be appreciated by those skilled in the art that the only electrical requirement to achieve proper interconnection of the cells is that the grid “fingers” (84,88,90) extend to the contact surface 48 associated with an adjacent cell. However, in those cases where the grid fingers comprise an electrodeposit, inclusion of the “busses” provides a convenient way to pass electrical current by providing a continuous path from the rectified current source during electroplating to the individual grid “fingers”. This facilitates the electrodeposition of layers 88, 90 etc. onto the originally deposited “finger” and “buss” patterns 84 and 86. Those skilled in the art will recognize that if the grid “fingers” comprise material deposited by selective chemical, masked vapor deposition or printing, the grid “fingers” could constitute individual islands and the “buss” structure might be eliminated for certain embodiments. In alternate embodiments, it may be appropriate to have a structure consisting of a current collecting buss absent extending fingers. Thus, while the embodiment of FIGS. 41-43 depicts both fingers and busses either of these structures might be eliminated in alternate embodiments.

In the present specification lamination will be shown as a means of combining the collector grid or electrode structures with a conductive surface. However, one will recognize that other application methods to combine the grid or electrode with a conductive surface may be appropriate such as transfer application processing. For example, in the embodiments of FIGS. 42 and 43 substrate 70 is shown to remain in its entirety as a component of the final interconnected array. This is not a requirement. In other embodiments, all or a portion of substrate 70 may be removed following the laminating process to accomplish positioning and attachment of “fingers” 84 and “busses” 86 to form the interconnected array. In this case, a suitable release material (not shown) may be used to facilitate separation of the conductive collector electrode structure from a removed portion of substrate 70 during or following an application such as the lamination process depicted in FIG. 40. Thus, in this embodiment the removed portion of substrate 70 would serve as a surrogate or temporary support to initially manufacture and transfer the grid or electrode structure to the desired conductive surface. One example would be that situation where layer 76 of FIG. 28 would remain with the final interconnected array while layers 72 and/or 74 would be removed.

Those skilled in the art will recognize that contact between the top surface 59 of the cell (or other conductive surface) and the mating surface 98 of the grid finger will be achieved by ensuring good adhesion between first surface 80 of substrate 70 and the mating conductive surface, such as surface 59 of the cell, in those regions where surface 80 is not covered by the grid. In this case the flexible laminating composite substrate 70 acts as an adhesive blanket to hold the conductive fingers tightly against the surface 59.

Using such a laminating approach to secure the conductive grid materials to a conductive surface involves some design and performance “tradeoffs”. For example, if the electrical trace or path “finger” 84 comprises a wire form, it has the advantage of potentially reducing light shading of the surface (at equivalent current carrying capacity) in comparison to a substantially flat electrodeposited, printed or etched foil member. However, the relatively higher profile for the wire form must be addressed. It has been taught in the art that wire diameters as small as 50 micrometers (0.002 inch) can be assembled into grid like arrangements. Thus when laid on a flat surface such a wire would project above the surface 0.002 inches. For purposes of this instant specification and claims, a structure projecting above a surface less than 0.002 inches will be defined as a low-profile structure. Often a low profile structure may be further characterized as having a substantially flat surface.

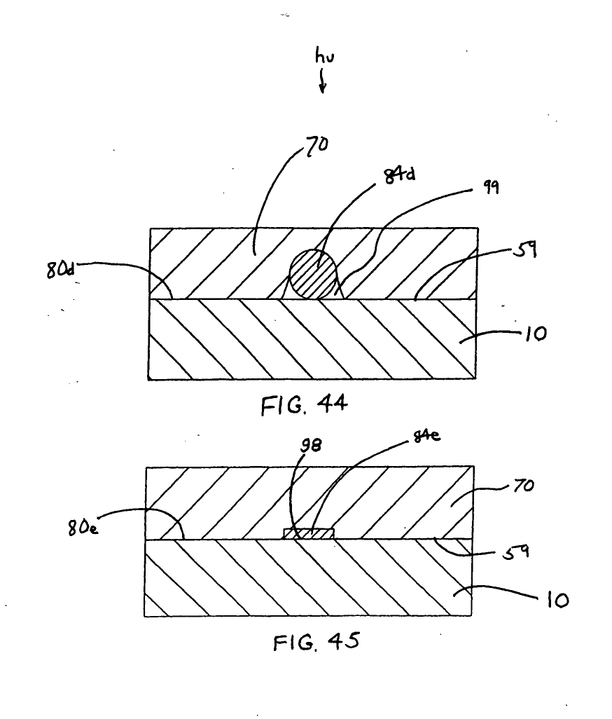

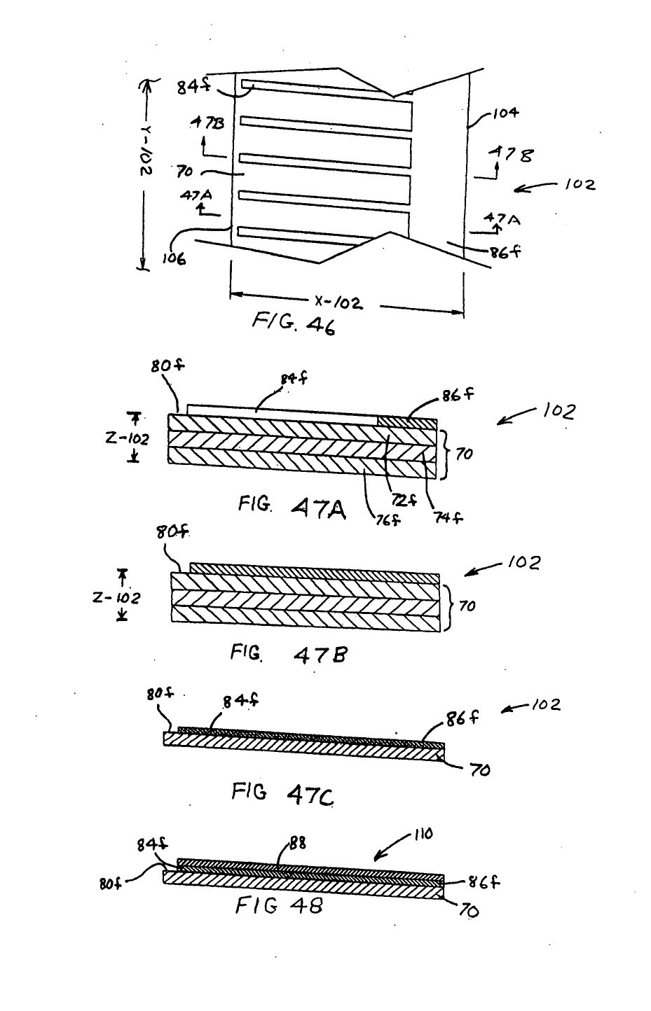

A potential cross sectional view of a wire 84d laminated to a surface by the process such as that of FIG. 40 is depicted in FIG. 44. FIG. 45 depicts a typical cross sectional view of an electrical trace 84e formed by printing, electrodeposition, chemical “electroless” plating, foil etching, masked vacuum deposition etc. It is seen in FIG. 44 that being round the wire itself contacts the surface essentially along a line (normal to the paper in FIG. 44). In addition, the sealing material forming surface 80d of film 70 may have difficulty flowing completely around the wire, leaving voids as shown in FIG. 44 at 99, possibly leading to insecure contact. Thus, the thickness of the sealing layer and lamination parameters and material choice become very important when using a round wire form. On the other hand, using a lower profile substantially flat conductive trace such as depicted in FIG. 45 increases contact surface area compared to the line contact associated with a wire. The low profile form of FIG. 45 facilitates broad surface contact and secure lamination but comes at the expense of increased light shading. The low profile, flat structure does require consideration of the thickness of the “flowable” sealing layer forming surface 80e relative to the thickness of the conductive trace. Excessive thickness of certain sealing layer materials might allow relaxation of the “blanket” pressure promoting contact of the surfaces 98 with a mating conductive surface such as 59. Insufficient thickness may lead to voids similar to those depicted for the wire forms of FIG. 44. However, it has been found that sealing layer thicknesses for low profile traces such as embodied in FIG. 45 ranging from 0.5 mil (0.0005 inch) to 10 mil (0.01 inch) all perform satisfactorily. Thus a wide range of thickness is possible, and the invention is not limited to sealing layer thicknesses within the stated tested range.

A low profile structure such as depicted in FIG. 45 may be advantageous because it may allow minimizing sealing layer thickness and consequently reducing the total amount of functional groups present in the sealing layer. Such functional groups may adversely affect solar cell performance or integrity. For example, it may be advantageous to limit the thickness of a sealing layer such as EVA to 2 mils or less when using a CIS or CIGS photovoltaic material.

Electrical contact between conductive grid “fingers” or “traces” 84 and a conductive surface (such as cell surface 59) may be further enhanced by coating a conductive adhesive formulation onto “fingers” 84 and possibly “busses” 86 prior to or during the lamination process such as taught in the embodiment of FIGS. 40 through 43. In a preferred embodiment, the conductive adhesive would be a “hot melt” material. A “hot melt” conductive adhesive would melt and flow at the temperatures involved in the laminating process 92 of FIG. 40. In this way surface 98 is formed by a conductive adhesive resulting in secure adhesive and electrical joining of grid “fingers” 84 to a conductive surface such as top surface 59 following the lamination process. In addition, such a “flowable” conductive material may assist in reducing voids such as depicted in FIG. 44 for a wire form. In addition, a “flowable” conductive adhesive may increase the contact area for the wire form 84d.

In the case of a low profile form such as depicted in FIG. 45, the conductive adhesive may be applied by standard registered printing techniques. However, it is noted that a conductive adhesive coating for a low profile conductive trace may be very thin, of the order of 1-10 micron thick. Thus, the intrinsic resistivity of the conductive adhesive can be relatively high, perhaps up to or even exceeding about 100 ohm-cm. This fact allows reduced loading and increased choices for a conductive filler. Since the conductive adhesive does not require heavy filler loading (i.e. it may have a relatively high intrinsic resistivity as noted above) other unique application options exist.

For example, a suitable conductive “hot melt” adhesive may be deposited from solution onto the surface of the “fingers” and “busses” by conventional paint electrodeposition techniques. Alternatively, should a condition be present wherein the exposed surface of fingers and busses be pristine (no oxide or tarnished surface), the well known characteristic of such a surface to “wet” with water based formulations may be employed to advantage. A freshly activated or freshly electroplated metal surface will be readily “wetted” by dipping in a water-based polymer containing fluid such as a latex emulsion containing a conductive filler such as carbon black. Application selectivity would be achieved because the exposed polymeric sealing surface 80 would not wet with the water based latex emulsion. The water based material would simply run off or could be blown off the sealing material using a conventional air knife. However, the water based film forming emulsion would cling to the freshly activated or electroplated metal surface. This approach is similar to applying an anti-tarhish or conversion dip coating to freshly electroplated metals such as copper and zinc.

Alternatively, one may employ a low melting point metal-based material as a constituent of the material forming either or both surfaces 98 and 100 of “fingers” and “busses”. In this case the low melting point metal-based material, or alloy, such as a tin based solder is caused to melt during the temperature exposure of the process 92 of FIG. 40 (typically less than 600 degrees F.) thereby increasing the contact area between the mating surfaces 98, 100 and a conductive surface such as 59. Such low melting point metal-based materials may be applied by electrodeposition or simple dipping to wet the underlying conductive trace. In another preferred embodiment indium or indium containing alloys are chosen as the low melting point contact material at surface 98,100. Indium melts at a low temperature, considerably below possible lamination temperatures. In addition, indium is known to bond to glass and ceramic materials when melted in contact with them. Given sufficient lamination pressures, only a very thin layer of indium or indium alloy would be required to take advantage of this bonding ability.

In yet another embodiment, one or more of the layers 84, 86, 88, 90 etc. may comprise a material having magnetic characteristics. Magnetic materials include nickel and iron. In this embodiment, either a magnetic material in the cell substrate or the material present in the finger/grid collector structure is caused to be permanently magnetized. The magnetic attraction between the “grid pattern” and magnetic component of the foil substrate of the photovoltaic cell (or visa versa) creates a permanent “pressure” contact.

In yet another embodiment, the “fingers” 84 and/or “busses” 86 comprise a magnetic component such as iron or nickel and a external magnetic field is used to maintain positioning of the fingers or busses during the lamination process depicted in FIG. 40.

Bonding to the contact surface 48 of conductive region 23 can be accomplished by any number of the electrical joining techniques mentioned above. These include electrically conductive adhesives, solder, and melting of suitable metals or metal-base alloys during the heat and pressure exposure of a process such as 92 of FIG. 40. As with the discussion above concerning contact of the “fingers”, selecting low melting point metal-based materials or hot melt conductive adhesives as constituents forming surface 100 could aid in achieving good ohmic contact and adhesive bonding of “busses” 86 to the contact surface 48 of conductive region 23 in the embodiment of FIGS. 42 and 43.

FIG. 46 is a top plan view of an article 102 embodying another form of the electrodes of the current invention. FIG. 46 shows article 102 having structure comprising “fingers” 84f extending from “buss/tab” 86f arranged on a substrate 70. The structure of FIG. 46 is similar to that shown in FIG. 30. However, whereas FIG. 30 depicted multiple finger and buss/tab structures arranged in a substantially repetitive pattern in direction “X-71”, the FIG. 46 embodiment consists of one finger/buss pattern. Thus, the dimension “X-102” of FIG. 46 may be roughly equivalent to the repeat dimension “F” shown in FIG. 30. Indeed, it is contemplated that article 102 of FIG. 46 may be produced by subdividing the FIG. 30 structure 71 according to repeat dimension “F” shown in FIG. 30. Dimension “Y-102” may be chosen appropriate to the particular processing scheme envisioned for the eventual lamination to a photovoltaic cell. However, it is envisioned that “Y-102” may be much greater than “X-102” such that article 102 may be characterized as continuous or capable of being processed in a roll-to-roll fashion. Article 102 has a first terminal edge 104 and second terminal edge 106. In the embodiment fingers 84f are seen to terminate prior to intersection with terminal edge 106. One will understand that this is not a requirement.

“Fingers” 84f and “buss/tab” 86f have the same characterization as “fingers” 84 and “busses” 86 of FIGS. 30 through 32. Like the “fingers” 84 and “busses” 86 of FIGS. 30 through 32, “fingers” 84f and “buss” 86f may comprise materials that are either conductive, assist in a subsequent deposition of conductive material or promote adhesion of a subsequently applied conductive material to substrate 70. While shown as a single layer, one appreciates that “fingers” 84f and “buss” 86f may comprise multiple layers. The materials forming “fingers” 84f and “buss” 86f may be different or the same. In addition, the substrate 70 may comprise different materials or structures in those regions associated with “fingers” 84f and “buss region” 86f. For example, substrate 70 associated with “buss region” 86f may comprise a fabric to provide thru-hole communication and enhance flexibility, while substrate 70 in the region associated with “fingers” 84f may comprise a film devoid of thru-holes such as depicted in FIGS. 27-29. A “holey” structure in the “buss region” would provide increased flexibility, surface area and structural characteristic for an adhesive to grip.

FIGS. 47A and 47B are sectional embodiments taken substantially from the perspective of lines 47A-47A and 47B-47B respectively of FIG. 46. FIGS. 47A and 47B show that article 102 has thickness Z-102 which may be much smaller than the X and Y dimensions, thereby allowing article 102 to be flexible and processable in roll form. Also, flexible sheet-like article 102 may comprise any number of discrete layers (three layers 72f, 74f, 76f are shown in FIGS. 47A and 47B). These layers contribute to functionality as previously pointed out in the discussion of FIG. 28. As will be understood in light of the following discussion, it is normally helpful for layer 72f forming free surface 80f to exhibit adhesive characteristics to the eventual abutting conductive surface.

FIG. 47C is an alternate representation of the sectional view of FIG. 47B. FIG. 47C depicts substrate 70 as a single layer for ease of presentation. The single layer representation will be used in many following embodiments, but one will understand that substrate 70 may comprise multiple layers.

FIG. 48 is a sectional view of the article now identified as 110, similar to FIG. 47C, after an additional optional processing step. In a fashion like that described above for production of the current collector structure of FIGS. 36 through 39, additional conductive material 88 has been deposited by optional processing to produce the article 110 of FIG. 48. The discussion involving processing to produce the article of FIGS. 36 through 39 is proper to describe production of the article of FIG. 48. Thus, while additional conductive material has been designated as a single layer 88 in the FIG. 48 embodiment, one will understand that layer 88 of FIG. 48 may represent any number of multiple additional layers. In subsequent embodiments, additional conductive material 88 will be represented as a single layer for ease of presentation. In its form prior to combination with cells 10, the structures such as shown in FIGS. 30-39, and 46-48 can be referred to as “current collector stock”. For the purposes of this specification and claims a current collector in its form prior to combination with a conductive surface can be referred to as “current collector stock”. “Current collector stock” can be characterized as being either continuous or discrete. Further, in light of the teachings to follow one will recognize that the structures shown in FIGS. 30-39 and 46-48 may function as laminating electrodes.

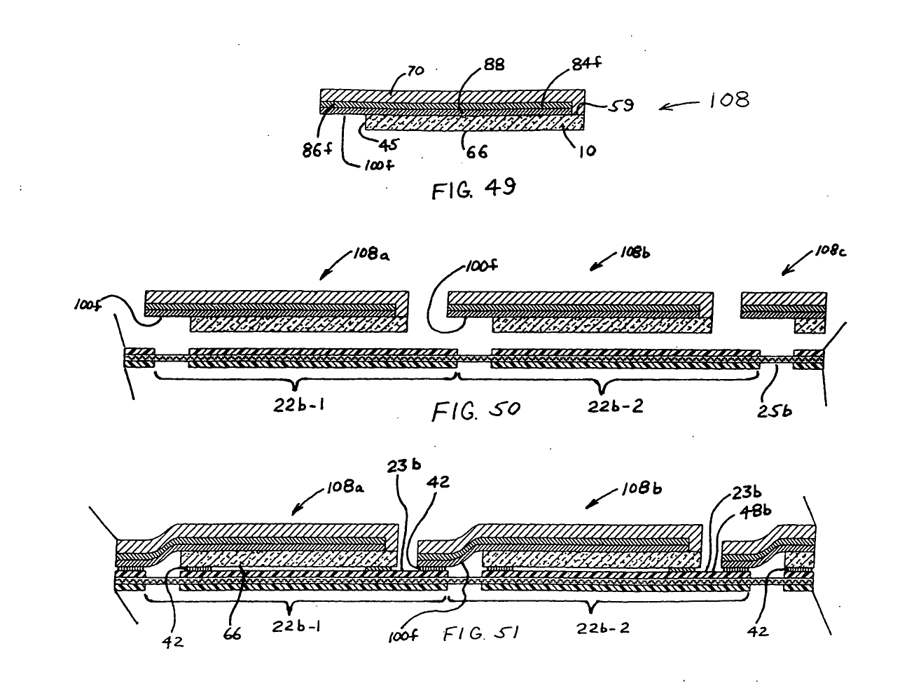

FIG. 49 is a sectional view of an article 108 resulting from laminating the FIG. 48 current collector article 110 to the light incident surface 59 of a photovoltaic cell stock such as that of FIG. 2A. It is seen in FIG. 49 that the conductive collector material of the “fingers” 84f contacts the top surface 59 of cell 10 and also extends in a continuous conductive path over the terminal edge 45 of the cell stock 10 to a readily accessible exposed electrode surface designated as 100f in FIG. 49. Such an exposed free surface 100f extending outward of the terminal edge of a photovoltaic cell may be referred to as a “tab”. The article 108 of FIG. 49 can thus be referred to as “tabbed cell stock”. In light of the present teachings, one will understand that “tabbed cell stock” can be characterized as being either continuous or discrete.

A tabbed cell stock 108 has a number of fundamental advantageous attributes. First, it can be produced as a continuous cell “strip” and in a continuous roll-to-roll fashion in the Y direction (direction normal to the paper in the sectional view of FIG. 49). Following the envisioned lamination, the tabbed cell stock strip can be continuously monitored for quality since there is ready access to the exposed free surface 100f which is in electrical communication with top cell surface 59 and the cell bottom electrode surface 66 is also readily accessible. Thus defective cell material can be identified and discarded prior to final interconnection into an array. Finally, the laminated current collector electrode protects the surface of the cell from defects possibly introduced by the further handing associated with final interconnections.

FIG. 50 is a sectional view showing an arrangement of multiple articles 108 in juxtaposition with an interconnecting substrate as depicted in FIGS. 9 and 10 just prior to an assembly process which may be similar to that of FIG. 13A. FIG. 51 is a sectional view embodying the final interconnected array. In FIG. 51 it is seen that the conductive free surface 100f of one unit article 108b is electrically joined to the conductive surface region 23b of an adjacent interconnecting substrate unit 22b-1 in contact region 48b. In the FIG. 51 embodiment electrical joining is shown as employing electrically conductive adhesive 42. However, as discussed above many different electrical joining techniques can be envisioned. The conductive region 23b of interconnecting substrate unit 22b-1 is also in contact with the rear conductive surface 66 of adjacent unit article 108a. In the FIG. 51 embodiment, this conductive joining of surface 66 and region 23b is also shown to be accomplished with conductive adhesive 42. Thus there is a series connection between the top surface 59 of cell 10 of article 108b and the rear conductive surface 66 of cell 10 of article 108a.

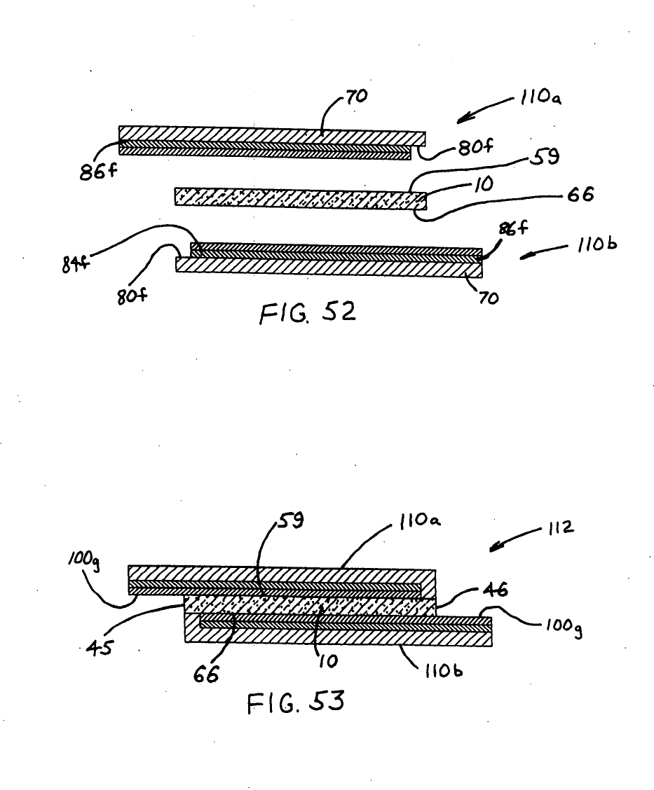

Yet another embodiment of the instant invention is taught in conjunction with FIGS. 52 through 55. FIG. 52 is a sectional view showing a photovoltaic cell 10 such as embodied in FIGS. 2A and 2B disposed between two current collecting electrodes 110a and 110b such as article 110 embodied in FIG. 48. FIG. 53 is a sectional view showing the article 112 resulting from laminating the three individual structures of FIG. 52 while substantially maintaining the relative positioning depicted in FIG. 52. FIG. 53 shows that a laminating current collector electrode 110a has now been applied to the top conductive surface 59 of cell 10. Laminating current electrode 110b mates with and contacts the bottom conductive surface 66 of cell 10. However, the positioning is such that a first current collector article 110a overlays cell 10 and also overhangs peripheral terminal edge 45 of cell 10 while current collector article 110b overlays surface 66 and also overhangs terminal edge 46 of cell 10. Thus article 112 is characterized as having readily accessible conductive surface portions or tabs 100g in electrical communication with both top cell surface 59 and bottom cell surface 66. Thus article 112 is another embodiment of a tabbed cell stock. One will recognize that electrodes 110a and 110b can be used independently of each other. For example, 110b could be employed as a back side electrode while a current collector electrode different than 110a is employed on the top side of cell 10.

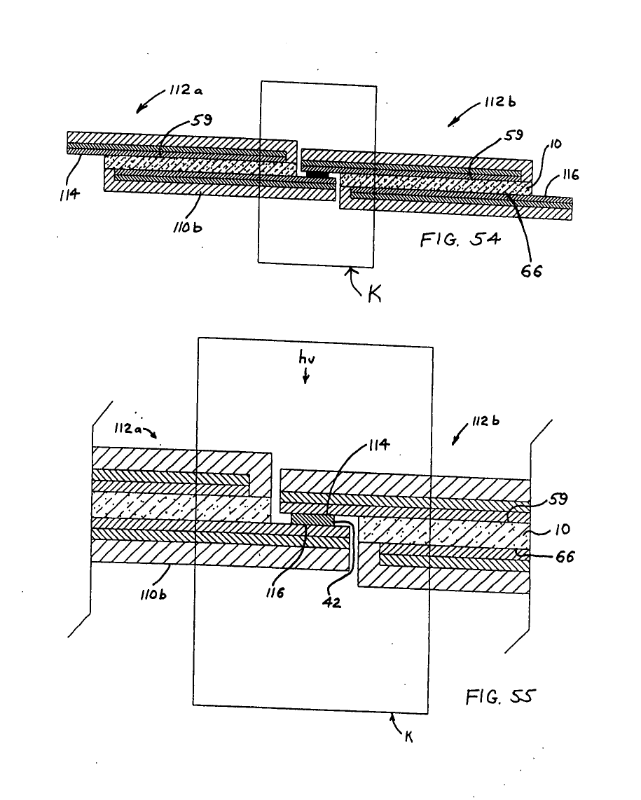

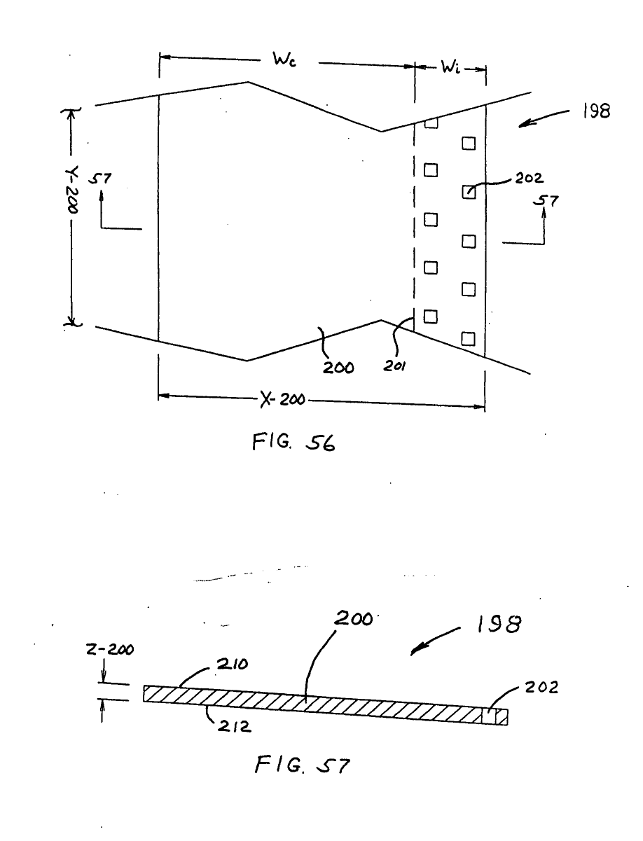

The sectional drawings of FIGS. 54 and 55 show the result of joining multiple articles 112a, 112b. Each article has a readily accessible downward facing conductive surface (in the drawing perspective) 114 in communication with the cell top surface 59. A readily accessible upward facing conductive surface 116 extends from the cell bottom surface 66. One will appreciate that in this embodiment, current collector 110b functions as an interconnecting substrate unit such as taught in previous embodiments of FIGS. 6 through 12, and FIGS. 22 through 26. Series connections are easily achieved by overlapping the top surface extension 114 of one article 112b and a bottom surface extension 116 of a second article 112a and electrically connecting these extensions with electrically conductive joining means such as conductive adhesive 42 shown in FIGS. 54 and 55. Other electrically conductive joining means including those defined above may be selected in place of conductive adhesive 42. Finally, since the articles 112 of FIG. 53 can be produced in a continuous form (in the direction normal to the paper in FIG. 53) the series connections and array production embodied in FIGS. 54 and 55 may also be accomplished in a continuous manner by using continuous feed rolls of tabbed cell stock 112. However, while continuous assembly may be possible, other processing may be envisioned to produce the interconnection embodied in FIGS. 54 and 55. For example, defined lengths of tabbed cell stock 112 could be produced by subdividing a continuous strip of tabbed cell stock 112 in the Y dimension and the individual articles thereby produced could be arranged as shown in FIGS. 54 and 55, perhaps using standard pick and place positioning.

Referring now to FIGS. 56 through 59, there are shown embodiments of a starting structure for another grid/interconnect article of the invention. FIG. 56 is a top plan view of an article 198. Article 198 comprises a polymeric film or glass sheet substrate generally identified by numeral 200. Film 200 has width X-200 and length Y-200. Length Y-200 is sometimes much greater the width X-200 such that film 200 can be processed in essentially a “roll-to-roll” fashion. However, this is not necessarily the case. Dimension “Y” can be chosen according to the application and process envisioned. FIG. 57 is a sectional view taken substantially from the perspective of lines 57-57 of FIG. 56. Thickness dimension Z-200 is normally small in comparison to dimensions Y-200 and X-200 and thus film 200 has a sheetlike structure and is often flexible. Film 200 is further characterized by having regions of essentially solid structure combined with regions having holes 202 extending through the thickness Z-200. In the FIG. 56 embodiment, a substantially solid region is generally defined by a width Wc, representing a current collection region. The region with through-holes (holey region) is generally defined by width Wi, representing an interconnection region. Imaginary line 201 separates the two regions. Holes 202 may be formed by simple punching, laser drilling and the like. Alternatively, holey region Wi may comprise a fabric joined to region Wc along imaginary line 201, whereby the fabric structure comprises through-holes. The reason for these distinctions and definitions will become clear in light of the following teachings.

Referring now to FIG. 57, region Wc of film 200 has a first surface 210 and second surface 212. The sectional view of film 200 shown in FIG. 57 shows a single layer structure. This depiction is suitable for simplicity and clarity of presentation. Often, however, film 200 will comprise a laminate of multiple layers as depicted in FIG. 58. In the FIG. 58 embodiment, film 200 is seen to comprise multiple layers 204, 206, 208, etc. As previously taught herein, the multiple layers may comprise inorganic or organic components such as thermoplastics, thermosets, or silicon containing glass-like layers. The various layers are intended to supply functional attributes such as environmental barrier protection or adhesive characteristics. In particular, in light of the teachings to follow, one will recognize that it may be advantageous to have layer 204 forming surface 210 comprise a sealing material such as ethylene vinyl acetate (EVA), an ionomer, an atactic polyolefin, or a polymer containing polar functional groups for adhesive characteristics during a possible subsequent lamination process. For example, the invention has been successfully demonstrated using a standard laminating material sold by GBC Corp., Northbrook, Ill., 60062. Additional layers 206, 208 etc. may comprise materials which assist in support or processing such as polypropylene and polyethylene terepthalate, barrier materials such as fluorinated polymers and biaxially oriented polypropylene, and materials offering protection against ultraviolet radiation as previously taught in characterizing substrate 70 of FIG. 27.

As embodied in FIGS. 56 and 57, the solid regions Wc and “holey” regions Wi of film 200 may comprise the same material. This is not necessarily the case. For example, the “holey” regions Wi of film 200 could comprise a fabric, woven or non-woven, joined to an adjacent substantially solid region along imaginary line 201. However, the materials forming the solid region Wc should be relatively transparent or translucent to visible light, as will be understood in light of the teachings to follow.

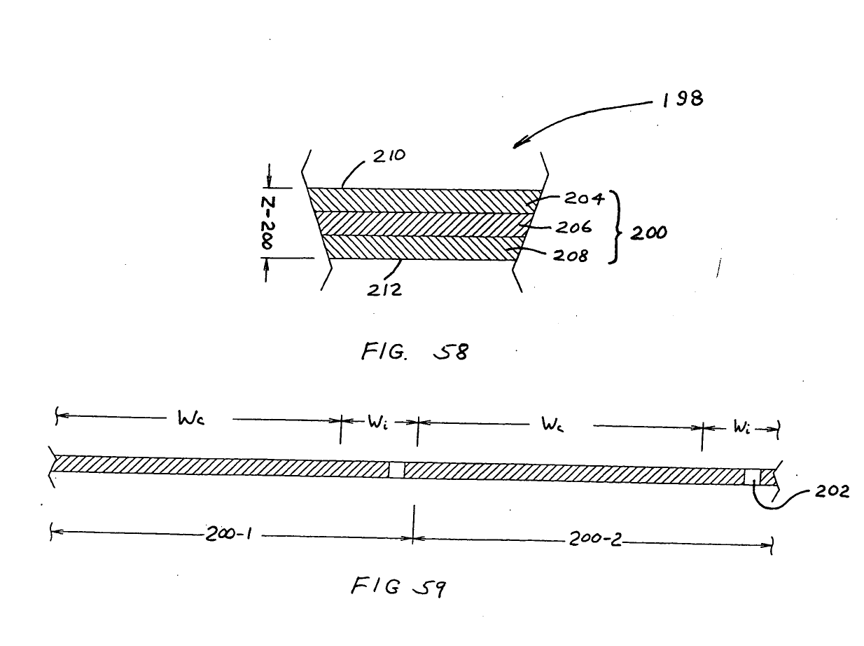

FIG. 59 depicts an embodiment wherein multiple widths 200-1, 200-2 etc. of the general structure of FIGS. 56 and 57 are joined together in a generally repetitive pattern in the width direction. Such a structure allows simultaneous production of multiple repeat structures corresponding to widths 200-1, 200-2 in a fashion similar to that taught in conjunction with the embodiments of FIGS. 27 through 39.

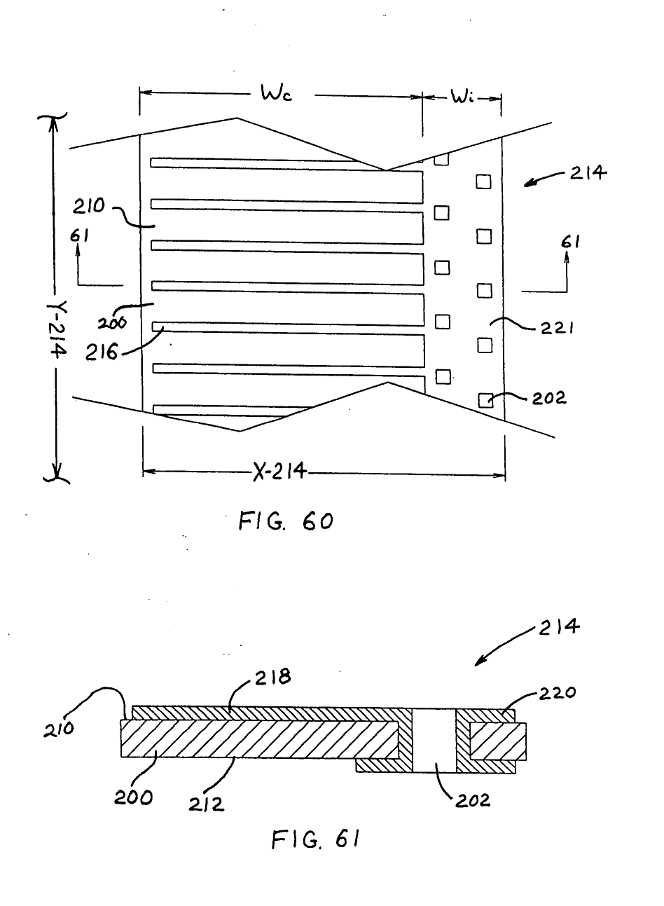

FIG. 60 is a plan view of the FIG. 56 film 200 following an additional processing step, and FIG. 61 is a sectional view taken along line 61-61 of FIG. 60. In FIGS. 60 and 61, the article is now designated by the numeral 214 to reflect this additional processing. In FIGS. 60 and 61, it is seen that a pattern of “fingers” 216 has been formed by material 218 positioned in a pattern onto surface 210 of original film 200. “Fingers” 216 extend over the width Wc of the solid portion of sheetlike structure 214. The “fingers” 216 extend to the “holey” interconnection region generally defined by Wi. Portions of the Wc region not overlayed by “fingers” 216 remain transparent or translucent to visible light. The “fingers” may comprise electrically conductive material. Examples of such materials are metal containing inks, patterned deposited metals such as etched metal patterns, masked vacuum deposited metal patterns, fine wires, intrinsically conductive polymers and DER formulations. The “fingers” may comprise materials intended to facilitate subsequent deposition of conductive material in the pattern defined by the fingers. An example of such a material would be ABS, catalyzed to constitute a “seed” layer to initiate chemical “electroless” metal deposition. Another example would be a material functioning to promote adhesion of a subsequently applied conductive material to the film 200. In a preferred embodiment, the “fingers” comprise material which will enhance or allow subsequent metal electrodeposition such as a DER or electrically conductive ink. In the embodiment of FIGS. 60 and 61, the “fingers” 216 are shown to be a single layer of material 218 for simplicity of presentation. However, the “fingers” can comprise multiple layers of differing materials chosen to support various functional attributes as has previously been taught.

Continuing reference to FIGS. 60 and 61 also shows additional material 220 applied to the “holey” region Wi of article 214. As with the material comprising the “fingers” 216, the material 220 applied to the “holey” region Wi is either conductive or material intended to facilitate subsequent deposition of conductive material. One will understand that “holey” region Wi may comprise a fabric which may further comprise conductive material extending through the natural holes of the fabric. Further, such a fabric may comprise fibrils formed from conductive materials such as metals or conductive polymers. Such a fabric structure can be expected to increase and retain flexibility after subsequent processing such as metal electroplating and perhaps bonding ability of the ultimate interconnected cells as will be understood in light of the teachings contained hereafter. In the embodiment of FIGS. 60 and 61, the “holey” region takes the general form of a “buss” 221 extending in the Y-214 direction in communication with the individual fingers. However, as one will understand through the subsequent teachings, the invention requires only that conductive communication extend from the fingers to a region Wi intended to be electrically joined to the bottom conductive surface of an adjacent cell. The “holey” region Wi thus does not require overall electrical continuity in the “Y” direction as is characteristic of a “buss” depicted in FIGS. 60 and 61.

Reference to FIG. 61 shows that the material 220 applied to the “holey” interconnection region Wi is shown as the same as that applied to form the fingers 216. However, these materials 218 and 220 need not be identical. In this embodiment material 220 applied to the “holey” region extends through holes 202 and onto the opposite second surface 212 of article 214. The extension of material 220 through the holes 202 can be readily accomplished as a result of the relatively small thickness (Z dimension) of the sheetlike article. Techniques include two sided printing of material 220, through hole spray application, masked metallization or selective chemical deposition or mechanical means such as stapling, wire sewing or riveting.

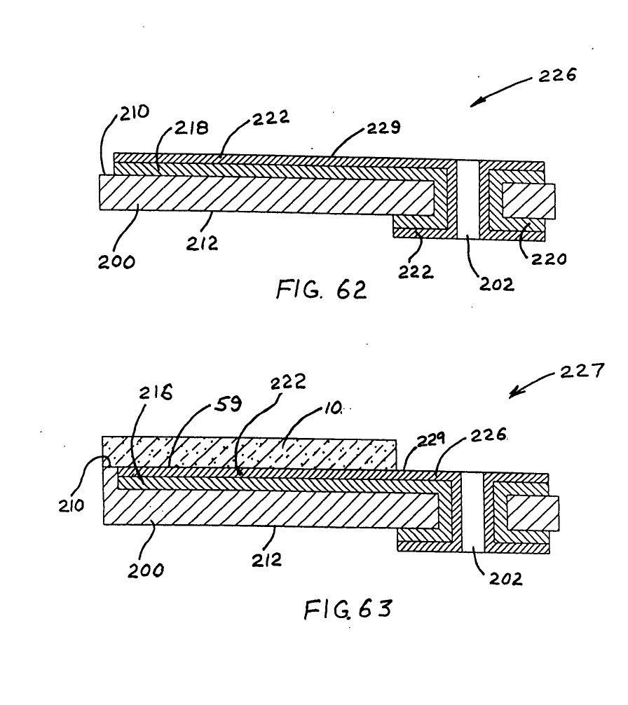

FIG. 62 is a view similar to that of FIG. 61 following an additional optional processing step. The article embodied in FIG. 62 is designated by numeral 226 to reflect this additional processing. It is seen in FIG. 62 that the additional processing has deposited highly conductive material 222 over the originally free surfaces of materials 218 and 220. Material 222 normally comprises metal-based material such as copper or nickel, tin or a conductive metal containing paste or ink. Typical deposition techniques such as printing, chemical or electrochemical metal deposition and masked deposition can be used for this additional optional process to produce the article 226. In a preferred embodiment, electrodeposition is chosen for its speed, ease, and cost effectiveness as taught above. It is understood that article 226 is another form of current collector stock.

It is seen in FIG. 62 that highly conductive material 222 extends through holes to electrically join and form electrically conductive surfaces on opposite sides of article 226. While shown as a single layer in the FIG. 62 embodiment, the highly conductive material can comprise multiple layers to achieve functional value. In particular, a layer of copper is often desirable for its high conductivity. Nickel is often desired for its adhesion characteristics, plateability and corrosion resistance. The exposed surface 229 of material 222 can be selected for corrosion resistance and bonding ability. It has been found very advantageous to form surface 229 with a material compatible with the conductive surface with which eventual contact is made. In preferred embodiments, electroless deposition or electrodeposition is used to form a suitable metallic surface. Specifically electrodeposition offers a wide choice of potentially suitable materials to form the top surface. Corrosion resistant materials such as nickel, chromium, tin, indium, silver, gold and platinum are readily electrodeposited. When compatible, of course, surfaces comprising metals such as copper or zinc or alloys of copper or zinc may be considered. Alternatively, the surface 229 may comprise a conversion coating, such as a chromate coating, of a material such as copper or zinc. Further, as will be discussed below, it may be highly advantageous to choose a material, such as a conductive adhesive or metallic solder to form surface 229 which exhibits adhesive or bonding ability to a subsequently positioned abutting conductive surface. In this regard, electrodeposition offers a wide choice of materials to form surface 229. In particular, indium, tin or tin containing alloys are a possible choice of material to form the exposed surface 229 of material 222. These metals melt at relatively low temperatures, which may be desirable to promote ohmic joining, through soldering to other components in subsequent processing such as lamination. Alternatively, exposed surface 229 may comprise an electrically conductive adhesive material in a fashion previously discussed in the embodiments of FIGS. 27 through 43. As previously discussed, selective deposition techniques such as brush plating would allow the conductive materials of region Wi to differ from those of fingers 216. In addition to supplying electrical communication from surfaces 210 to 212, holes 202 also function to increase flexibility of “buss” 221 by relieving the “sandwiching” effect of continuous oppositely disposed layers. Holes 202 can clearly be the holes naturally present should substrate 200 in the region Wi be a fabric.

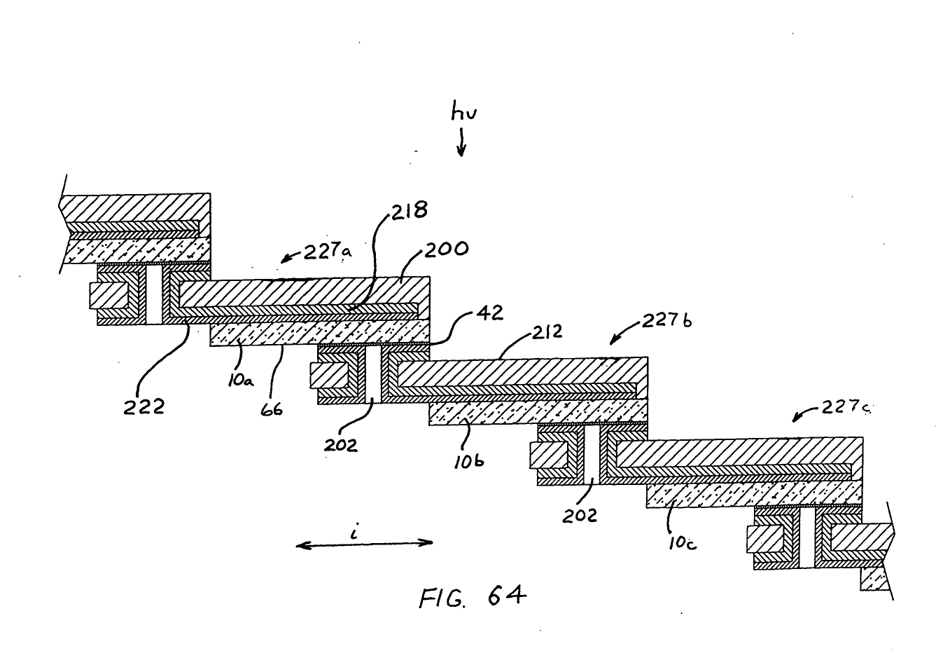

One method of combining the current collector stock 226 embodied in FIG. 62 with a cell stock 10 as embodied in FIGS. 1A and 2A is illustrated in FIGS. 63 and 64. In the FIG. 64 structure, individual current collector stocks 226 are combined with cells 10a, 10b, 10c respectively to produce a series interconnected array. This may be accomplished via a process generally described as follows.

As embodied in FIG. 63, individual current collector stock, such as 226, is combined with cells such as 10 by positioning of surface region “Wc” of current collector stock 226 having free surface 210 in registration with the light incident surface 59 of cell 10. The article so produced is identified as article 227. Adhesion joining the two surfaces is accomplished by a suitable process. In particular, the material forming the remaining free surface 210 of article 226 (that portion of surface 210 not covered with conductive material 222) may be a sealing material chosen for adhesive affinity to surface 59 of cell 10 thereby promoting good adhesion between the collector stock 226 and cell surface 59 during a laminating process. A laminating process brings the conductive material of fingers 216 into firm and effective contact with the window electrode 18 forming surface 59 of cell 10. This contact is ensured by the blanketing “hold down” afforded by the adhesive bonding adjacent the conductive fingers 216. Also, as mentioned above, the nature of the free surface of conductive material 222 may optionally be manipulated and chosen to further enhance ohmic joining and adhesion. It is envisioned that batch or continuous laminating would be suitable. Should the articles 226 and 10 be in a continuous form it will be understood that article 227 could be formed as a continuous tabbed cell stock. The subsequent series arrangement of articles 227a, 227b, . . . depicted in FIG. 64 may employ strip portions of tabbed cell stock having a defined length. Alternatively continuous series interconnection of multiple strips of tabbed cell stock supplied from corresponding multiple rolls of tabbed cell stock is possible.

Proper positioning allows the conductive material 222 extending over the second surface 212 of article 227b to be ohmicly adhered to the bottom surface 66 of cell 10a. This joining is accomplished by suitable electrical joining techniques such as soldering, riveting, spot welding or conductive adhesive application. The particular ohmic joining technique embodied in FIG. 64 is through electrically conductive adhesive 42. A particularly suitable conductive adhesive is one comprising a carbon black filler in a polymer matrix possibly augmented with a more highly conductive metal filler. Such adhesive formulations are relatively inexpensive and can be produced as hot melt formulations. Despite the fact that adhesive formulations employing carbon black alone have relatively high intrinsic resistivities (of the order 1 ohm-cm.), the bonding in this embodiment is accomplished through a relatively thin adhesive layer and over a broad surface. Thus the resulting resistance losses are relatively limited. A hot melt conductive adhesive is very suitable for establishing the ohmic connection using a straightforward lamination process.

FIG. 64 embodies three cells assembled in a series arrangement using the teachings of the instant invention. In FIG. 64, “i” indicates the direction of net current flow and “hv” indicates the light incidence for the arrangement. It is noted that the arrangement of FIG. 64 resembles a shingling arrangement of cells, but with an important distinction. The prior art shingling arrangements have included an overlapping of cells at a sacrifice of portions of very valuable cell surface. In the FIG. 64 teaching, the benefits of the shingling interconnection concept are achieved without any loss of photovoltaic surface from shading by an overlapping cell. In addition, the FIG. 64 arrangement retains a high degree of flexibility because there is no immediate overlap of the metal foil cell substrate.

Yet another form of the instant invention is embodied in FIGS. 65 through 76. FIG. 65 is a top plan view of an article designated 230. Article 230 has width “X-230” and length “Y-230”. It is contemplated that “Y-230” may be considerably greater than “X-230” such that article 230 may be processed in continuous roll-to-roll fashion. However, such continuous processing is not a requirement.

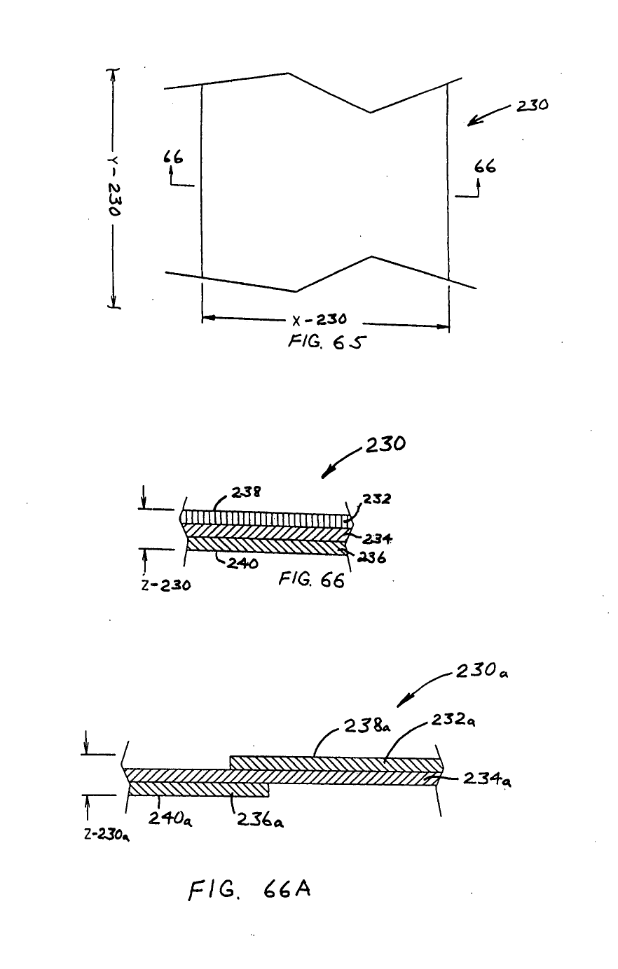

FIG. 66 is a sectional view taken substantially from the perspective of lines 66-66 of FIG. 65. It is shown in FIG. 66 that article 230 may comprise any number of layers such as those designated by numerals 232, 234, 236. The layers are intended to supply functional attributes to article 230 as has been discussed for prior embodiments. Article 230 is also shown to have thickness “Z-230”. “Z-230” is much smaller than “X-230” of “Y-230” and thus article 230 can generally be characterized as being flexible and sheetlike. Article 230 is shown to have a first surface 238 and second surface 240. As will become clear in subsequent embodiments, it may be advantageous to form layer 232 forming surface 238 using a material having adhesive affinity to the bottom surface 66 of cell 10. In addition, it may be advantageous to have surface 240 formed by a material having adhesive affinity to surface 59 of cell 10.

FIG. 66A is an alternate sectional embodiment depicting an article 230a. The layers forming article 230a do not necessarily have to cover the entire expanse of article 230a.

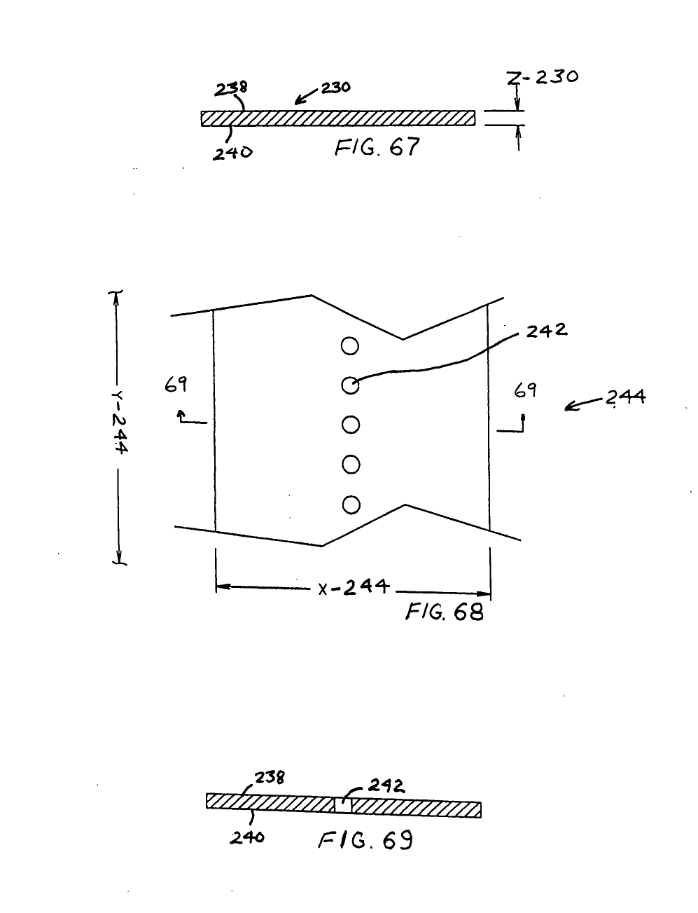

FIG. 67 is a simplified sectional view of the article 230 which will be used to simplify presentation of embodiments to follow. While FIG. 67 presents article 230 as a single layer, it is emphasized that article 230 may comprise any number of layers.

FIG. 68 is a top plan view of the initial article 230 following an additional processing step. The article embodied in FIG. 68 is designated 244 to reflect this additional processing step. FIG. 69 is a sectional view taken substantially from the perspective of lines 69-69 of FIG. 68. Reference to FIGS. 68 and 69 show that the additional processing has produced holes 242 in the direction of “Y-244”. The holes extend from the top surface 238 to the bottom surface 240 of article 244. Holes 242 may be produced by any number of techniques such as laser drilling or simple punching.

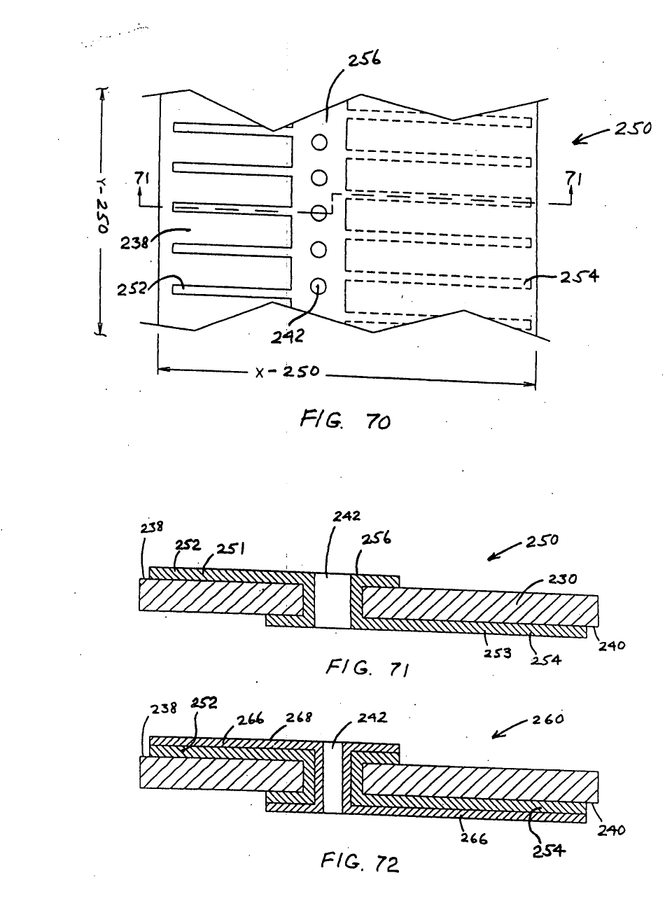

FIG. 70 is a top plan view of the article 244 following an additional processing step. The article of FIG. 70 is designated 250 to reflect this additional processing. FIG. 71 is a sectional view taken substantially from the perspective of lines 71-71 of FIG. 70. Reference to FIGS. 70 and 71 shows that additional material 251 is applied to the first surface 238 in the form of “fingers” 252. Further, additional material 253 has been applied to second surface 240 in the form of “fingers” 254. In the embodiment, “fingers” 252 and 254 extend substantially perpendicular from a “buss-like” structure 256 extending in the direction “Y-250”. As seen in FIG. 71, additional materials 251 and 253 extend through the holes 242. In the FIG. 71 embodiment, materials 251 and 253 are shown as being the same. This is not necessarily a requirement and they may be different. Also, in the embodiment of FIGS. 70 and 71, the buss-like structure 256 is shown as being formed by materials 251/253. This is not necessarily a requirement. Materials forming the “fingers” 252 and 254 and “buss” 256 may all be the same or they may differ in actual composition and be applied separately. Alternatively, fingers and busses may comprise a continuous material structure forming portions of both fingers and busses. Fingers and busses need not both be present in certain embodiments of the invention.

As in prior embodiments, “fingers” 252 and 254 and “buss” 256 may comprise electrically conductive material. Examples of such materials are metal wires and foils, conductive metal containing inks and pastes, patterned deposited metals such as etched metal patterns or masked vacuum deposited metals, intrinsically conductive polymers, conductive inks and DER formulations. In a preferred embodiment, the “fingers and “busses” comprise material such as DER or an electrically conductive ink such as silver containing ink which will enhance or allow subsequent metal electrodeposition. “Fingers” 252 and 254 and “buss” 256 may also comprise non-conductive material which would assist accomplishing a subsequent deposition of conductive material in the pattern defined by the “fingers” and “busses”. For example, “fingers” 252 and 254 or “buss” 256 could comprise a polymer which may be seeded to catalyze chemical deposition of a metal in a subsequent step. An example of such a material is ABS. “Fingers” 252 and 254 and “buss” 256 may also comprise materials selected to promote adhesion of a subsequently applied conductive material.

FIG. 72 is a sectional view showing the article 250 following an additional optional processing step. The article of FIG. 72 is designated 260 to reflect this additional processing. In a fashion like that described above for production of the current collector structure of FIGS. 36 through 39, additional conductive material 266 has been deposited by optional processing to produce the article 260 of FIG. 72. The discussion involving processing to produce the article of FIG. 36 through 39 is proper to describe the additional processing to produce the article 260 of FIG. 72. In a preferred embodiment, conductive material 266 comprises material applied by electrodeposition. In addition, while shown in FIG. 72 as a single continuous layer, the additional conductive material may comprise multiple layers. As in prior embodiments, it may be advantageous to use a material such as a low melting point alloy or conductive adhesive to form exterior surface 268 of additional conductive material 266. Additional conductive material overlaying “fingers” 252 need not be the same as the additional conductive material overlaying “fingers” 254.

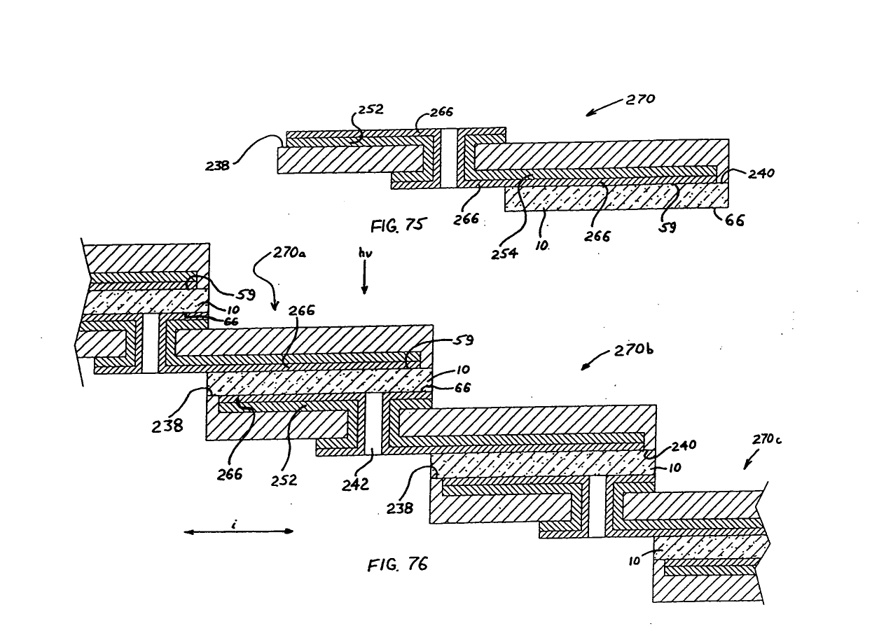

The sectional views of FIGS. 75 and 76 embody the use of article 250 or 260 to achieve a series connected structural array of photovoltaic cells 10. In FIG. 75, an article designated as 270 has been formed by combining article 260 with cell 10 by laminating the bottom surface 240 of article 260 to the top conductive surface 59 of cell 10. In a preferred embodiment, exposed surface 240 (those regions not covered with “fingers” 254) is formed by a material having adhesive affinity to surface 59 and a secure and extensive adhesive bond forms between surfaces 240 and 59 during the heat and pressure exposure of the lamination process. Thus an adhesive “blanket” holds conductive material 266 of “fingers” 254 in secure ohmic contact with surface 59. As previously pointed out, low melting point alloys or conductive adhesives may also be considered to enhance this contact. It is understood that article 270 of FIG. 75 is yet another embodiment of a tabbed cell stock.

The sectional view of FIG. 76 embodies multiple articles 270 arranged in a series interconnected array. In the FIG. 76 embodiment, it is seen that “fingers” 252 positioned on surface 238 of article 270b have been brought into contact with the bottom surface 66 of cell 10 associated with article 270a. This contact is achieved by choosing material 232 forming free surface 238 of article 270b to have adhesive affinity for bottom conductive surface 66 of cell 10 of article 270a. Secure adhesive bonding is achieved during the heat and pressure exposure of a laminating process thereby resulting in a hold down of the “fingers” 252. The ohmic contact thus achieved can be enhanced using low melting point alloys or conductive adhesives as previously taught herein.

Thus, it is seen that continuous communication is achieved between the top surface of one cell and the bottom or rear surface of an adjacent cell. Importantly, the communication is achieved with a continuous and unitary conductive structure. This avoids potential degradation of contact sometimes associated with multiple contact surfaces possible when using conductive adhesives. In addition, the FIG. 76 embodiment clearly shows an advantageous “shingling” type structure that avoids any shielding of valuable photovoltaic cell surface.

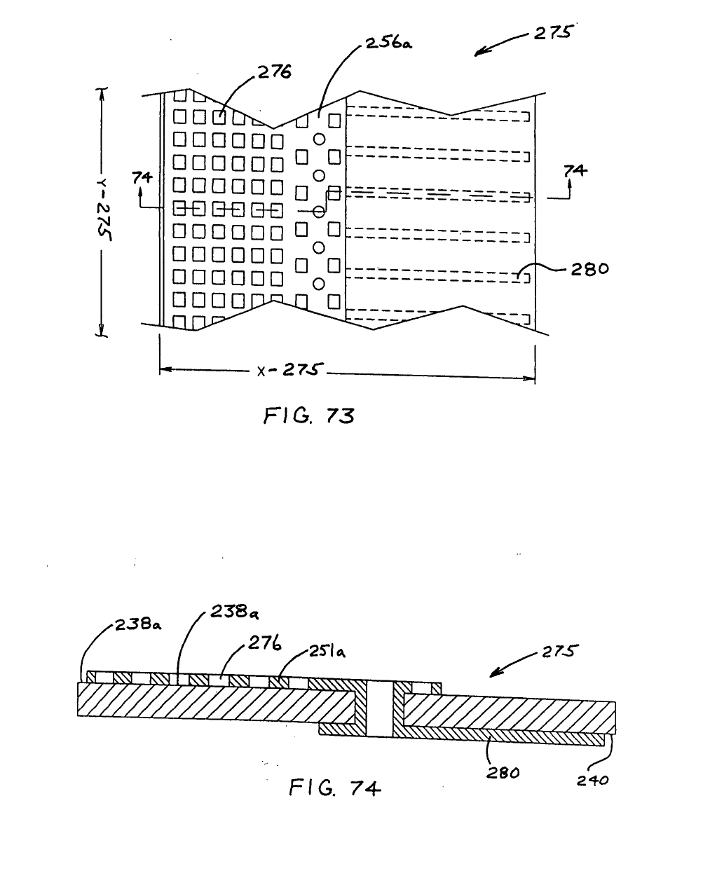

The embodiments of FIGS. 70 through 72 show the “fingers” and “busses” as essentially planar rectangular structures. Other geometrical forms are clearly possible. This is especially the case when considering structure for contacting the rear or bottom surface 66 of a photovoltaic cell 10. One embodiment of an alternate structure is depicted in FIGS. 73 and 74. FIG. 73 is a top plan view while FIG. 74 is a sectional view taken substantially from the perspective of lines 74-74 of FIG. 73. In FIGS. 73 and 74, there is depicted an article 275 analogous to article 250 of FIG. 70. The article 275 in FIGS. 73 and 74 comprises “fingers” 280 similar to “fingers” 254 of the FIG. 70 embodiment. However, the pattern of material 251a forming the structure on the top surface 238a of article 275 is considerably different than the “fingers” 252 and “buss” 256 of the FIG. 70 embodiment. In FIG. 73, material 251a is deposited in a mesh-like pattern having voids 276 leaving multiple regions of surface 238a exposed. Lamination of such a structure may result in improved surface area contact of the pattern compared to the finger structure of FIG. 70. It is emphasized that since surface 238a of article 275 eventually contacts rear surface 66 of the photovoltaic cell, potential shading is not an issue and thus geometrical design of the exposed contacting surfaces 238a relative to the mating conductive surfaces 66 can be optimized without consideration to shading issues.

A number of methods are available to combine the current collecting and interconnection structures taught hereinabove with photovoltaic cell stock to achieve effective interconnection of multiple cells into arrays. A brief description of some possible methods follows. A first method envisions combining photovoltaic cell structure with current collecting electrodes while both components are in their originally prepared “bulk” form prior to subdivision to dimensions appropriate for individual cells. A expansive surface area of photovoltaic structure such as embodied in FIGS. 1 and 2 of the instant specification representing the cumulative area of multiple unit cells is produced. As a separate and distinct operation, an array comprising multiple current collector electrodes arranged on a common substrate, such as the array of electrodes taught in FIGS. 30-39 and 59 is produced. The bulk array of electrodes is then combined with the expansive surface of photovoltaic structure in a process such as the laminating process embodied in FIG. 40. This process results in a bulk combination of photovoltaic structure and collector electrode. Appropriate subdividing of the bulk combination results in individual cells having a preattached current collector structure. Electrical access to the collector structure of individual cells may be achieved using through holes, as taught in conjunction with the embodiments of FIGS. 34, 35 and 59 through 62. Alternatively, one may simply lift the collector structure away from the surface 59 at the edge of the unit photovoltaic cell to expose the collector electrode.

Another method of combining the collector electrodes and interconnect structures taught herein with photovoltaic cells involves a first step of manufacture of multiple individual current collecting structures or electrodes. A suitable method of manufacture is to produce a bulk continuous roll of electrodes using roll to roll processing. Examples of such manufacture are the processes and structures embodied in the discussion of FIGS. 30 through 39 of the instant specification. The bulk roll is then subdivided into individual current collector electrodes for combination with discrete units of cell stock. The combination produces discrete individual units of “tabbed” cell stock. In concept, this approach is appropriate for individual cells having known and defined surface dimensions, such as 6″×6″, 4″×3″, 2″×8″ and 2″×16″. Cells of such defined dimensions are produced directly, such as with conventional single crystal silicon manufacture. Alternatively, cells of such dimension are produced by subdividing an expansive cell structure into smaller dimensions. The “tabbed” cell stock thereby produced could conceptually be packaged in cassette packaging. The discrete “tabbed” cells are then electrically interconnected into an array, possibly using automatic dispensing, positioning and electrical joining of multiple cells. The overhanging tabs of the individual “tabbed” cells facilitate such joining into an array. Interconnect substrate structures such as those embodied in FIGS. 6 through 12 of the instant specification may contribute to the interconnected array assembly. Alternately, the overhanging tab corresponding to a top current collector electrode of one cell may be bent over to present an upward facing region to abut the bottom conductive surface of an adjacent unit “tabbed” cell. Yet another alternative is to use the structure such as depicted in FIG. 53 having tabbed current collector electrodes attached to both the upper and lower conductive surfaces of cells and subsequently interconnect according to the embodiments of FIGS. 54 and 55.

Alternate methods to achieve interconnected arrays according to the instant invention comprise first manufacturing multiple current collector structures in bulk roll to roll fashion. In this case the “current collector stock” would comprise electrically conductive current collecting structure on a supporting sheetlike web essentially continuous in the “Y” of “machine” direction. Furthermore, the conductive structure is possibly repetitive in the “X” direction, such as the arrangement depicted in FIGS. 30 and 59 of the instant specification. In a separate operation, individual rolls of unit “cell stock” are produced, possibly by subdividing an expansive web of cell structure. The individual rolls of unit “cell stock” are envisioned to be continuous in the “Y” direction and having a defined width corresponding to the defined width of cells to be eventually arranged in interconnected array. Having separately prepared rolls of “current collector stock” and unit “cell stock”, multiple array assembly processes may be considered as follows.
A first assembly process is to employ an interconnect substrate to facilitate combining the “collector stock” and “cell stock”. In this case, continuous rolls of interconnect substrate, unit “cell stock” and “collector stock” are positioned and combined as taught in conjunction with FIGS. 41 through 43 of the instant specification. In this process embodiment, multiple repetitive current collector forms are present in the web “X” direction, all supported on a single sheetlike web.
In an alternate array assembly process, a roll of unit “current collector stock” is produced, possibly by subdividing a bulk roll of “current collector stock” to appropriate width for the unit roll. The rolls of unit “collector stock” and unit “cell stock” are then combined in a continuous process to produce a roll of unit “tabbed stock”. The “tabbed” stock therefore comprises cells, which may be extensive in the “y” dimension, equipped with readily accessible contacting surfaces for either or both the top and bottom surfaces of the cell. The “tabbed” stock may be assembled into an interconnected array using a multiple of different processes. As examples, two such process paths are discussed according to (a) and (b) following.
   (a) Multiple strips of “tabbed” stock are fed to a process such that an interconnected array of multiple cells is achieved continuously in the machine (original “Y”) direction. This process would produce an interconnected array having series connections of cells whose number would correspond to the number of rolls of “tabbed” stock being fed. In this case the individual strips of “tabbed” stock would be arranged in appropriate overlapping fashion as dictated by the particular embodiment of “tabbed” stock. The multiple overlapping tabbed cells would be electrically joined appropriately using electrical joining means, laminating or combinations thereof. Both the feed and exit of such an assembly process would be substantially in the original “Y” direction and the output of such a process would be essentially continuous in the original “Y” direction. The multiple interconnected cells could be rewound onto a roll for further processing.
   (b) In an alternative process, a single strip of “tabbed” cell stock is unwound, cut to a predetermined length, and positioned. This length is “shuttled” in the original “x” direction a distance substantially the length of a repeat dimension among adjacent series connected cells. A second strip of “tabbed” cell stock is then unwound and appropriately positioned to properly overlap the first strip, cut to length and electrically joined in series to the first strip. The electrical joining may take many forms, depending somewhat on the structure of the individual “tabbed” cell stock. For example, in the embodiment of FIGS. 54 and 55, joining may take the form of an electrically conductive adhesive, solder, etc. as previously taught. In the case of “tabbed” cell stock such as FIG. 75, electrical joining may comprise a simple lamination such as embodied in FIG. 76. In such an assembly process the interconnected cell stock would exit the basic assembly process in a fashion substantially perpendicular to the original “Y” direction of the “tabbed” cell stock. The interconnected cells produced would therefore have a new predetermined width (in the original “Y” direction) and the new length (in the original “X” direction) may be of extended dimension. The output in the new length dimension may be described as essentially continuous.

### Example 1

A standard plastic laminating sheet from GBC Corp. 75 micrometer (0.003 inch) thick was coated with DER in a pattern of repetitive fingers joined along one end with a busslike structure resulting in an article as embodied in FIGS. 46 through 47C. The fingers were 0.020 inch wide, 1.625 inch long and were repetitively separated by 0.150 inch. The buss-like structure which contacted the fingers extended in a direction perpendicular to the fingers as shown in FIG. 46. The buss-like structure had a width of 0.25 inch. Both the finger pattern and buss-like structure were printed simultaneously using the same DER ink and using silk screen printing. The DER printing pattern was applied to the laminating sheet surface formed by the sealing layer (i.e. that surface facing to the inside of the standard sealing pouch).

The finger/buss pattern thus produced on the lamination sheet was then electroplated with nickel in a standard Watts nickel bath at a current density of 50 amps. per sq. ft. Approximately 4 micrometers of nickel thickness was deposited to the overall pattern.

A photovoltaic cell having surface dimensions of 1.75 inch wide by 2.0625 inch long was used. This cell was a CIGS semiconductor type deposited on a 0.001 inch stainless steel substrate. A section of the laminating sheet containing the electroplated buss/finger pattern was then applied to the top, light incident side of the cell, with the electroplated grid finger extending in the width direction (1.75 inch dimension) of the cell. Care was taken to ensure that the buss region of the conductive electroplated metal did not overlap the cell surface. This resulted in a total cell surface of 3.61 sq. inch. (2.0625″×1.75″) with about 12% shading from the grid, (i.e. about 88% open area for the cell).

The electroplated “finger/buss” on the lamination film was applied to the photovoltaic cell using a standard Xerox office laminator. The resulting completed cell showed good appearance and connection.

The cell prepared as above was tested in direct sunlight for photovoltaic response. Testing was done at noon, Morgan Hill, Calif. on Apr. 8, 2006 in full sunlight. The cell recorded an open circuit voltage of 0.52 Volts. Also recorded was a “short circuit” current of 0.65 Amps. This indicates excellent power collection from the cell at high efficiency of collection.

### Example 2

An interconnecting substrate structure was produced in the following way. A non-woven fabric sheet comprising polypropylene fibrils, having intrinsic “through holes” of typical dimension approximately 0.002 inch and a thickness approximately 0.002 inches was selected. This starting sheet had a length of 12 inches and a width of 8.5 inches. A DER ink comprising solids of 66 percent Kraton rubber (Trademark Kraton Polymers), 30 percent Vulcan XC-72 conductive carbon black (product of Cabot Corp.), 2 percent sulfur and 2 percent MBTS was selected. The DER ink was coated in strips 1 inch wide separated by 1 inch (2 inch center to center distance) extending in the length direction. Coating was performed on both opposite sides to insure that the ink fully extended through the holes joining opposite surfaces of the fabric. The strips were then electroplated with approximately 5 micrometers nickel from a standard Watts nickel bath followed by approximately 5 micrometers copper from a standard acid copper bath and finally a flash of about 0.5 micrometer nickel.

In a separate operation, individual thin film CIGS semiconductor cells comprising a stainless steel supporting substrate 0.001 inch thick were cut to dimensions of 7.5 inch length and 1.75 inch width.

In another separate operation, multiple laminating collector grids were prepared. A 0.003 inch thick laminating film supplied by GBC Corp. was selected. The film was coated with DER in a pattern of repetitive fingers joined along one end with a busslike structure. Multiple such patterns were produced in a repetitive pattern in the width direction of the film to result in an article as embodied in FIGS. 30 through 32. The fingers were 0.012 inch wide, 1.625 inch long and were repetitively separated on 0.120 inch centers in the length direction. The buss-like structures which contacted the fingers extended in the length direction perpendicular to the fingers as shown in FIG. 30. The buss-like structures had a width of 0.25 inch. A repeat distance (dimension “F” shown in FIG. 30) of 2 inches was maintained. Both the finger patterns and buss-like structures were printed simultaneously using the same DER ink and using silk screen printing. The DER printing pattern was applied to the laminating sheet surface formed by the sealing layer (i.e. that surface facing to the inside of the standard sealing pouch). The DER pattern supported on the GBC laminating film was then coated with electrodeposit comprising 2 micrometer nickel, 5 micrometer copper and finally 0.5 micrometer nickel. Nickel was deposited from a nickel sulfamate bath and copper from an acid copper bath. Following electroplating, individual unit laminating current collector sheets were cut from the larger sheet of multiple units. The individual units were of length 7.5 inches and width 2.0 inches.

The individual cells and individual unit collector sheets were then combined to form tabbed cell stock as depicted in FIG. 49. Combination was accomplished by appropriate positioning of the individual cells with mating unit collector stock sheets and passing through a standard Xerox office laminator.

The individual tabbed cells were then positioned on the interconnecting substrate in a fashion similar to that depicted in FIG. 51. This placement resulted in a remaining exposed contact portion 48 of each conductive region 23 of about 0.25 inch. Electrical joining between the bottom surface of a first of the individual tabbed cells was accomplished with a thin film of electrically conductive adhesive comprising 67 percent Kraton elastomer and 33 percent conductive carbon black, Vulcan XC-72. Electrical joining of the tab portion of an adjacent cell to the remaining exposed contact portion 48 was accomplished with the same conductive adhesive.

Three cells were accordingly joined in series interconnection using the procedure to thereby produce a three cell array. The array generated a short circuit current of 2.0 amperes and a closed circuit voltage of 1.53V when tested in full noon time sun.

### Example 3

An interconnected array of three cells according to the arrangement depicted in FIG. 64 was prepared. Initial preparation of the collector stock (such as depicted in FIG. 62) was accomplished in a fashion very similar to production of the collector stock as in Example 2. The major difference in production of the Example 3 collector stock was the inclusion of the through holes allowing electrical communication between opposite surfaces of the stock. Dimensions for the individual cells and individual collector grids were identical as those for the Example 2. The electrical joining among adjacent cells (identified by numeral 42 in FIG. 64) was accomplished using a thin film of the same conductive carbon loaded adhesive used for Example 2. Since there is no interconnect “dead area” associated with the FIG. 64 arrangement, the total area of the 3 cell array was 39.4 square inches (1.75″×7.5″×3). In full noon time sun, the Example 3 array had a short circuit current of 2.1 amperes and a closed circuit voltage of 1.54V.

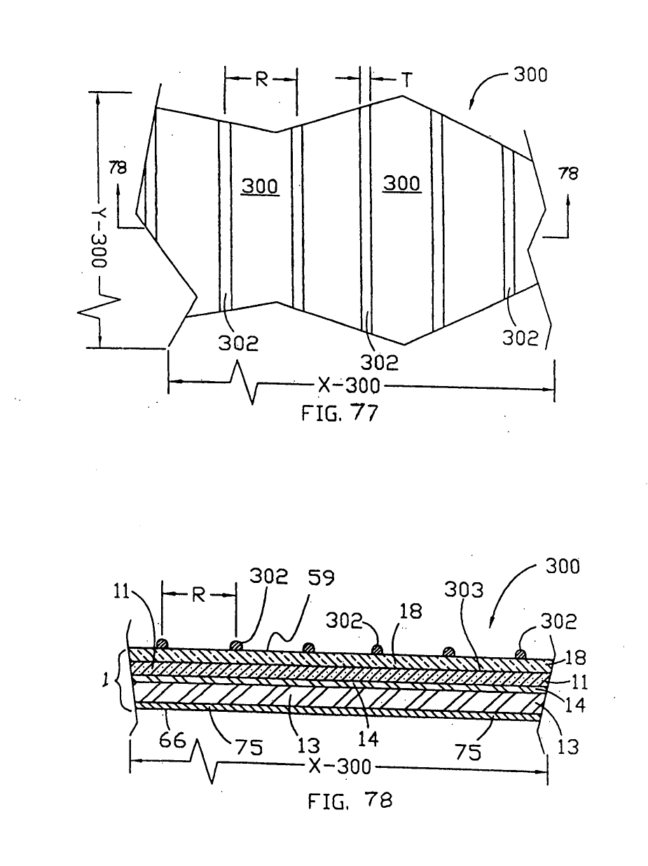

A further embodiment of a front face current collector structure is taught in conjunction with FIGS. 77 through 91. FIG. 77 is a top plan view of a metal foil/semiconductor photovoltaic structure similar to the structure depicted in FIGS. 1 and 2. However, the structure of FIG. 77, generally referred to as article 300, also includes narrow strips of insulating material 302 extending in the length direction Y-300. Strips 302 are usually positioned at repeat distances “R” in the width direction X-300 of article 300. As will be seen below, dimension “R” approximates the width X-10 of the eventual individual cells.

FIG. 78 is a sectional view taken substantially along line 78-78 of FIG. 77. FIG. 78 shows a laminate comprising separate layers 75,13,14,11, and 18 as previously described for the structure of FIG. 2. Insulating strips 302 are shown positioned on top surface 59 of article 300. However, it is understood that strips 302 could be positioned on top surface 303 of semiconductor material 11. In this latter case, window electrode 18 could be deposited over the entire surface (including strips 302) or selectively onto the surface areas between strips 302. It should also be understood that insulating strips 302 are optional. For simplicity, the embodiments of FIGS. 77 through 91 will show strips 302 disposed on top surface 59 of window electrode 18. The purpose of the optional insulating strips 302 is to prevent shorting between top and bottom electrode material during subsequent slitting into individual cells, as will become clear below.

In the embodiment shown, length Y-300 may be much greater than width X-300 and length Y-300 can generally be described as “continuous” or being able to be processed in roll-to-roll fashion. This dimensional characterization is not necessary, and in other embodiments, dimension Y-300 may be of finite dimension and not “continuous”. In contrast to width X-10 of the individual cell structure of FIGS. 1A and 2A, X-300 of FIGS. 77 and 78 is envisioned to be of magnitude equivalent to the cumulative widths of multiple cell structures. Optional strips 302 are typically 0.002 inch to 0.050 inch wide (dimension “T”, FIG. 77). Optional strips 302 can be applied to the surface 59 by any number of methods such as thermoplastic extrusion, roll printing or photo masking.

In order to promote simplicity of presentation, layers 75,13,14,11 and 18 of article 300 will be depicted as a single layer 1 in subsequent embodiments.

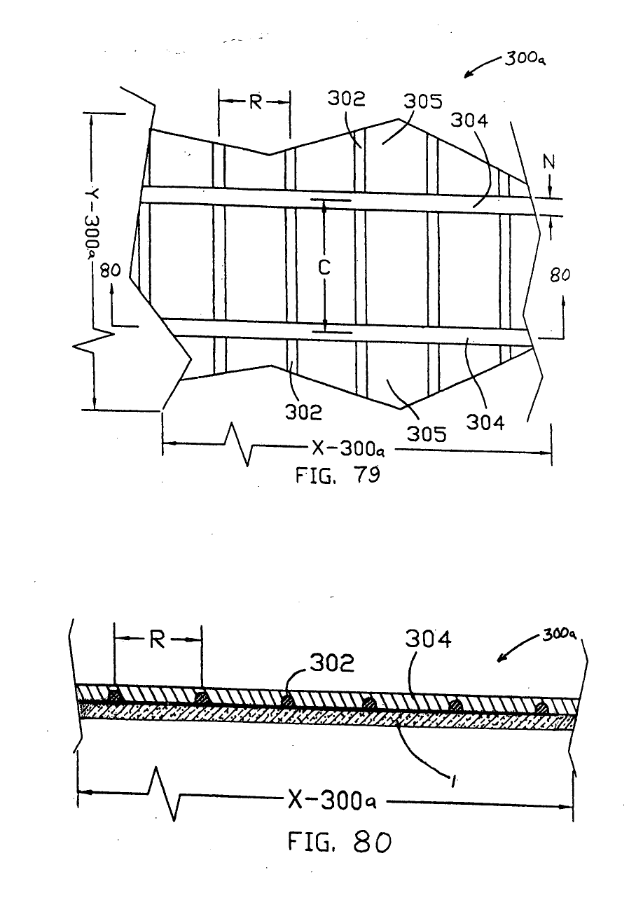

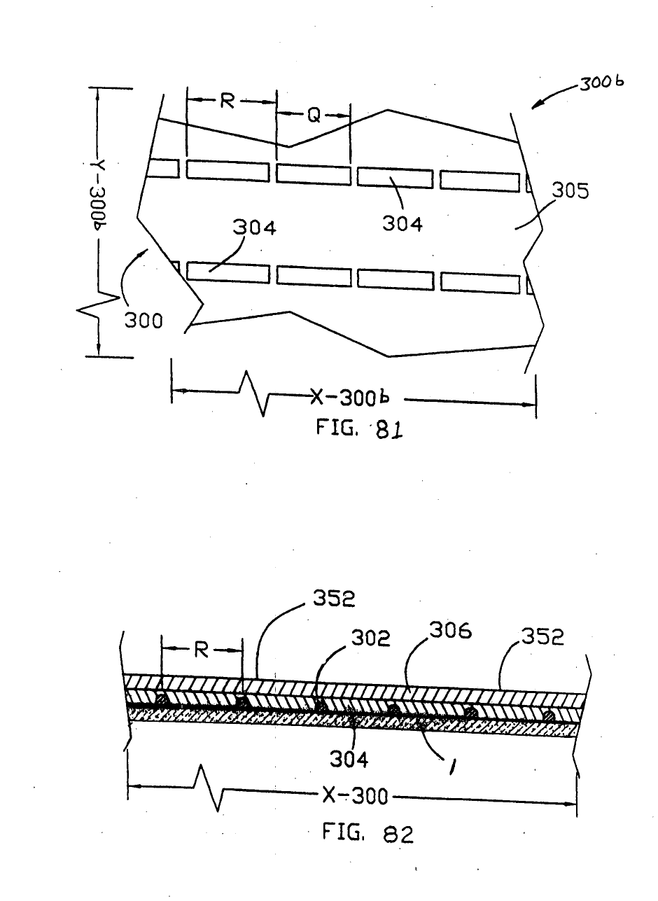

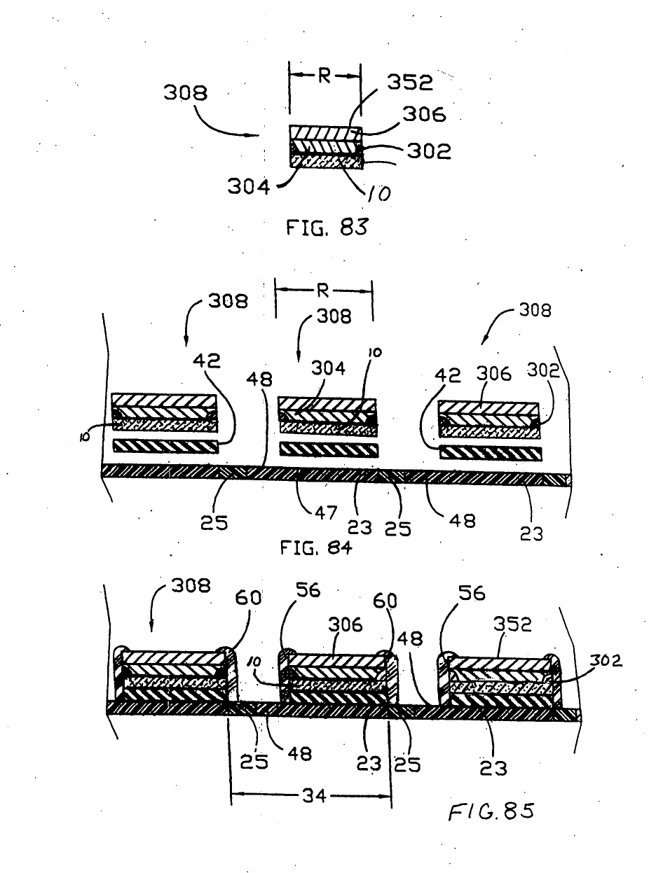

FIG. 79 is a top plan view of the FIG. 77 article following an additional processing step and FIG. 80 is a sectional view taken substantially along the line 80-80 of FIG. 79. The article of FIG. 79 is identified as 300a reflecting this additional processing. Electrically conductive material 304 has been deposited as strips onto the top surface of article 300 of FIG. 77 to produce article 300a. In the FIG. 79 embodiment, conductive material 304 extends in the width direction X-300a and traverses a plurality of repeat distances “R”. Dimension “N” of strips 304 is normally made as small as possible, typically 0.001 inch to 0.100 inch. Dimension “C”, the repeat distance between strips 304 depends to some extent on dimension “N” but is typically 0.05 inch to 1.0 inch.

Conductive material 304 can comprise electrically conductive resins or adhesives such as silver filled inks. Alternatively, conductive material 304 can comprise metal-based materials applied by selective deposition such as masked metal evaporation and sputtering. It is, of course, advantageous to select materials and techniques which promote adhesive and ohmic contact to the top surface 59 of window electrode 18. As will be appreciated by those skilled in the art in light of the following teachings, electrically conductive resins or inks, including DER's, may be very suitable as materials for conductive material 304. Alternately, conductive material 304 can comprise conductive metallic wires or strips positioned in a substantially parallel arrangement as shown. In this case provision should be made to fix the wires in position to maintain proper positioning during subsequent processing taught following in the specification. Such “fixing” becomes more difficult as the width X-300 increases. Such “fixing” may be accomplished using techniques such as coating the wires with a conductive resin based adhesive. Such an adhesive may be formulated as a pressure sensitive formulation (tacky and having adhesive characteristics at room temperature) or a hot melt formulation (heated to tackify to achieve a bond which remains upon cooling). Such conductive resin based adhesives may comprise a curing agent. Alternately the wire or metal strip may be coated with metal based material in which case heating the wires above the melting point of the coating would promote “soldering” and improved surface contact of the wires to the surface of the photovoltaic cell. Yet another alternative would be to use a magnetic field to assist fixing the wires in place during a subsequent processing. This may be achieved by having the wires comprise a magnetic material such as iron or nickel. Magnetic “fixing” may be achieved by permanently magnetizing the wires themselves to produce a magnetic attraction to a magnetic component of a foil substrate of the photovoltaic cell. Alternatively, a magnetic component of the foil cell substrate may be permanently magnetized. Another alternative would be to impose an externally generated magnetic field to hold the wires in position until a subsequent permanent “fixing” could be achieved.

In the embodiment of FIG. 79, those areas of the top surface of article 300a not covered with conductive material 304 may be optionally coated with a thin coating of electrically insulating material 305 should subsequent processing, such as electroplating, be deleterious to the photovoltaic materials themselves.

FIG. 81 is a top plan view of an alternate embodiment. In FIG. 81, 300b designates an article similar to the article 300a of FIGS. 79 and 80 but optional insulating strips 302 are not shown. They have either been excluded or are invisible in the plan view of FIG. 81, having been deposited on the surface of semiconductor material 11 (and thus overcoated with window electrode 18) or covered by optional insulating material 305. Conductive material 304 designates strips or islands of electrically conductive material having dimension “Q” slightly less than repeat distance “R”. Those skilled in the art will recognize, in light of the teachings that follow below, that in many cases the article 300b embodied in FIG. 81 would be conceptually equivalent to the article 300a of FIG. 79.

FIG. 82 is a sectional view similar to FIG. 80 after an additional optional processing step. In FIG. 82, additional highly electrically conductive material 306 has been deposited overlaying conductive material 304. Material 306 has exposed top surface 352. It is understood that if optional material 306 is not present, numeral 352 would represent the top surface of material 304 in this and subsequent embodiments. In a preferred embodiment, highly electrically conductive material 306 is electrodeposited of electroleesly deposited. In particular, electrodeposition permits relatively rapid deposition rates and permits facile deposition of very conductive materials such as copper and silver. In this regard, it may be advantageous to employ a DER for the conductive material 304. In yet another preferred embodiment conductive material 306 comprises a metal wire or foil.

It can be appreciated that regardless of the specific deposition process and characterization of the conductive materials 304/306, their pattern or “footprint” extends in the “X” direction a distance equivalent to multiple widths “R”. This concept therefore allows for deposition of the individual cell grid fingers in an essentially bulk, and possible continuous fashion.

FIG. 83 is a sectional view of a portion of the FIG. 82 structure after an additional processing step comprising slitting the FIG. 82 structure along the optional insulating strip 302 at repeat distances “R” to give individual unit articles 308 comprising laminate portions of structures 10, 302, 304, and 306 of the prior embodiments. Articles 308 have width “R” which, as will be seen, approximates the eventual photovoltaic cell width. During this slitting process, optional insulating beads 302 may help prevent or limit smearing of the top conductive material to the bottom metal-base foil 12 of cell 10 which would result in electrical shorting. Articles 308 may “Y” dimension (dimension normal to the paper in FIG. 83) appropriate to be described as “continuous”. However, this is not necessary, and dimension “Y” for article 308 may be discretely defined.

FIGS. 84 through 91 embody a process to interconnect the unit articles 308. FIG. 84 is a view similar to FIG. 13B showing the FIG. 83 structures just prior to a combining process similar to FIG. 13A. Individual articles 308 are positioned in spacial relationship with electrically conductive adhesive 42 and conductive regions 23. As in prior embodiments, regions 23 are separated by insulating regions 25. Conductive regions 23 can be considered to have a top contact surface region 48 and top collector surface region 47.

FIG. 85 is a sectional view of the structure resulting from the combining of the articles of FIG. 84 plus an additional step of applying insulating beads 56,60 to the terminal edges of the individual articles 308. As shown in FIG. 85, at least a portion of top contact surface 48 remains exposed following this combination. In addition, the combination is characterized by repeat dimension 34, which is slightly greater than dimension “R”.

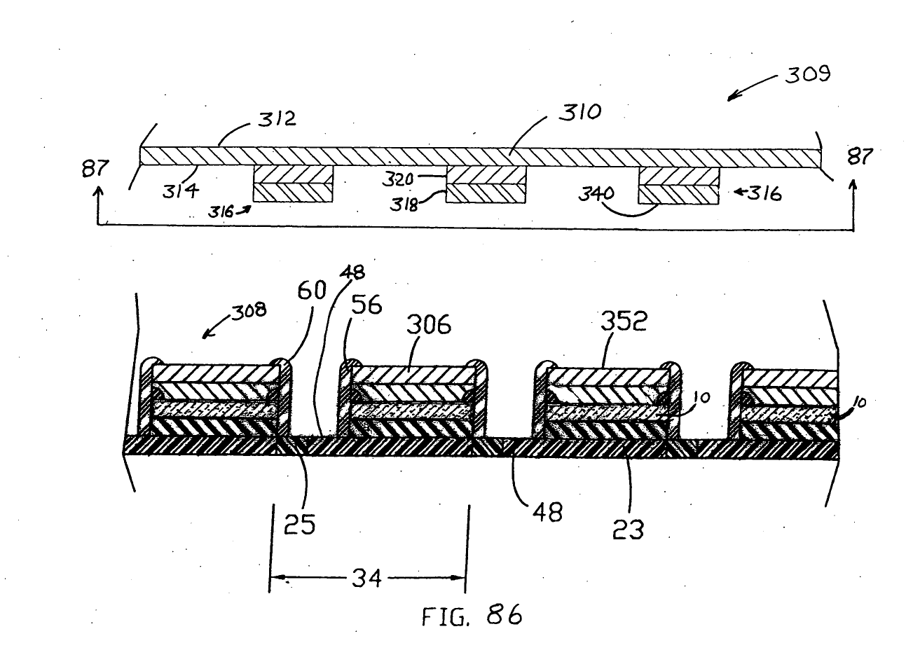

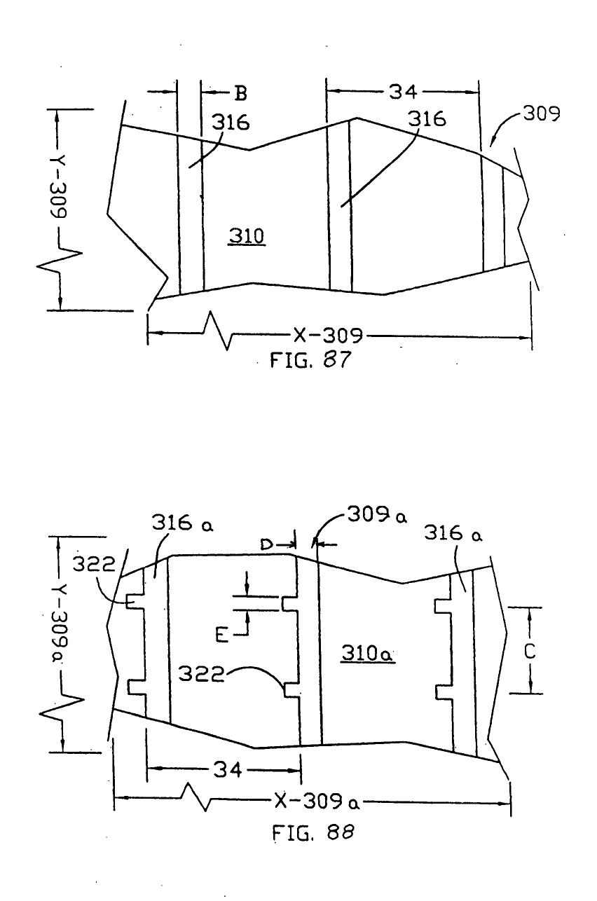

FIG. 86 is a sectional view prior to a further laminating step in the production of the overall array. FIG. 86 introduces an additional sheetlike laminating interconnection component 309 comprising material structure 316 mounted on sheet 310. Sheet 310 has a top surface 312 and a bottom surface 314. Sheet 310, while shown as a single layer for simplicity, may comprise a laminate of multiple layers of materials to supply adhesive and barrier properties to the sheet. It will be recognized in light of the teachings to follow that interconnection component 309 may be similar in character to article 71 of FIGS. 30-32 and the optional articles in FIGS. 36-39 except that the “finger” structures of those embodiments has been omitted in component 309.

Mounted in spaced arrangement on the bottom surface 314 of sheet 310 are strips 316 of material having an exposed surface 340 which is electrically conductive. Strips 316 are also shown in FIG. 86 to comprise layer 320 which adhesively bonds conductive layer 318 to sheet 310. Layer 320 need not necessarily be electrically conductive and may be omitted if adhesion between conductive material 318 and sheet 310 is sufficient. Layer 318 may comprise, for example, an electrically conductive adhesive or polymer, a metal, etc. as for prior embodiments of “fingers” and “busses”.

FIG. 87, a top plan view taken substantially along line 87-87 of FIG. 86. In the FIGS. 87 and 88 embodiments material 316 is in the form of strips extending in the Y-309 dimension. Strips 316 have a width dimension “B”. In the specific embodiments presented in FIGS. 84 through 91, dimension “B” is sufficient to span the distance between conductive strips 306 of one article 308 to a contact region 48 associated with an adjacent unit (see FIG. 86). Typical magnitudes for dimension “B” for such an embodiment are from 0.020 inch to 0.25 inch depending on registration accuracy during the multiple lamination processes envisioned.

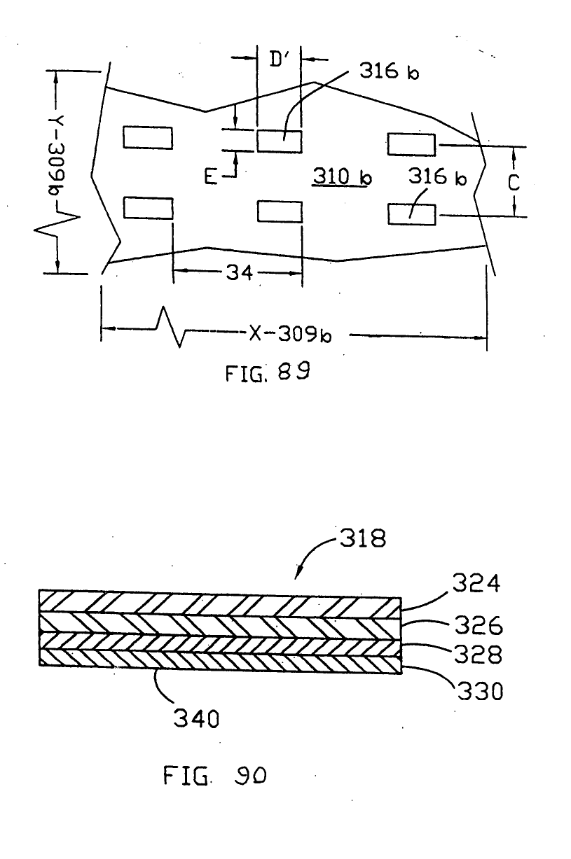

FIGS. 88 and 89 present alternatives to the FIG. 87 article. In FIG. 88, conductive tab extensions 322 of width “E” reach out in the “X” direction from the strips 316a. Tabs 322 are positioned at repeat distances “C” in the “Y” direction corresponding to the repeat dimension “C” of the conductive materials 304/306. Proper positional registration during the lamination process envisioned in FIG. 86 allows tabs 322 to overlap and contact conductive material 306, permitting increased contact area between conductive material 306 and tabs 322 and also a possible reduction in width “D” of strips 316a of FIG. 88 in comparison to dimension “B” of FIG. 87.

FIG. 89 shows an alternate embodiment wherein strips 316 and 316a of FIGS. 87 and 88 respectively have been replaced by individual islands 316b. Thus, material forming conductive surface 340 need not be continuous in the “Y” direction. Islands 316b can comprise, for example, an electrically conductive adhesive. Dimension “D′” of FIG. 89 is sufficient to span the distance between conductive material 306 of one article 308 to the contact surface 48 of conductive region 23 corresponding to an adjacent article.

Since the linear distance between conductive material 306 of one article 308 and contact surface 48 corresponding to an adjacent article is small, the materials 316, 316a, and 316b of FIGS. 87, 88, and 89 respectively, and the material forming conductive tab extensions 322 do not necessarily need to comprise materials exhibiting electrical conductivities characteristic of pure metals and alloys. However, as will be discussed below, proper selection of materials to form surface 340 of these structures can be used to advantage in achieving excellent ohmic and adhesive contacts to conductive material 306 and contact surfaces 48 of conductive regions 23.

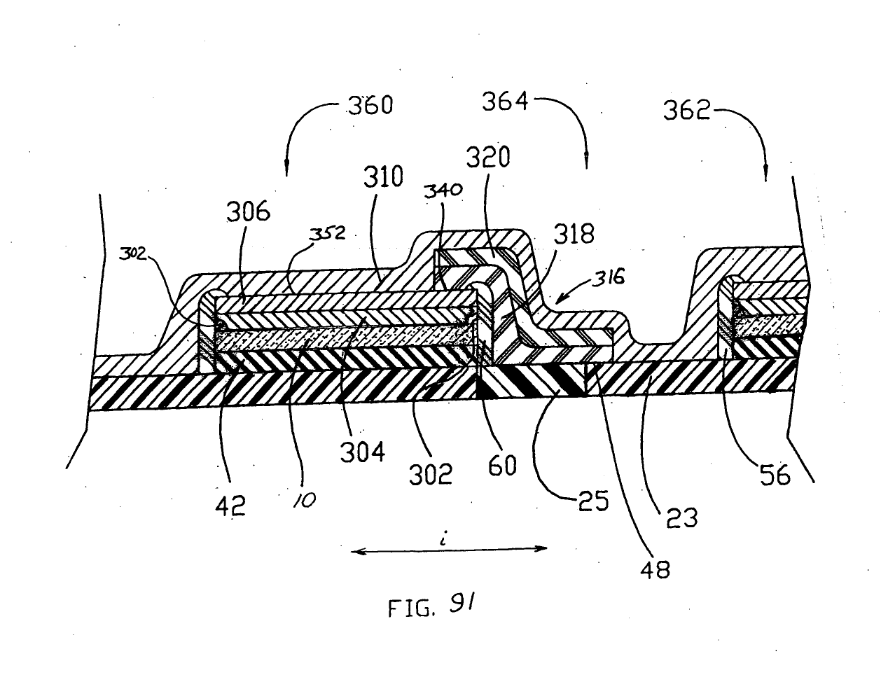

Accordingly, an example of a laminated structure envisioned for conductive layer 318 is embodied in the sectional view of FIG. 90. A layer of electroplateable resin 324 is attached to optional adhesive layer 320 (layer 320 is not shown in FIG. 90). This is followed by layers 326,328 of electrodeposited metal for mechanical and electrical robustness. As in previous embodiments it is understood that the electrodeposited metal can comprise a single layer. Finally in the FIG. 90 embodiment, an optional layer of material having adhesive affinity to the respective mating conductive surfaces is designated as numeral 330. Material 330 may be for example a conductive “hot melt” adhesive or a layer of a low melting point metal or alloy solder. Material 330 has a free surface 340. Those skilled in the art will recognize that DER's would be a highly attractive choice for electroplateable resin layer 324. Alternatively, a material, not necessarily conductive, which would allow selective deposition of metal by chemical techniques could be chosen for layer 324.

Using the structure embodied in FIG. 90 for the conductive layer 318, the material 330 with free surface 340 is caused to soften or melt during the lamination process depicted in FIG. 86, resulting in a conductive adhesive joining between the material forming contact surface 48 of conductive region 23 and material 330 with free surface 340. A similar conductive joining may be formed between the material forming exposed top surface 352 of conductive material 306 and material 330 having free surface 340.

One will note that the retention of sheets 310 of FIGS. 86 through 89 is not an absolute requirement for achieving the electrical interconnections among cells, but does facilitate handling and maintenance of spacial positioning during formation of the conductive interconnect structures and the subsequent laminating process envisioned in FIG. 86. In this regard, sheet 310 could be a surrogate support which is removed subsequent to or during lamination. This removal could be achieved, for example, by having adhesive layer 320 melt during the lamination process to release sheet 310 from material 318.

One also should recognize that the electrical interconnections between conductive material 306 of articles 308 and contact surface 48 corresponding to an adjacent cell could be made by using individual “beads” of conductive material spanning the gap between contact region 48 and each individual grid finger of an adjacent cell.

FIG. 91 is a greatly exploded view of one embodiment of a completed interconnection achieved according to the teachings embodied in FIGS. 77 through 90. FIG. 91 shows first cell 360 and a portion of adjacent cell 362. Interconnect region 364 is positioned between cells 360 and 362. Sheet 310 holds strip 316 in position contacting surface 352 of material 306 of cell 360 and extending to contact surface 48 associated with adjacent cell 362. Film 310 forms an adhesive “blanket” to maintain the positioning and contact. As taught above, electrical contact may be optionally augmented by choice of material forming surface 340 of strips 316. It is seen that robust, highly efficient top surface current collection and cell interconnections are achieved with inexpensive, controllable and repetitive manufacturing techniques. Sensitive and fine processing techniques involving material removal which increase costs and may adversely affect yields are avoided. The double pointed arrow “i” in FIG. 91 indicates the direction of net current flow among the interconnected cells.

The embodiments of FIGS. 86 through 91 illustrate the use of article 309 comprising strips 316 to interconnect adjacent cells employing a separate interconnect substrate as embodied in FIGS. 6 and 7. One will understand that articles such as 309 comprising conductive strips 316 may be employed in other ways. For example, the strips 316 could be positioned across conductive strips 304/306 of an individual unit cell such as 308 (FIG. 83) to collect and convey current from the surface of the cell 308. Once collected in this way, the current could be transported to a point remote from the cell (such as to an electrode of an adjacent cell) by a simple extension of the strip 316 structure to the remote point.

While the grid/interconnect structure taught in conjunction with FIGS. 77 through 91 employed the substrate structure depicted in FIGS. 6 and 7, it is understood that similar results would be achieved with the other substrate embodiments taught in this specification

### Example 4

Multiple photovoltaic cells comprising thin film CIGS semiconductor supported on a 0.002 inch thick stainless steel substrate were prepared. These individual cells had dimensions of 4 inch length and 3 inch width had a printed pattern of fingers comprising a silver loaded ink. The fingers had a length of approximately 2.75 inches long extending in the width dimension.

Sheets of laminating current collector stock were prepared. In this example the substrate comprised a film of biaxially oriented polypropylene (BOPP) coated with an olefinic based sealant layer. In this case the collector stock consisted simply of a buss pattern in the form of a strip of width 0.1 inch. The buss comprised metal electrodeposited onto the surface of the sealant layer. The electrodeposited metal consisted of 2 micrometer nickel, 13 micrometer copper and 0.5 micrometer nickel topcoat. The laminating collector sheets were dimensioned such that the buss strips were of sufficient length to extend to the bottom surface of an adjacent series connected cell.

The current collector stock was positioned over the cells such that the electrodeposited busses extended perpendicular to the silver ink fingers. Lamination brought the buss into intimate contact with the fingers and also caused the sealant to melt and adhere vigorously to the top conductive cell surface. Simultaneously, the buss extensions overhanging a particular cell were brought into laminated contact with the rear conductive surface of an adjacent cell. This was accomplished by folding over the extending buss strip portions of the collector stock on themselves such that the region underlying the adjacent cell had the sealing layer and buss facing upward to properly form a laminated connection to the base of the adjacent cell.

A series array of three cells was formed in this way. Exposure to full noon sunlight resulted in a short circuit current of 1.5 amperes and a closed circuit voltage of 1.5 V.

The simplified interconnections among multiple photovoltaic cells taught in the present disclosure are made possible in large measure by the ability to selectively electrodeposit highly conductive metal-based materials to manufacture both supporting interconnect substrates and current collector grid structures. This selectivity is readily and inexpensively achieved by employing directly electroplateable resins (DERs) as defined herein or alternatively metal based “seed” inks which allow direct electroplating.

While many of the embodiments of the invention refer to “current collector” structure, one will appreciate that similar articles could be employed to convey other electrical characteristics such as voltage.

Although the present invention has been described in conjunction with preferred embodiments, it is to be understood that modifications, alternatives and equivalents may be included without departing from the spirit and scope of the inventions, as those skilled in the art will readily understand. Such modifications, alternatives and equivalents are considered to be within the purview and scope of the invention and appended claims.

What is claimed is:

1. In combination, a conductive surface and an electrode attached to said conductive surface, said electrode comprising a at least one electrically conductive material in the form of multiple traces connected by a buss, said combination characterized by having said electrode positioned relative to said conductive surface such that a first portion of said conductive material overlays said conductive surface and a second portion of said conductive material overhangs a peripheral edge of said conductive surface, said conductive material being of monolithic structure.

2. An interconnecting electrode suitable for electrically joining two electrical surfaces, said electrode comprising electrically conductive material positioned over a first surface of a sheetlike film, said first surface being formed by material having adhesive affinity for a first of said electrical surfaces, said electrically conductive material on said first surface being in electrical communication with additional conductive material positioned over a second surface of said sheetlike film, said second surface being formed of material having adhesive affinity for a second of said electrical surfaces.
